(19) United States
(12) Patent Application Publication
(10) Pub. No.: US 2025/0316551 A1
(43) Pub. Date: Oct. 9, 2025

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Soichi YOSHIDA, Matsumoto-city (JP)

(21) Appl. No.: 19/245,404

(22) Filed: Jun. 23, 2025

Related U.S. Application Data
(63) Continuation of application No. PCT/JP2024/025236, filed on Jul. 12, 2024.

(30) Foreign Application Priority Data
Jul. 14, 2023 (JP) 2023-115900

(51) Int. Cl. H01L 23/34; H10D 84/00

(52) U.S. Cl. CPC H01L 23/34; H10D 84/161

(57) ABSTRACT

Provided is a semiconductor device including: an active portion; and a temperature sensitive portion, in which the temperature sensitive portion includes a temperature sensitive trench portion which is provided on a front surface side of a semiconductor substrate, a temperature sensitive anode region which is provided inside a trench of the temperature sensitive trench portion, and a temperature sensitive cathode region which is provided in contact with the temperature sensitive anode region inside the trench of the temperature sensitive trench portion.

The contents of the following patent application(s) are incorporated herein by reference:
NO. 2023-115900 filed in JP on Jul. 14, 2023
NO. PCT/JP2024/025236 filed in WO on Jul. 12, 2024.

### BACKGROUND

### 1. Technical Field

The present invention relates to a semiconductor device and a method for manufacturing the semiconductor device.

### 2. Related Art

Patent Document 1 describes “a semiconductor device including an integrated PN diode temperature sensor and a method for manufacturing the same”.

### PRIOR ART DOCUMENTS

### Patent Documents

Patent Document 1: U.S. Patent Application Publication No. 2019/0172770
Patent Document 2: Japanese Patent Application Publication No. 2014-053554
Patent Document 3: Japanese Patent Application Publication No. 2012-195339
Patent Document 4: Japanese Patent Application Publication No. 2021-015884
Patent Document 5: Japanese Patent Application Publication No. 2010-287786

### BRIEF DESCRIPTION OF THE DRAWINGS

FIG. 1A illustrates an example of an enlarged top view of a semiconductor device 100.

FIG. 1B illustrates an example of a cross section a-a′ in FIG. 1A.

FIG. 2A illustrates an enlarged top view of a modification of the semiconductor device 100.

FIG. 2B illustrates an example of a cross section b-b′ in FIG. 2A.

FIG. 3 illustrates an example of a top view of the semiconductor device 100.

FIG. 4A illustrates an example of a cross section of the semiconductor device 100 including a temperature sensitive portion 180.

FIG. 4B illustrates a cross section of a modification of the semiconductor device 100 including the temperature sensitive portion 180.

FIG. 4C illustrates a cross section of a modification of the semiconductor device 100 including the temperature sensitive portion 180.

FIG. 4D illustrates a cross section of a modification of the semiconductor device 100 including the temperature sensitive portion 180.

FIG. 5A illustrates an example of a cross section of a temperature sensitive trench portion 185.

FIG. 5B illustrates a cross section of a modification of the temperature sensitive trench portion 185.

FIG. 5C illustrates a cross section of a modification of the temperature sensitive trench portion 185.

FIG. 5D illustrates a cross section of a modification of the temperature sensitive trench portion 185.

FIG. 6A illustrates an example of an enlarged top view of a temperature sensitive diode portion 183 in the temperature sensitive portion 180 of a region T in FIG. 3.

FIG. 6B is an enlarged top view illustrating another example of the temperature sensitive diode portion 183 in the temperature sensitive portion 180.

FIG. 6C is an enlarged top view illustrating another example of the temperature sensitive diode portion 183 in the temperature sensitive portion 180.

FIG. 6D is an enlarged top view illustrating another example of the temperature sensitive diode portion 183 in the temperature sensitive portion 180.

FIG. 6E is an enlarged top view illustrating another example of the temperature sensitive diode portion 183 in the temperature sensitive portion 180.

FIG. 6F illustrates an equivalent circuit of the temperature sensitive diode portion 183 illustrated in FIGS. 6A, 6B, 6C, 6D, and 6E.

FIG. 6G is an enlarged top view illustrating another example of the temperature sensitive diode portion 183 in the temperature sensitive portion 180.

FIG. 6H is an enlarged top view illustrating another example of the temperature sensitive diode portion 183 in the temperature sensitive portion 180.

FIG. 6I is an enlarged top view illustrating another example of the temperature sensitive diode portion 183 in the temperature sensitive portion 180.

FIG. 6J is an enlarged top view illustrating another example of the temperature sensitive diode portion 183 in the temperature sensitive portion 180.

FIG. 6K is an equivalent circuit diagram of the temperature sensitive diode portion 183 illustrated in FIGS. 6I, 6J, and 6K.

FIG. 6L is an enlarged top view illustrating another example of the temperature sensitive diode portion 183 in the temperature sensitive portion 180.

FIG. 6M is an equivalent circuit diagram of the temperature sensitive diode portion 183 illustrated in FIG. 6L.

FIG. 6N illustrates another example of the enlarged top view of the temperature sensitive diode portion 183 in the temperature sensitive portion 180 of the region T in FIG. 3.

FIG. 6O illustrates an equivalent circuit of the temperature sensitive diode portion 183 illustrated in FIG. 6N.

FIG. 6P illustrates another example of the enlarged top view of the temperature sensitive diode portion 183 in the temperature sensitive portion 180 of the region T in FIG. 3.

FIG. 6Q illustrates an equivalent circuit of the temperature sensitive diode portion 183 illustrated in FIG. 6P.

FIG. 6R illustrates another example of the enlarged top view of the temperature sensitive diode portion 183 in the temperature sensitive portion 180 of the region T in FIG. 3.

FIG. 7A illustrates a cross section of a modification of the semiconductor device 100 including the temperature sensitive portion 180.

FIG. 7B illustrates a cross section of a modification of the semiconductor device 100 including the temperature sensitive portion 180.

FIG. 7C illustrates a cross section of a modification of the semiconductor device 100 including the temperature sensitive portion 180.

FIG. 8 is a flowchart illustrating an example of a manufacturing step of the semiconductor device 100.

FIG. 9 is an example of electrical connection of each portion of the semiconductor device 100.

FIG. 10A illustrates an example of the enlarged top view of the semiconductor device 100.

FIG. 10B illustrates an example of a cross section c-c′ in FIG. 10A.

FIG. 11A illustrates an example of a cross section d-d′ in FIG. 10A.

FIG. 11B illustrates an example of a cross section d-d′ in FIG. 10A.

FIG. 12A illustrates an example of a cross section e-e′ in FIG. 10A.

FIG. 12B illustrates an example of the cross section e-e′ in FIG. 10A.

FIG. 13A illustrates an example of the top view of the semiconductor device 100.

FIG. 13B illustrates an example of a region R in FIG. 13A.

FIG. 14A illustrates an example of a cross section f-f′ in FIG. 13B.

FIG. 14B illustrates an example of the cross section f-f′ in FIG. 13B.

FIG. 15 illustrates an example of a cross section g-g′ in FIG. 13A.

FIG. 16 illustrates an example of the cross section g-g′ in FIG. 13A.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is ND and the acceptor concentration is NA, the net doping concentration at any position is given as ND-NA. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of vacancy (V), oxygen (O), and hydrogen (H), an Si-i-H defect which is a combination of interstitial silicon (Si-i) and hydrogen, and a CiOi-H defect which is a combination of interstitial carbon (Ci), interstitial oxygen (Oi), and hydrogen that exist in the semiconductor function as a donor for supplying electrons. In the present specification, the VOH defect or the like may be referred to as a hydrogen donor.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier means a charge carrier of an electron or a hole. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like. The carrier concentration decreases for a following reason. In the SRP method, the spreading resistance is measured, and the carrier concentration is converted from a measurement value of the spreading resistance. At this time, mobility of the crystalline state is used as the carrier mobility. On the other hand, despite the fact that the carrier mobility has decreased at a position where the lattice defect is introduced, the carrier concentration is calculated by using the carrier mobility of the crystalline state. Therefore, a value lower than an actual carrier concentration, that is, a concentration of the donor or the acceptor, is obtained.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. As used herein, a unit of a distance or length may be represented by cm (centimeter). In this case, various calculations may be converted into m (meter) to be calculated. As for numeric representation of power of 10, for example, the representation 1E+16 indicates 1×10¹⁶, and the representation 1E-16 indicates 1×10⁻¹⁶.

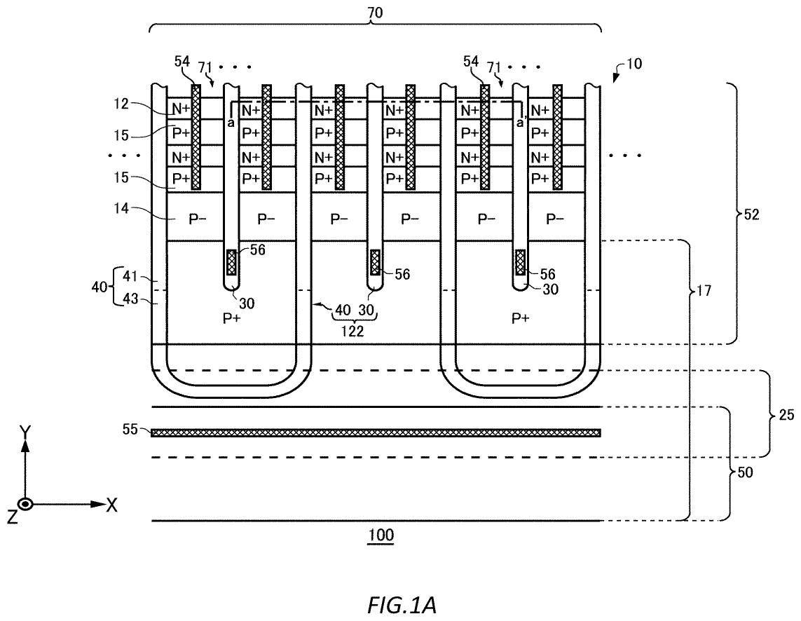

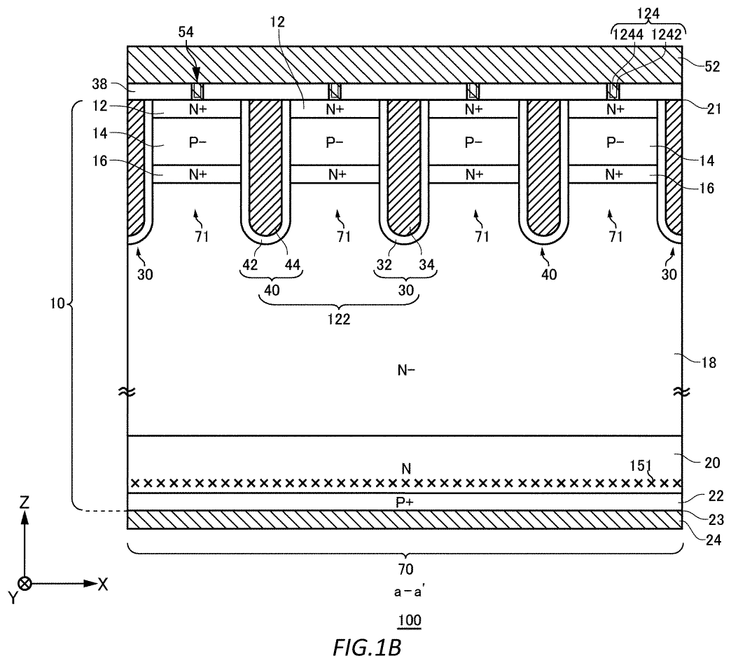

FIG. 1A illustrates an example of an enlarged top view of a semiconductor device 100. The semiconductor device 100 in the present example is a semiconductor chip which includes a transistor portion 70. The semiconductor device 100 is not limited to a transistor as long as it is a semiconductor element in which a semiconductor substrate 10 has a MOS gate structure.

The transistor portion 70 is a region obtained by projecting a collector region 22 provided on a back surface side of the semiconductor substrate 10 onto an upper surface of the semiconductor substrate 10. The collector region 22 will be described below. The transistor portion 70 includes a transistor such as an IGBT. In the present example, the transistor portion 70 is an IGBT. Note that the transistor portion 70 may be another transistor such as a MOSFET.

The present drawing illustrates a region around an active portion 120 of the semiconductor device 100, and illustration of other regions is omitted. The active portion 120 is a part through which a main current flows between a front surface 21 and a back surface 23 of the semiconductor substrate 10. The active portion 120 will be described below. For example, an edge termination structure portion may be provided in a region on a negative side in the Y axis direction in the semiconductor device 100 in the present example. The edge termination structure portion reduces electric field strength on an upper surface side of the semiconductor substrate 10. For example, the edge termination structure portion has a structure of a guard ring, a field plate, a RESURF, and a combination thereof. Note that although the present example describes an edge on the negative side in the Y axis direction for convenience, the same applies to other edges of the semiconductor device 100.

The semiconductor substrate 10 is a substrate which is formed of a semiconductor material. The semiconductor substrate 10 may be a silicon substrate, a silicon carbide substrate, another compound semiconductor substrate, or a diamond semiconductor substrate. The semiconductor substrate 10 in the present example is the silicon substrate. Note that when simply referred to as a top view in the present specification, it means that the semiconductor substrate 10 is viewed from an upper surface side. As will be described below, the semiconductor substrate 10 includes the front surface 21 and the back surface 23.

The semiconductor device 100 in the present example includes a gate trench portion 40, a dummy trench portion 30, an emitter region 12, a base region 14, a contact region 15, and a well region 17 at the front surface 21 of the semiconductor substrate 10. In addition, the semiconductor device 100 in the present example includes an emitter electrode 52 and a gate metal layer 50 which are provided above the front surface 21 of the semiconductor substrate 10. The emitter electrode 52 and the gate metal layer 50 are examples of a front surface side metal layer. The gate trench portion 40 is an example of the MOS gate structure provided in the semiconductor device 100. Note that although the semiconductor device 100 in the present example is a transistor including the MOS gate structure, the semiconductor device 100 may be a diode including the MOS gate structure.

The emitter electrode 52 is provided above the gate trench portion 40, the dummy trench portion 30, the emitter region 12, the base region 14, the contact region 15, and the well region 17. In addition, the gate metal layer 50 is provided above a connection portion 25 and the well region 17.

The emitter electrode 52 and the gate metal layer 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or of a metal alloy such as an aluminum-silicon alloy (AlSi) or an aluminum-silicon-copper alloy (AlSiCu). The emitter electrode 52 and the gate metal layer 50 may include a barrier metal film formed of titanium, a titanium compound, or the like under a region formed of aluminum or the like. The emitter electrode 52 and the gate metal layer 50 are provided separated from each other.

The emitter electrode 52 and the gate metal layer 50 are provided above the semiconductor substrate 10 with an interlayer dielectric film 38 interposed therebetween. The interlayer dielectric film 38 is omitted in FIG. 1A. A contact hole 54, a contact hole 55, and a contact hole 56 are provided to penetrate the interlayer dielectric film 38.

The contact hole 55 electrically connects the gate metal layer 50 and the gate conductive portion in the transistor portion 70 via the connection portion 25. A barrier metal film formed of titanium, a titanium compound, or the like and/or a plug portion formed of tungsten or the like may be formed inside the contact hole 55.

The contact hole 56 connects the emitter electrode 52 with a dummy conductive portion within the dummy trench portion 30. A barrier metal film formed of titanium, a titanium compound, or the like and/or a plug portion formed of tungsten or the like may be formed inside the contact hole 56.

The connection portion 25 is connected to the front surface side metal layer such as the emitter electrode 52 or the gate metal layer 50. In an example, the connection portion 25 is provided between the gate metal layer 50 and the gate conductive portion. The connection portion 25 in the present example may be provided to extend in the X axis direction and electrically connected to the gate conductive portion. The connection portion 25 may also be provided between the emitter electrode 52 and the dummy conductive portion. In the present example, the connection portion 25 is not provided between the emitter electrode 52 and the dummy conductive portion. The connection portion 25 is a conductive material such as polysilicon doped with impurities. The connection portion 25 in the present example is polysilicon (N+) doped with impurities of the N type. The connection portion 25 is provided above the front surface 21 of the semiconductor substrate 10 via a dielectric film such as an oxide film, or the like.

The gate trench portion 40 is an example of an active trench portion 122 provided at the front surface 21 of the semiconductor substrate 10. That is, the active trench portion 122 may be a trench portion provided in the active portion 120. The active trench portion 122 will be described below. The gate trench portions 40 are arrayed at a predetermined interval along a predetermined array direction (the X axis direction in the present example). The gate trench portion 40 in the present example may include two extending parts 41 which extend along an extending direction (the Y axis direction in the present example) parallel to the front surface 21 of the semiconductor substrate 10 and perpendicular to the array direction, and a connecting part 43 which connects the two extending parts 41.

At least a part of the connecting part 43 is preferably formed in a curved shape.

Connecting end portions of the two extending parts 41 of the gate trench portion 40 can reduce electric field strength at the end portions of the extending parts 41. In the connecting part 43 of the gate trench portion 40, the gate metal layer 50 may be electrically connected to the gate conductive portion via the connection portion 25.

The dummy trench portion 30 is an example of the active trench portion 122 provided at the front surface 21 of the semiconductor substrate 10. That is, the active trench portion 122 may be a trench portion provided in the active portion 120. The dummy trench portion 30 is a trench portion which is electrically connected to the emitter electrode 52. Similarly to the gate trench portions 40, the dummy trench portions 30 are arrayed at a predetermined interval along a predetermined array direction (the X axis direction in the present example). Although the dummy trench portion 30 in the present example has an I shape at the front surface 21 of the semiconductor substrate 10, the dummy trench portion 30 may have a U shape at the front surface 21 of the semiconductor substrate 10, similarly to the gate trench portion 40. That is, the dummy trench portion 30 may include two extending parts extending along an extending direction and a connecting part connecting the two extending parts.

The transistor portion 70 in the present example has a structure in which two gate trench portions 40 and two dummy trench portions 30 are repeatedly arrayed. That is, the transistor portion 70 in the present example has the gate trench portions 40 and the dummy trench portions 30 at a ratio of 1:1. For example, the transistor portion 70 has one dummy trench portion 30 between two extending parts 41.

It is to be noted that the ratio between the gate trench portions 40 and the dummy trench portions 30 is not limited to that in the present example. A ratio of the gate trench portions 40 may be larger than a ratio of the dummy trench portions 30, or the ratio of the dummy trench portions 30 may be larger than the ratio of the gate trench portions 40. The ratio between the gate trench portions 40 and the dummy trench portions 30 may be 2:3, or may be 2:4. In addition, the transistor portion 70 may not include the dummy trench portions 30 with all trench portions being the gate trench portions 40.

The well region 17 is a region of a second conductivity type which is provided on a front surface 21 side of the semiconductor substrate 10 relative to a drift region 18 to described below. The well region 17 is an example of a well region provided in a peripheral side of the active portion 120. The well region 17 is of the P+ type as an example. The well region 17 is formed in a predetermined range from an end portion of an active region on a side where the gate metal layer 50 is provided. A diffusion depth of the well region 17 may be deeper than a depth of the gate trench portion 40 and the dummy trench portion 30. Partial regions of the gate trench portion 40 and the dummy trench portion 30 on a gate metal layer 50 side are formed in the well region 17. Bottoms of ends in the extending direction of the gate trench portion 40 and the dummy trench portion 30 may be covered with the well region 17.

The contact hole 54 is formed above each region of the emitter region 12 and the contact region 15 in the transistor portion 70. The contact hole 54 is not provided above the well regions 17 provided at both ends in the Y axis direction. In this manner, one or more contact holes 54 are formed in the interlayer dielectric film. The one or more contact holes 54 may be provided to extend in an extending direction.

A mesa portion 71 is a mesa portion provided adjacent to the trench portion in a plane parallel to the front surface 21 of the semiconductor substrate 10. The mesa portion may be a part of the semiconductor substrate 10 sandwiched between two trench portions adjacent to each other, and may be a part from the front surface 21 of the semiconductor substrate 10 to a depth of a lowermost bottom portion of each trench portion. The extending part of each trench portion may be defined as one trench portion. That is, a region sandwiched between two extending parts may be defined as a mesa portion.

The mesa portion 71 is provided adjacent to at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. In the mesa portion 71, the emitter regions 12 and the contact regions 15 are alternately provided in an extending direction.

The base region 14 is a region of the second conductivity type which is provided on the front surface 21 side of the semiconductor substrate 10. The base region 14 is of the P− type as an example. The base regions 14 may be provided at both end portions of the mesa portion 71 in the Y axis direction at the front surface 21 of the semiconductor substrate 10. Note that FIG. 1A illustrates only one end portion of the base region 14 in the Y axis direction.

The emitter region 12 is a region of a first conductivity type which has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71.

The emitter region 12 is also provided below the contact hole 54.

In addition, the emitter region 12 may or may not be in contact with the dummy trench portion 30. The emitter region 12 in the present example is in contact with the dummy trench portion 30.

The contact region 15 is a region of the second conductivity type which is provided above the base region 14 and has a doping concentration higher than that of the base region 14. The contact region 15 in the present example is of the P+ type as an example. The contact region 15 in the present example is provided at the front surface 21 in the mesa portion 71. The contact region 15 may be provided in the X axis direction from one to another of the two trench portions sandwiching the mesa portion 71. The contact region 15 may or may not be in contact with the gate trench portion 40 or the dummy trench portion 30. The contact region 15 in the present example is in contact with the dummy trench portion 30 and the gate trench portion 40. The contact region 15 is also provided below the contact hole 54. Note that in FIG. 1A, configurations of the gate trench portion 40, the dummy trench portion 30, the emitter region 12, the contact region 15, or the like may be periodically or continuously formed in a +X axis direction and a −X axis direction (not shown).

FIG. 1B illustrates an example of a cross section a-a′ in FIG. 1A. The cross section a-a′ is an XZ plane passing through the emitter region 12 in the transistor portion 70. The semiconductor device 100 in the present example includes, in the cross section a-a′, the semiconductor substrate 10, the interlayer dielectric film 38, the emitter electrode 52, a collector electrode 24, and an active contact portion 124. The collector electrode 24 is an example of a back surface side metal layer provided in contact with the back surface 23 of the semiconductor substrate 10. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region which has remained without another doping region formed in the semiconductor substrate 10. That is, the doping concentration of the drift region 18 may be a doping concentration of the semiconductor substrate 10.

The buffer region 20 is a region of the first conductivity type which is provided on the back surface 23 side of the semiconductor substrate 10 relative to the drift region 18. The buffer region 20 in the present example is of the N type as an example. A doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. Note that the buffer region 20 may be omitted.

The collector region 22 is provided below the buffer region 20 in the transistor portion 70. The collector region 22 is of the second conductivity type. The collector region 22 in the present example is of the P+ type as an example.

The collector electrode 24 is formed on the back surface 23 of the semiconductor substrate 10. The collector electrode 24 is formed of a conductive material such as metal. The material of the collector electrode 24 may be a same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may or may not be in contact with the dummy trench portion 30.

An accumulation region 16 is a region of the first conductivity type which is provided on the front surface 21 side of the semiconductor substrate 10 relative to the drift region 18. The accumulation region 16 in the present example is of the N+ type as an example. It is to be noted that the accumulation region 16 may not be provided.

The accumulation region 16 is provided in contact with the gate trench portion 40. The accumulation region 16 may or may not be in contact with the dummy trench portion 30. The doping concentration of the accumulation region 16 is higher than the doping concentration of the drift region 18. An ion implantation dose amount of the accumulation region 16 may be 1.0E+12 cm⁻² or more and 1.0E+13 cm⁻² or less. In addition, the ion implantation dose amount of the accumulation region 16 may be 3.0E+12 cm⁻² or more and 6.0E+12 cm⁻² or less. Providing the accumulation region 16 can increase a carrier injection enhancement effect (IE effect) to reduce an on-voltage of the transistor portion 70.

One or more gate trench portions 40 and one or more dummy trench portions 30 are provided at the front surface 21. Each trench portion may be the active trench portion 122 included in the active portion 120. Each trench portion is provided from the front surface 21 to the drift region 18. In a region provided with at least one of the emitter region 12, the base region 14, the contact region 15, or the accumulation region 16, each trench portion also penetrates these regions to reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The gate trench portion 40 includes a gate trench formed at the front surface 21, a gate dielectric film 42, and a gate conductive portion 44. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside from the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on a mesa portion 71 side with the gate dielectric film 42 interposed therebetween, in the depth direction of the semiconductor substrate 10. When a predetermined voltage is applied to the gate conductive portion 44, a channel is formed by an electron inversion layer in a surface layer of the base region 14 at an interface in contact with the gate trench.

The dummy trench portion 30 may have a same structure as that of the gate trench portion 40. The dummy trench portion 30 includes a dummy trench formed on the front surface 21 side, a dummy dielectric film 32, and a dummy conductive portion 34. The dummy dielectric film 32 is formed to cover an inner wall of the dummy trench. The dummy conductive portion 34 is formed inside the dummy trench, and is formed inside from the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may also be provided to penetrate the interlayer dielectric film 38. The interlayer dielectric film 38 may be a Boro-phospho Silicate Glass (BPSG) film, may be a borosilicate glass (BSG) film, may be a Phosphosilicate glass (PSG) film, may be an HTO film, or may be a stack of these materials. A film thickness of the interlayer dielectric film 38 is, for example, 1.0 μm, but is not limited thereto.

The active contact portion 124 is provided above the semiconductor substrate 10. The active contact portion 124 may include the contact hole 54 and a metal layer with which an inside of the contact hole 54 is filled. The inside of the contact hole 54 may be filled with a same material as that of the emitter electrode 52, or a material different from that of the emitter electrode 52. The active contact portion 124 may include a barrier metal film 1242 provided in the contact hole 54 and in contact with the semiconductor substrate 10. The active contact portion 124 may include a plug portion 1244 which is in contact with the barrier metal film 1242 and is provided so as to be embedded into the contact hole 54. The barrier metal film 1242 of the active contact portion 124 may contain titanium, a titanium compound, or the like. The plug portion 1244 of the active contact portion 124 may contain a plug metal such as tungsten. Similarly, the contact hole 55 and the contact hole 56, and a metal layer with which the insides of the contact hole 55 and the contact hole 56 are filled may also be the active contact portion 124. That is, the active contact portion 124 may be provided above the active portion 120 to electrically connect the front surface side metal layer to the semiconductor substrate 10 and/or the active trench portion 122. Note that an alloy layer which consists of an alloy of a metal included in the barrier metal film 1242 and a layer of the semiconductor substrate 10 or the like located below the contact hole 54 may be formed in contact with the barrier metal film 1242. In addition, in the layer of the semiconductor substrate 10 or the like located below the contact hole 54, a region having a high impurity concentration may be formed at a position in contact with the alloy layer.

A back surface side lifetime control region 151 may be provided in the transistor portion 70. It is to be noted that the back surface side lifetime control region 151 may be omitted. The back surface side lifetime control region 151 is a region where a lifetime killer has intentionally been formed, for example, by implanting impurities inside the semiconductor substrate 10. In an example, the back surface side lifetime control region 151 is formed by implanting helium into the semiconductor substrate 10. The back surface side lifetime control region 151 may also be formed by implanting protons. By providing the back surface side lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements constituting the semiconductor substrate 10, or dislocation. In addition, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements constituting the semiconductor substrate 10, or may be a dislocation concentration. In addition, the lifetime killer concentration may be a chemical concentration of the noble gas element such as helium and neon, or may be a chemical concentration of the metal element such as platinum.

The back surface side lifetime control region 151 may be formed by implantation from the back surface 23 side. Accordingly, it becomes easy to avoid an effect on the front surface 21 side of the semiconductor device 100. For example, the back surface side lifetime control region 151 is formed by radiating helium or protons from the back surface 23 side. Herein, which of the front surface 21 side and the back surface 23 side the implantation is performed from for forming the back surface side lifetime control region 151 can be determined by acquiring a state of the front surface 21 side by the SRP method or a measurement of a leakage current.

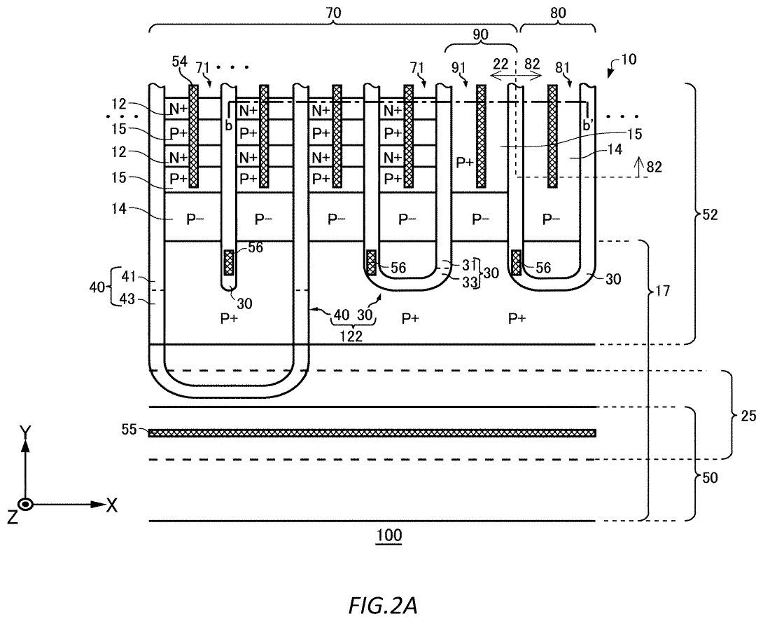

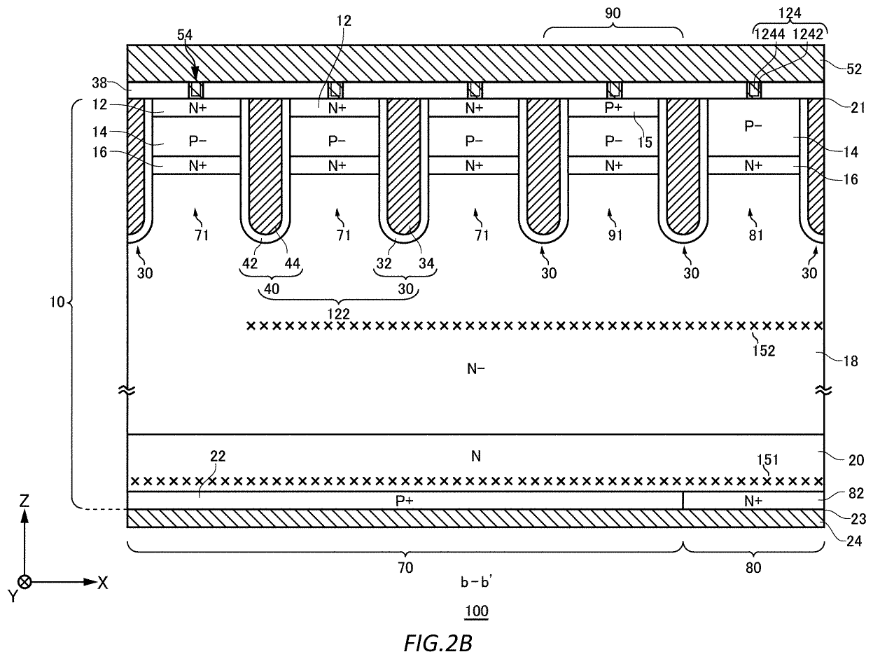

FIG. 2A illustrates an enlarged top view of a modification of the semiconductor device 100. The semiconductor device 100 in the present example includes the transistor portion 70 and a diode portion 80.

The semiconductor device 100 in the present example includes the gate trench portion 40, the dummy trench portion 30, the emitter region 12, the base region 14, the contact region 15, and the well region 17 which are provided inside the semiconductor substrate 10 on the front surface 21 side. Each of the gate trench portion 40 and the dummy trench portion 30 is an example of the active trench portion 122.

Similarly to the gate trench portion 40, the dummy trench portion 30 in the present example may have a U shape at the front surface 21 of the semiconductor substrate 10. That is, the dummy trench portion 30 may include two extending parts 31 extending along the extending direction and a connecting part 33 connecting the two extending parts 31.

The semiconductor device 100 in the present example includes the emitter electrode 52 and the gate metal layer 50 which are provided above the front surface 21 of the semiconductor substrate 10. The emitter electrode 52 and the gate metal layer 50 are provided separated from each other. The transistor portion 70 in the present example includes a boundary portion 90 which is located at a boundary between the transistor portion 70 and the diode portion 80. It is to be noted that the semiconductor device 100 does not need to include the boundary portion 90.

The boundary portion 90 is a region which is provided in the transistor portion 70 and is in direct contact with the diode portion 80. The boundary portion 90 includes the contact region 15 at the front surface 21 of the semiconductor substrate 10. The boundary portion 90 in the present example does not include the emitter region 12. In an example, trench portions in the boundary portion 90 are the dummy trench portions 30. The boundary portion 90 in the present example is arranged such that both ends thereof in the X axis direction become the dummy trench portions 30.

The contact hole 54 is provided above the base region 14 in the diode portion 80. The contact hole 54 is provided above the contact region 15 in the boundary portion 90. No contact hole 54 is provided above the well regions 17 provided at both ends in the Y axis direction.

A mesa portion 91 is provided in the boundary portion 90. The mesa portion 91 includes the contact region 15 at the front surface 21 of the semiconductor substrate 10. The mesa portion 91 in the present example has the base region 14 and the well region 17 on a negative side in the Y axis direction.

A mesa portion 81 is provided in a region sandwiched between the dummy trench portions 30 adjacent to each other in the diode portion 80. The mesa portion 81 includes the base region 14 at the front surface 21 of the semiconductor substrate 10. The mesa portion 81 in the present example includes the well region 17 on the negative side in the Y axis direction.

The emitter region 12 is provided in the mesa portion 71, but does not need to be provided in the mesa portion 81 and the mesa portion 91. The contact region 15 is provided in the mesa portion 71 and the mesa portion 91, but does not need to be provided in the mesa portion 81.

FIG. 2B illustrates an example of a cross section b-b′ in FIG. 2A. The semiconductor device 100 in the present example includes the back surface side lifetime control region 151 and a front surface side lifetime control region 152. It is to be noted that the semiconductor device 100 may not include one of the back surface side lifetime control region 151 or the front surface side lifetime control region 152. The semiconductor device 100 in the present example includes the collector region 22 and a cathode region 82 on the back surface 23 side of the buffer region 20.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71.

The accumulation region 16 is provided in the transistor portion 70 and the diode portion 80. The accumulation region 16 in the present example is provided at entire surfaces of the transistor portion 70 and the diode portion 80. It is to be noted that the accumulation region 16 does not need to be provided in the diode portion 80.

The cathode region 82 is provided below the buffer region 20 in the diode portion 80. A boundary between the collector region 22 and the cathode region 82 is the boundary between the transistor portion 70 and the diode portion 80. That is, the collector region 22 is provided below the boundary portion 90 in the present example.

The back surface side lifetime control region 151 may be provided in both the transistor portion 70 and the diode portion 80, may be provided only in the transistor portion 70, or may be provided only in the diode portion 80. Accordingly, the semiconductor device 100 in the present example can further improve a switching loss by accelerating a turn-off operation of the transistor portion 70 or a reverse recovery operation in the diode portion 80. The back surface side lifetime control region 151 may be formed by a method similar to that of the back surface side lifetime control region 151 in another example.

The front surface side lifetime control region 152 is provided on the front surface 21 side relative to a center of the semiconductor substrate 10 in the depth direction of the semiconductor substrate 10. The front surface side lifetime control region 152 in the present example is provided in the drift region 18. The front surface side lifetime control region 152 may be provided in both the transistor portion 70 and the diode portion 80, or may be provided only in the diode portion 80. The front surface side lifetime control region 152 may be provided in the diode portion 80 and the boundary portion 90 and not be provided in a part of the transistor portion 70. The front surface side lifetime control region 152 can suppress implantation of holes from the transistor portion 70 and the diode portion 80, to reduce a reverse recovery loss.

The front surface side lifetime control region 152 may be formed by any method of the methods for forming the back surface side lifetime control region 151. An element, a dose amount, and the like for forming the back surface side lifetime control region 151 may be the same as or different from those for forming the front surface side lifetime control region 152.

The front surface side lifetime control region 152 is provided to extend from the diode portion 80 to the transistor portion 70. The front surface side lifetime control region 152 may be formed by introducing a lifetime killer from the front surface 21 of the semiconductor substrate 10. The front surface side lifetime control region 152 may also be formed by irradiation from the back surface 23 side of the semiconductor substrate 10. The front surface side lifetime control region 152 in the present example is provided below the gate trench portion 40. Particle beams or the like for forming the front surface side lifetime control region 152 may pass through the MOS gate structure of the semiconductor device 100, thereby causing defects at an interface between a gate oxide film and the semiconductor substrate.

The semiconductor device 100 may be a power semiconductor device for performing power control or the like. The semiconductor device 100 in the present example may have a vertical semiconductor structure in which the back surface side metal layer is provided on the back surface 23 side of the semiconductor substrate 10. It is to be noted that the semiconductor device 100 may have a horizontal semiconductor structure in which the metal layer is not provided on the back surface 23 side.

Note that, in the present example, an RC-IGBT having a trench gate structure is described as an example of the semiconductor device 100. It is to be noted that the semiconductor device 100 may be a semiconductor device having a planar gate structure, or may be another semiconductor device such as a diode. The semiconductor device 100 may include an N-channel MOSFET or P-channel MOSFET.

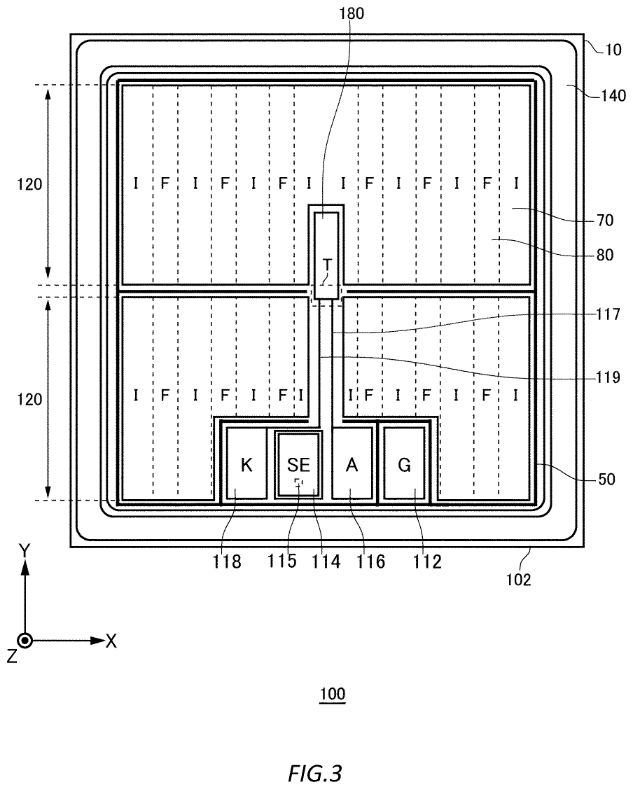

FIG. 3 illustrates an example of a top view of the semiconductor device 100. The semiconductor device 100 in the present example includes a temperature sensitive portion 180. In the present example, merely some members of the semiconductor device 100 are illustrated, and illustration of some members is omitted.

The semiconductor substrate 10 has an end side 102 in top view. The semiconductor substrate 10 in the present example has two sets of end sides 102 facing each other in top view. In the present example, the X axis and the Y axis are parallel to any of the end sides 102.

The semiconductor substrate 10 is provided with the active portion 120. The active portion 120 is a region through which a principal current flows in the depth direction between the front surface 21 and the back surface 23 of the semiconductor substrate 10 when the semiconductor device 100 is operated. The emitter electrode 52 is provided above the active portion 120, but is omitted in the present drawing.

The active portion 120 may be provided with at least one of the transistor portion 70 including a transistor element such as an IGBT or the diode portion 80 including a diode element such as a free wheel diode (FWD). In the example of FIG. 3, the transistor portions 70 and the diode portions 80 are alternately arranged along a predetermined array direction (the X axis direction in the present example) in the front surface 21 of the semiconductor substrate 10. In another example, the active portion 120 may be provided with only one of the transistor portion 70 and the diode portion 80. That is, only the transistor portion 70 may be provided in the active portion 120 as illustrated in FIG. 1A, both the transistor portion 70 and the diode portion 80 may be provided as illustrated in FIG. 2A, or only the diode portion 80 may be provided.

In the present example, a region where the transistor portion 70 is arranged is indicated by a symbol “I”, and a region where the diode portion 80 is arranged is indicated by a symbol “F”. Each of the transistor portion 70 and the diode portion 80 may be elongated in an extending direction. In other words, a length of the transistor portion 70 in the Y axis direction is larger than its width in the X axis direction. Similarly, a length of the diode portion 80 in the Y axis direction is larger than its width in the X axis direction. The extending direction of the transistor portion 70 and the diode portion 80 may be the same as a longitudinal direction of the active trench portion 122.

The diode portion 80 may be a region obtained by projecting the cathode region 82 provided on the back surface 23 side of the semiconductor substrate 10 onto the upper surface of the semiconductor substrate 10. The region obtained by projecting the cathode region 82 on the upper surface of the semiconductor substrate 10 may be located inside from the diode portion 80. In the back surface 23 of the semiconductor substrate 10, the collector region 22 of the P+ type may be provided in a region other than the cathode region 82.

An edge termination structure portion 140 is provided at the front surface 21 of the semiconductor substrate 10. The edge termination structure portion 140 is provided between the active portion 120 and the end side 102 in top view. The edge termination structure portion 140 reduces electric field strength on the front surface 21 side of the semiconductor substrate 10. The edge termination structure portion 140 may include at least one of a guard ring, a field plate, or a RESURF which is annularly provided to enclose the active portion 120.

The semiconductor device 100 may include one or more pads above the semiconductor substrate 10. The semiconductor device 100 in the present example includes a gate pad 112, a sensing electrode 114, an anode pad 116, and a cathode pad 118. Each pad may be arranged in a vicinity of the end side 102 of the semiconductor substrate 10. The vicinity of the end side 102 refers to a region between the end side 102 and the emitter electrode 52 in top view. When the semiconductor device 100 is mounted, each pad may be connected to an external circuit via a wiring line such as a wire.

A gate potential is applied to the gate pad 112. The gate pad 112 is electrically connected to the gate conductive portion 44 of the gate trench portion 40 of the active portion 120. The semiconductor device 100 may include a gate runner which connects the gate pad 112 and the gate trench portion 40. The gate runner may be constituted by either one of the gate metal layer 50 or the connection portion 25, or may be constituted by a combination of both as appropriate.

The sensing electrode 114 is electrically connected to a current sensing portion 115 provided below the sensing electrode 114. The sensing electrode 114 detects a current flowing through the current sensing portion 115. The current sensing portion 115 detects a current flowing through the transistor portion 70. The current sensing portion 115 has a structure corresponding to the transistor portion 70. A current flowing through the current sensing portion 115 is smaller than the current flowing through the transistor portion 70. In the current sensing portion 115, a current proportional to the current flowing through the transistor portion 70 may flow by simulating an operation of the transistor portion 70. A ratio of the current flowing through the current sensing portion 115 to the current flowing through the transistor portion 70 is appropriately set. By using the current sensing portion 115, the current flowing through the transistor portion 70 can be monitored.

The temperature sensitive portion 180 is provided above or inside the semiconductor substrate 10. The temperature sensitive portion 180 in the present example is provided between the transistor portions 70 in a central portion of the semiconductor device 100. The temperature sensitive portion 180 senses a temperature of the active portion 120. The temperature sensitive portion 180 may include a diode formed of monocrystalline or polycrystalline silicon. The temperature sensitive portion 180 is used to detect a temperature of the semiconductor device 100 and protect the semiconductor chip (semiconductor substrate 10) from overheating. The temperature sensitive portion 180 is connected to a constant current source. When the temperature of the semiconductor device 100 changes, a forward voltage of a current flowing through the temperature sensitive portion 180 changes. The semiconductor device 100 can detect the temperature based on the change in the forward voltage of the temperature sensitive portion 180.

The anode pad 116 is electrically connected to a temperature sensitive anode region 182 of the temperature sensitive portion 180. The anode pad 116 is electrically connected to the temperature sensitive anode region 182 of the temperature sensitive portion 180 by an anode wiring portion 117 electrically connected to the temperature sensitive anode region 182. The temperature sensitive anode region 182 will be described below.

The cathode pad 118 is electrically connected to a temperature sensitive cathode region 181 of the temperature sensitive portion 180. The cathode pad 118 is electrically connected to the temperature sensitive cathode region 181 of the temperature sensitive portion 180 by a cathode wiring portion 119 electrically connected to the temperature sensitive cathode region 181. The temperature sensitive cathode region 181 will be described below.

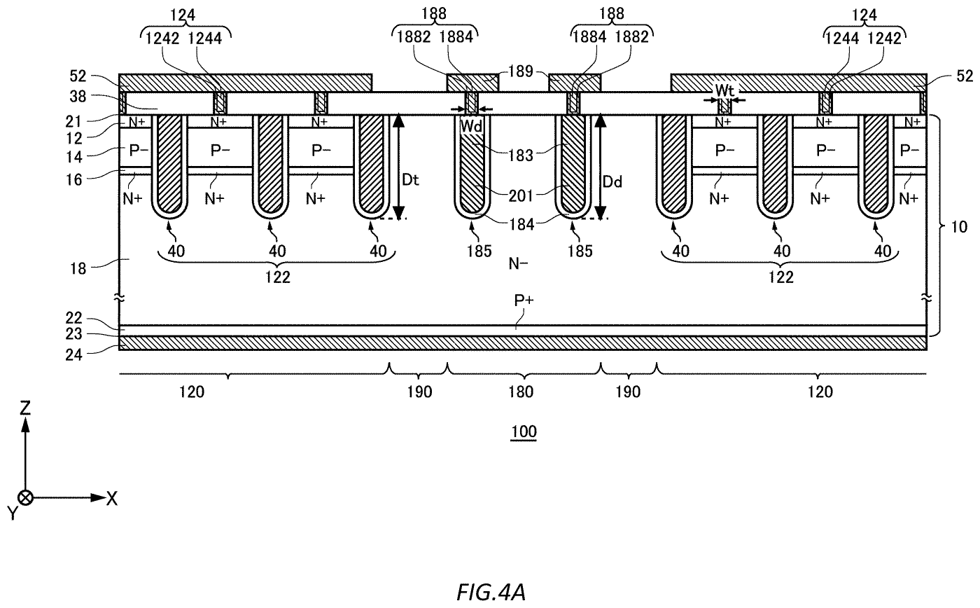

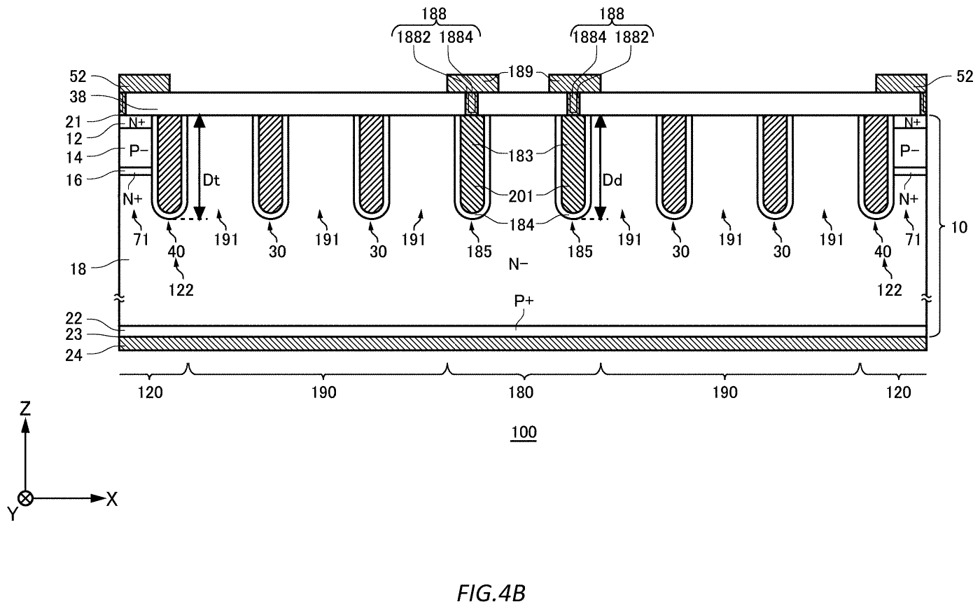

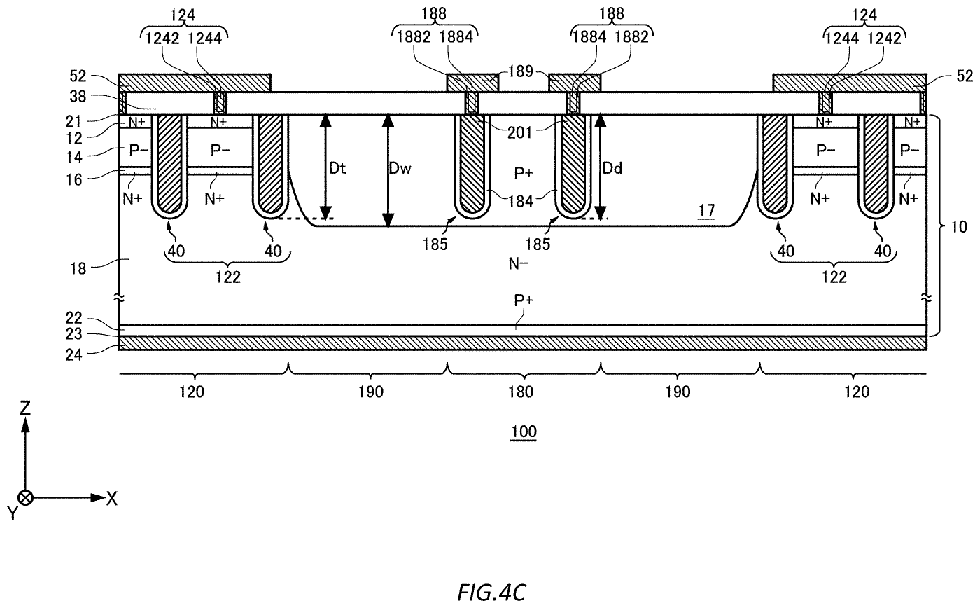

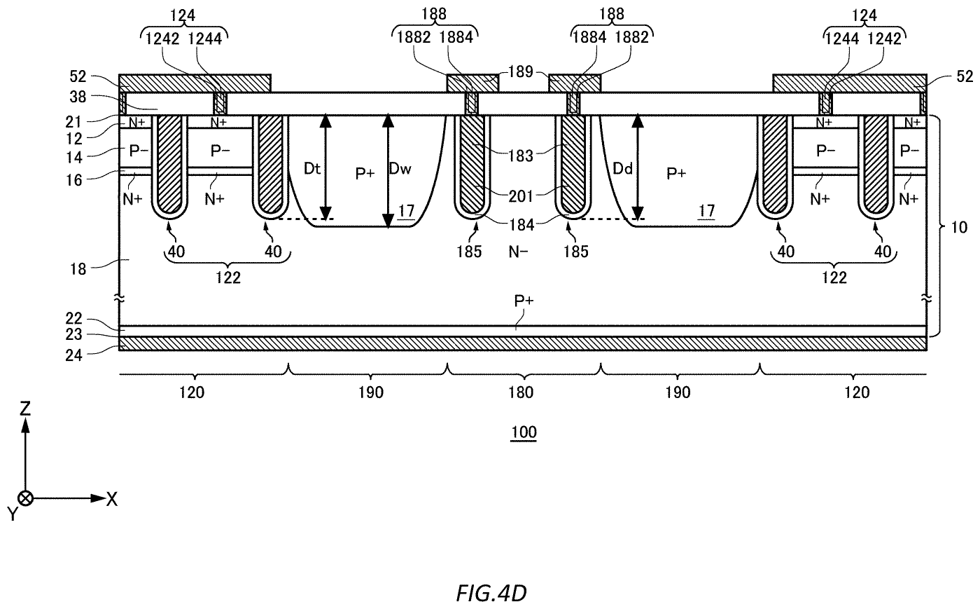

FIG. 4A illustrates an example of a cross section of the semiconductor device 100 including the temperature sensitive portion 180. The semiconductor device 100 may include a transition portion 190. The temperature sensitive portion 180 may include a temperature sensitive diode portion 183, a temperature sensitive trench portion 185, a temperature sensitive contact portion 188, and a temperature sensitive wiring portion 189. The temperature sensitive wiring portion 189 may include at least one of the anode wiring portion 117 or the cathode wiring portion 119. The temperature sensitive portion 180 and the transition portion 190 may include the base region 14. Accordingly, it is possible to prevent electric field strength on the temperature sensitive trench portion 185 of the temperature sensitive portion 180. The temperature sensitive portion 180 and the transition portion 190 may or may not include the accumulation region 16.

The temperature sensitive diode portion 183 includes a temperature sensitive trench conductive portion 201 inside the trench. The temperature sensitive trench conductive portion 201 is formed of a conductive material such as polysilicon. The temperature sensitive trench conductive portion 201 includes the temperature sensitive cathode region 181 and the temperature sensitive anode region 182. The temperature sensitive diode portion 183 may be a PN diode including a PN junction 300 where the temperature sensitive cathode region 181 and the temperature sensitive anode region 182 are in contact with each other. The temperature sensitive cathode region 181 and the temperature sensitive anode region 182 will be described below.

The temperature sensitive trench portion 185 is provided on the front surface 21 side of the semiconductor substrate. The temperature sensitive trench portion 185 may include a trench insulating portion 184 which covers an inner wall of the trench. The trench insulating portion 184 may be a semiconductor oxide film or a semiconductor nitride film. That is, the trench insulating portion 184 may be formed by oxidizing or nitriding the semiconductor on the inner wall of the trench. Due to the trench insulating portion 184, the temperature sensitive cathode region 181 and the temperature sensitive anode region 182 do not conduct with the p type region or the n type region formed in the semiconductor substrate 10.

A trench depth Dd of the temperature sensitive trench portion 185 may be the same as a trench depth Dt of the active trench portion 122. When the trench depth Dd of the temperature sensitive trench portion 185 and the trench depth Dt of the active trench portion 122 are the same, both trench portions can be simultaneously formed by a same etching step. A depth from the front surface 21 of the semiconductor substrate 10 to a lowermost depth position of the trench portion is defined as D, and an average value of the depths D of a plurality of trench portions is defined as Dₘₑₐₙ. A state where the trench depths are the same may be a state where the depth D of each trench portion is within 10% of the average value Dₘₑₐₙ.

The trench depth Dd of the temperature sensitive trench portion 185 may be different from the trench depth Dt of the active trench portion 122. The trench depth Dd of the temperature sensitive trench portion 185 may be deeper than the trench depth Dt of the active trench portion 122, or may be shallower than the trench depth Dt of the active trench portion 122. Note that the trench depth of the trench portion may be a depth at the deepest position of the trench portion.

By forming the temperature sensitive diode portion 183 inside the temperature sensitive trench portion 185, space saving of the temperature sensitive portion 180 can be realized. That is, since a junction surface of the PN junction 300 can be sufficiently secured in the depth direction of the semiconductor substrate 10 by the trench of the temperature sensitive trench portion 185, space saving in an in-plane direction of the semiconductor substrate can be realized while maintaining stable characteristics.

The temperature sensitive wiring portion 189 is provided above the interlayer dielectric film 38. The temperature sensitive wiring portion 189 may be electrically connected to the temperature sensitive trench portion 185. The temperature sensitive contact portion 188 is provided in the interlayer dielectric film 38. The temperature sensitive contact portion 188 may electrically connect the temperature sensitive wiring portion 189 and the temperature sensitive trench conductive portion 201 of the temperature sensitive trench portion 185. That is, the temperature sensitive wiring portion 189 may be electrically connected to the temperature sensitive diode portion 183 via the temperature sensitive contact portion 188. The temperature sensitive wiring portion 189 is electrically connected to the temperature sensitive cathode region 181 of the temperature sensitive diode portion 183. The temperature sensitive wiring portion 189 is electrically connected to the temperature sensitive anode region 182 of the temperature sensitive diode portion 183. The temperature sensitive wiring portion 189 may be the cathode wiring portion 119 or the anode wiring portion 117.

The temperature sensitive contact portion 188 may include a barrier metal film 1882 provided in the contact hole and a plug portion 1884. The barrier metal film 1882 of the temperature sensitive contact portion 188 may contain titanium, a titanium compound, or the like. The plug portion 1884 of the temperature sensitive contact portion 188 may contain a plug metal such as tungsten.

A contact width Wd of the temperature sensitive contact portion 188 may be the same as a contact width Wt of the active contact portion 124. A state where the contact widths are the same may mean that each of widths of a plurality of contact portions is within +10% of an average value of the widths of the plurality of contact portions. When the temperature sensitive contact portion 188 and the active contact portion 124 are formed in a same etching step, the contact width Wd of the temperature sensitive contact portion 188 and the contact width Wt of the active contact portion 124 are the same. However, the contact width Wd of the temperature sensitive contact portion 188 may be different from the contact width Wt of the active contact portion 124. The contact width Wd of the temperature sensitive contact portion 188 may be larger than the contact width Wt of the active contact portion 124, or may be smaller than the contact width Wt of the active contact portion 124. The contact portion may have a longitudinal direction and a short direction in top view. The contact width of the contact portion may be a width of the contact portion in the short direction. The contact width of the contact portion may be a largest width or a smallest width among the widths of the contact portion in the short direction in a plane parallel to the semiconductor substrate 10, or may be a width corresponding to half of the largest width or the smallest width.

In the depth direction of the semiconductor substrate 10, a height position of the upper surface of the interlayer dielectric film 38 in the active portion 120 may be the same as a height position of the upper surface of the interlayer dielectric film 38 in the temperature sensitive portion 180. A state where the height positions of the upper surface of the interlayer dielectric film 38 are the same may mean that a difference between a maximum value and a minimum value of the height positions of the upper surface of the interlayer dielectric film 38 is 10% or less of an average value of the height positions of the upper surface of the interlayer dielectric film 38. In this case, it may be said that the height position of the upper surface of the interlayer dielectric film 38 in the active portion 120 is substantially the same as the height position of the upper surface of the interlayer dielectric film 38 in the temperature sensitive portion 180. When the upper surfaces of both the interlayer dielectric film 38 in the active portion 120 and the interlayer dielectric film 38 in the temperature sensitive portion 180 are at a same height from the front surface 21 of the semiconductor substrate 10, no misalignment in a focal point of exposure occurs in a photolithography step. Accordingly, a dimensional tolerance of the interlayer dielectric film 38, the emitter electrode 52, or the like can be reduced. Furthermore, the active contact portion 124 and the temperature sensitive contact portion 188 can be formed with a same dimensional tolerance. Here, the term “same” is not limited to a case of being completely the same, and may include a case where there is a difference to an extent that misalignment in the focal point of exposure is tolerated in device design.

By forming the temperature sensitive contact portion 188 and the active contact portion 124 in the same etching step, it is possible to suppress spread of the active contact portion 124, and it is possible to suppress a short circuit failure or the like between the gate and the emitter. In addition, the temperature sensitive contact portion 188 and the active contact portion 124 are formed in the same etching step, the contact portions are formed to have a same shape, and embedding of the plug metal in the contact portion is improved. Accordingly, it is possible to prevent the plug metal from remaining during etch-back, and it is possible to improve a yield in manufacturing the semiconductor device 100. Note that the temperature sensitive contact portion 188 may be formed by a step different from that of the active contact portion 124.

The transition portion 190 is provided between the temperature sensitive portion 180 and the active portion 120. The transition portion 190 may be a region through which the principal current does not flow when the semiconductor device 100 is operated. When the principal current flows through the active portion 120, the current also circulates in the temperature sensitive portion 180, and a potential of the temperature sensitive portion 180 may become unstable. In this case, the principal current of the active portion 120 may affect an operation of the temperature sensitive portion 180. By providing the transition portion 190 between the active portion 120 and the temperature sensitive portion 180, the temperature sensitive portion 180 can accurately measure a temperature without being affected by the current flowing through the active portion 120.

FIG. 4B illustrates a cross section of a modification of the semiconductor device 100 including the temperature sensitive portion 180. The transition portion 190 in the present example is different from that in the example of FIG. 4A in including one or more dummy trench portions 30. In the present example, the difference from the example of FIG. 4A will be particularly described, and other configurations may be the same as those in the example of FIG. 4A.

The transition portion 190 includes one or more dummy trench portions 30 provided on the front surface 21 side of the semiconductor substrate 10. Each transition portion 190 in the present example has two dummy trench portions 30 in the array direction of the trench portions. A potential of the dummy trench portion 30 provided in the transition portion 190 may be an emitter potential or a potential different from a potential of the gate trench portion 40. The potential of the dummy trench portion 30 may be a floating potential, where the potential is not fixed. The mesa portion 191 of the transition portion 190 may or may not be connected to the emitter electrode 52.

The transition portion 190 includes a mesa portion 191 sandwiched between the temperature sensitive trench portion 185 and the dummy trench portion 30. The transition portion 190 may include the mesa portion 191 sandwiched between two dummy trench portions 30 adjacent to each other. Providing the dummy trench portion 30 in the transition portion 190 can suppress the electric field strength at a bottom portion of the temperature sensitive trench portion 185.

FIG. 4C illustrates a cross section of a modification of the semiconductor device 100 including the temperature sensitive portion 180. The semiconductor device 100 in the present example is different from those in the examples of FIGS. 4A and 4B in that the well region 17 is provided in the temperature sensitive portion 180 and the transition portion 190. In the present example, the difference from the examples of FIGS. 4A and 4B will be particularly described, and other configurations may be the same as those in the examples of FIGS. 4A and/or 4B.

The well region 17 may be provided on the peripheral side of the active portion 120. The well region 17 may be provided in the temperature sensitive portion 180 and the transition portion 190. The well region 17 may be in contact with a trench portion in contact with the transition portion 190 and the active portion 120. The well region 17 in the present example is in contact with the gate trench portion 40. The trench portion in contact with the transition portion 190 and the active portion 120 may be the dummy trench portion 30, and the well region 17 may be in contact with the dummy trench portion 30.

The temperature sensitive trench portion 185 may be provided inside the well region 17 in top view. At least one of a side wall or the bottom portion of the temperature sensitive trench portion 185 may be in contact with the well region 17, and both the side wall or the bottom portion of the temperature sensitive trench portion 185 may be in contact with the well region 17. A depth Dw of the well region 17 may be deeper than the depth Dd of the temperature sensitive trench portion 185 in the depth direction of the semiconductor substrate 10. In addition, the depth Dw of the well region 17 may be deeper than the depth Dt of the active trench portion 122.

The well region 17 may be provided from one transition portion 190 to another transition portion 190 in the array direction of the trench portions (X axis direction), the transition portions 190 opposing each other with the temperature sensitive portion 180 interposed therebetween.

The well region 17 may be deeper than the temperature sensitive trench portion 185 and may cover the bottom portion of the temperature sensitive trench portion 185.

FIG. 4D illustrates a cross section of a modification of the semiconductor device 100 including the temperature sensitive portion 180. The well region 17 in the present example is different from that in the example of FIG. 4C in that the well region 17 is not provided in the temperature sensitive portion 180. In the present example, the difference from the example of FIG. 4C will be particularly described, and other configurations may be the same as those in the example of FIG. 4C.

The transition portion 190 includes the well region 17 of the second conductivity type provided in the semiconductor substrate 10. The well region 17 may be provided in each of the transition portions 190 opposing each other with the temperature sensitive portion 180 interposed therebetween. The well region 17 may terminate so as to cover the bottom portion of the temperature sensitive trench portion 185.

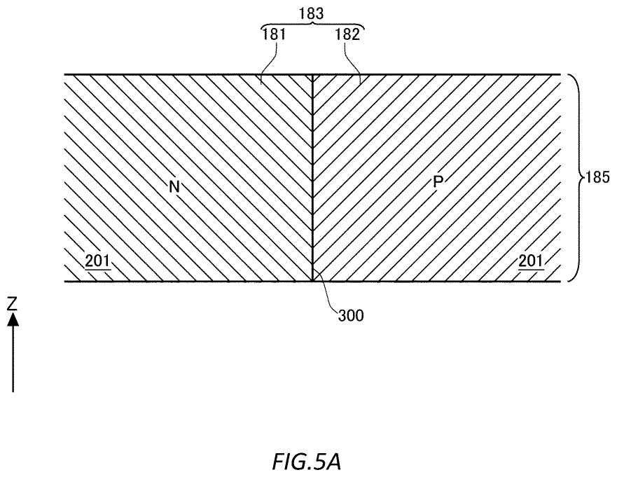

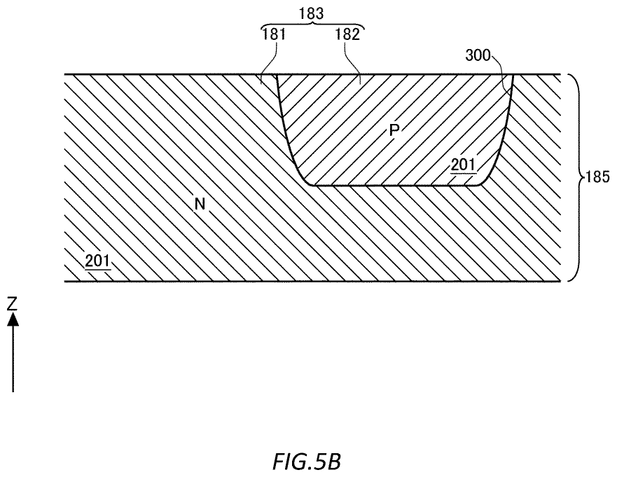

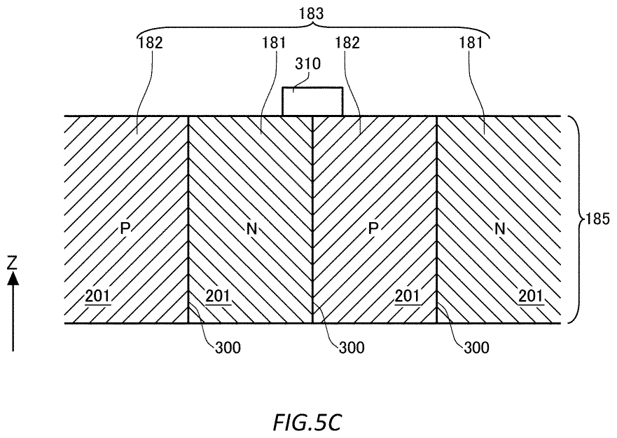

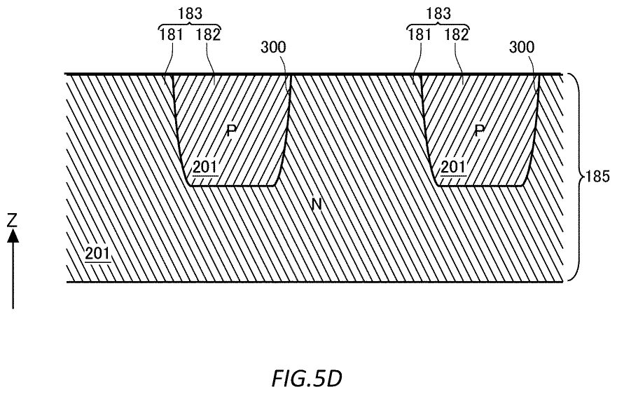

FIG. 5A illustrates an example of a cross section of the temperature sensitive trench portion 185. The cross section in the present drawing may be an XZ cross section, a YZ cross section, or any cross section parallel to the Z axis direction. That is, the cross section in the present drawing may be any cross section parallel to the depth direction of the semiconductor substrate 10. A relationship between arrangement of the temperature sensitive trench portion 185 and a cross-sectional direction will be described below.

The temperature sensitive diode portion 183 includes the temperature sensitive anode region 182 and the temperature sensitive cathode region 181 provided in the temperature sensitive trench conductive portion 201. The temperature sensitive diode portion 183 may be a PN diode including the PN junction 300 where the temperature sensitive cathode region 181 and the temperature sensitive anode region 182 are in contact with each other. The temperature sensitive cathode region 181 is formed of a semiconductor of the N type and may function as a cathode of the PN diode. The temperature sensitive anode region 182 is formed of a semiconductor of the P type, and may function as an anode of the PN diode. Materials of the temperature sensitive cathode region 181 and the temperature sensitive anode region 182 may be a polycrystalline semiconductor, and may be polysilicon as an example. The junction surface of the PN junction 300 in the present example may be formed as follows. Doped polysilicon of one conductivity type (the N type in the present example) is deposited as the temperature sensitive trench conductive portion 201, and then a dopant of another conductivity type (the P type in the present example) is ion-implanted. Thereafter, the dopant of another conductivity type is diffused so as to reach a lower end of the temperature sensitive trench conductive portion 201 in the depth direction.

The temperature sensitive anode region 182 and the temperature sensitive cathode region 181 may be provided in the temperature sensitive trench conductive portion 201 with which an inside of the trench of the temperature sensitive trench portion 185 is filled. The temperature sensitive trench conductive portion 201 may have only the temperature sensitive anode region 182 and the temperature sensitive cathode region 181. The temperature sensitive trench conductive portion 201 may be filled with another component in addition to the temperature sensitive anode region 182 and the temperature sensitive cathode region 181. As an example, the temperature sensitive trench conductive portion 201 may include an intrinsic semiconductor in contact with the temperature sensitive cathode region 181 or the temperature sensitive anode region 182.

A side wall of the temperature sensitive anode region 182 may be in contact with a side wall of the temperature sensitive cathode region 181. The temperature sensitive anode region 182 and the temperature sensitive cathode region 181 may include the junction surface of the PN junction 300 extending in a direction parallel to the Z axis direction, or may include the junction surface of the PN junction 300 extending in a direction having an inclination with respect to the Z axis direction.

FIG. 5B illustrates a cross section of a modification of the temperature sensitive trench portion 185. The cross section in the present drawing may also be any cross section parallel to the depth direction of the semiconductor substrate 10.

The PN junction 300 where the temperature sensitive anode region 182 and the temperature sensitive cathode region 181 are in contact with each other may have a bottom surface parallel to the upper surface of the temperature sensitive trench conductive portion 201. The PN junction 300 where the temperature sensitive anode region 182 and the temperature sensitive cathode region 181 are in contact with each other may be curved from the bottom surface and may be in contact with the upper surface of the temperature sensitive trench conductive portion 201. That is, both one end portion and another end portion of the PN junction 300 where the temperature sensitive anode region 182 and the temperature sensitive cathode region 181 are in contact with each other may be exposed to the upper surface of the temperature sensitive trench conductive portion 201. One of the temperature sensitive anode region 182 and the temperature sensitive cathode region 181 may be in contact with an upper surface of another thereof. In the present example, a lower surface of the temperature sensitive anode region 182 is in contact with an upper surface of the temperature sensitive cathode region 181. As an example, the junction surface of the PN junction 300 in the present example may be formed as follows. Doped polysilicon of one conductivity type (the N type in the present example) is deposited as the temperature sensitive trench conductive portion 201, and then a dopant of another conductivity type (the P type in the present example) is ion-implanted. Thereafter, the dopant of another conductivity type is diffused to a depth not reaching the lower end of the temperature sensitive trench conductive portion 201 in the depth direction. As in the present example, the temperature sensitive anode region 182 may be provided inside the temperature sensitive cathode region 181. Alternatively, the temperature sensitive cathode region 181 may be provided inside the temperature sensitive anode region 182.

FIG. 5C illustrates a cross section of a modification of the temperature sensitive trench portion 185. The cross section in the present drawing may also be any cross section parallel to the depth direction of the semiconductor substrate 10. The temperature sensitive diode portion 183 in the present example includes a short wiring portion 310. The short wiring portion 310 will be described below.

The present example is different from the example of FIG. 5A in that a plurality of temperature sensitive anode regions 182 and a plurality of temperature sensitive cathode regions 181 are provided in the temperature sensitive trench conductive portion 201. A plurality of PN junctions 300 between the temperature sensitive cathode region 181 and the temperature sensitive anode region 182 may be provided. The plurality of temperature sensitive anode regions 182 and the plurality of temperature sensitive cathode regions 181 may be alternately arrayed in the temperature sensitive trench conductive portion 201 in a direction parallel to the front surface of the semiconductor substrate 10. The plurality of temperature sensitive anode regions 182 and the plurality of temperature sensitive cathode regions 181 may be alternately arrayed in any cross section parallel to the depth direction of the semiconductor substrate 10 in the temperature sensitive trench conductive portion 201. A series connection of two or more diodes can be formed in one temperature sensitive trench portion 185.

FIG. 5D illustrates a cross section of a modification of the temperature sensitive trench portion 185. The present example is different from the example of FIG. 5B in that a plurality of temperature sensitive anode regions 182 are provided in the temperature sensitive trench conductive portion 201. A plurality of PN junctions 300 between the temperature sensitive cathode region 181 and the temperature sensitive anode region 182 may be provided. As in the present example, a plurality of temperature sensitive anode regions 182 may be provided inside the temperature sensitive cathode region 181. Alternatively, a plurality of temperature sensitive cathode regions 181 may be provided inside the temperature sensitive anode region 182. A connection in which two or more diodes are branched can be formed in one temperature sensitive trench portion 185.

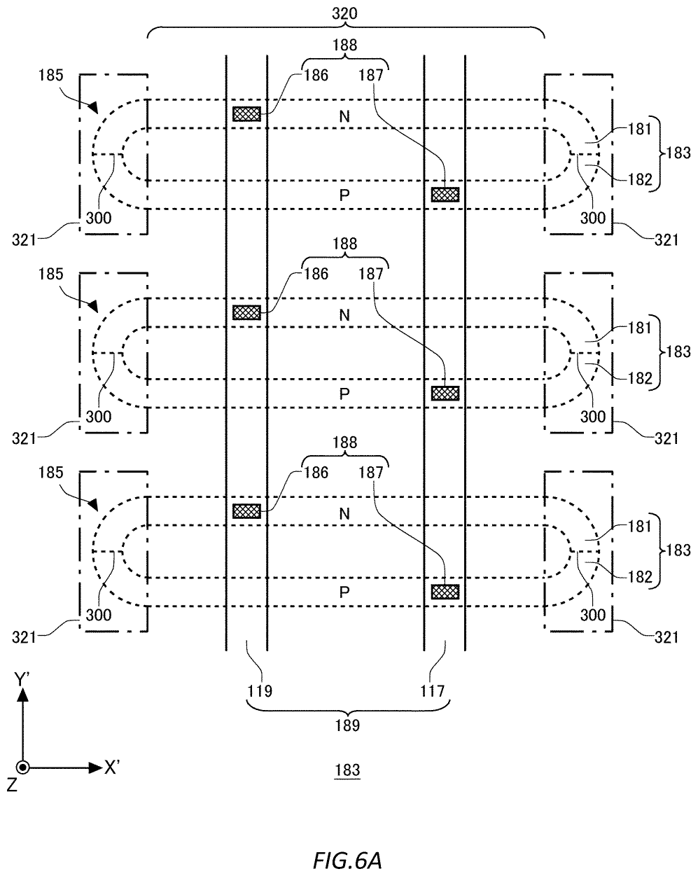

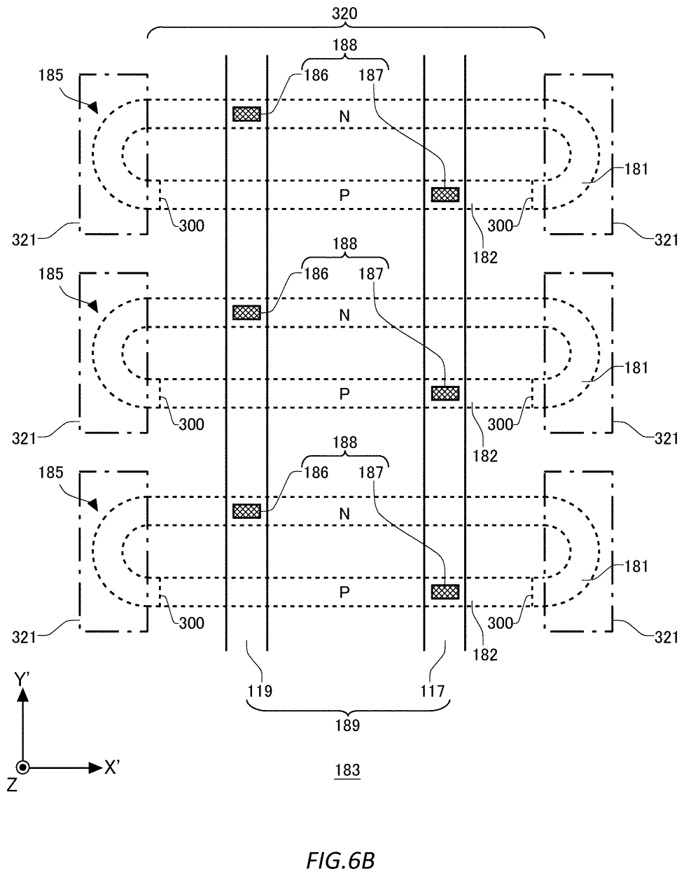

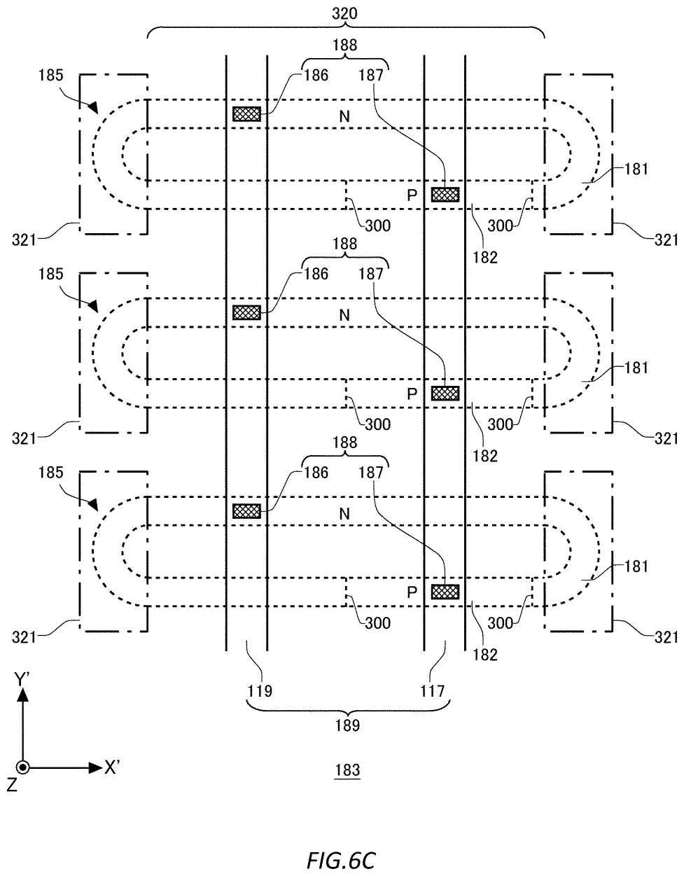

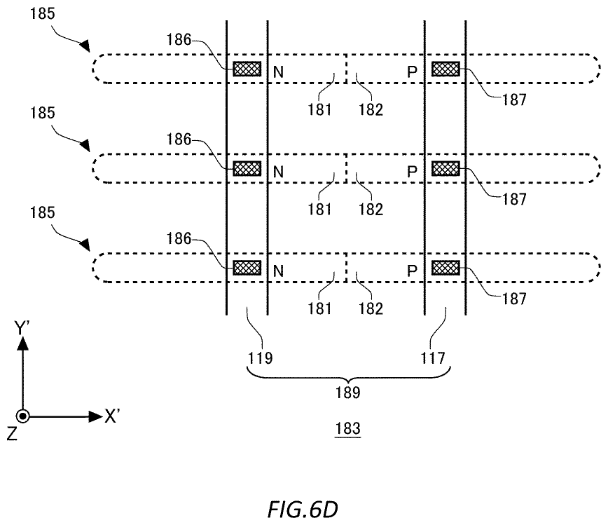

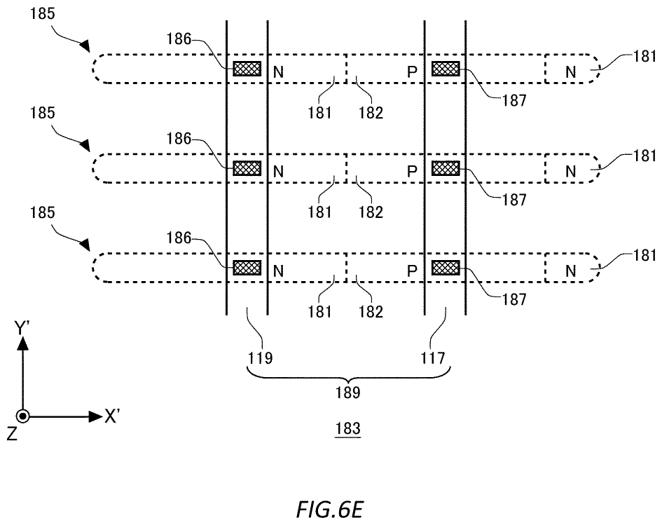

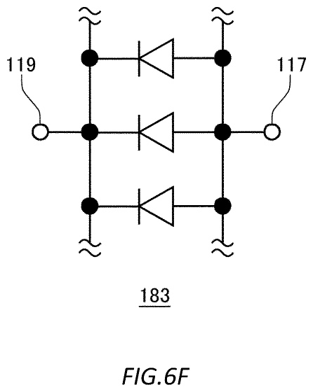

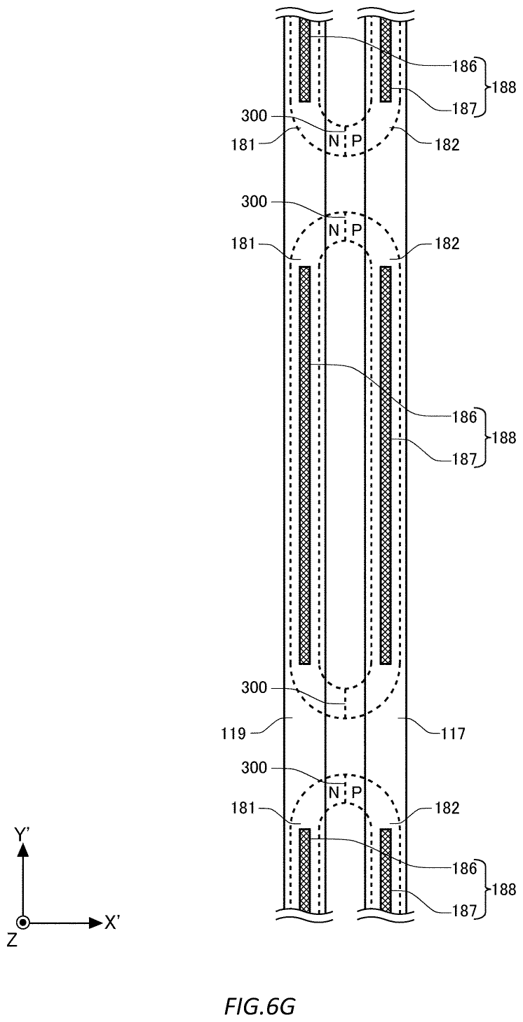

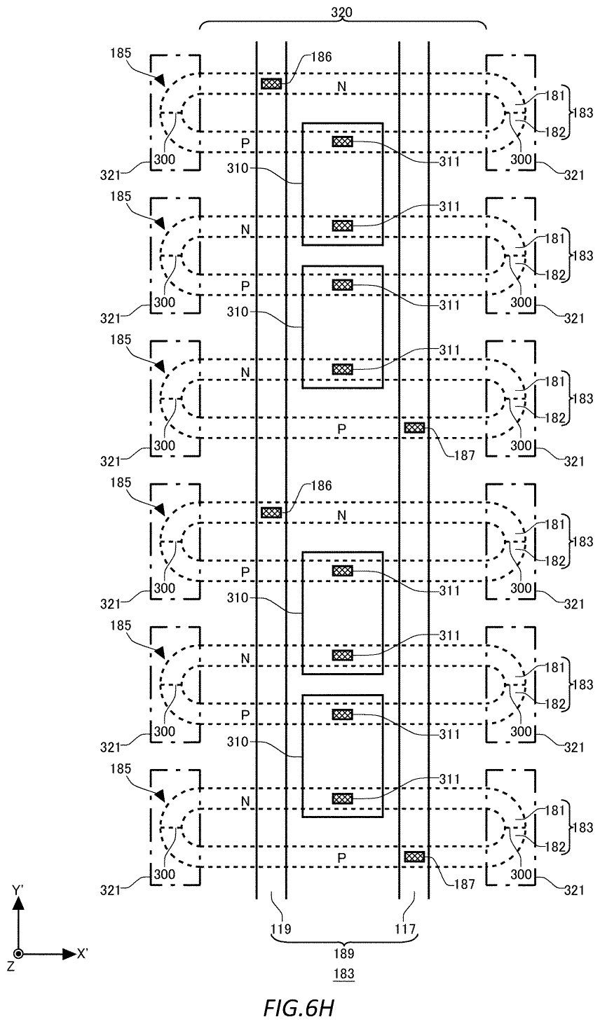

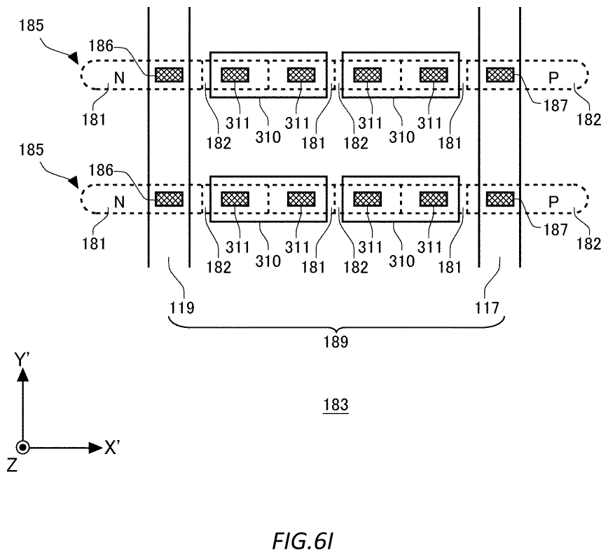

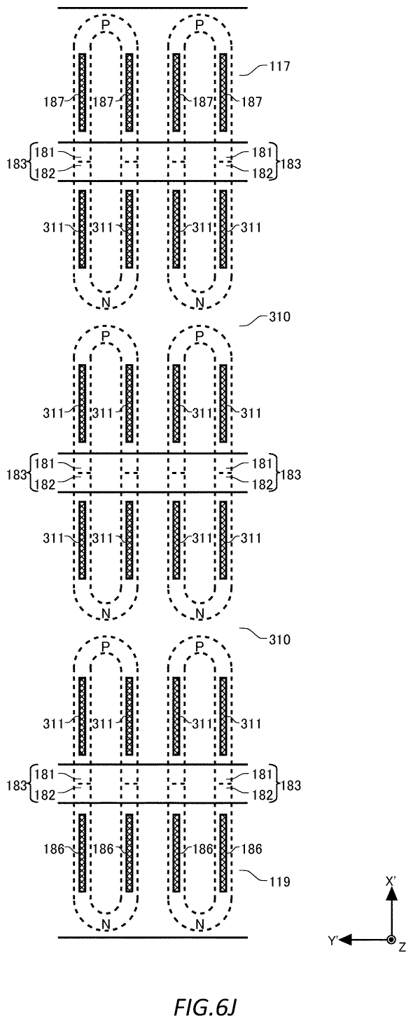

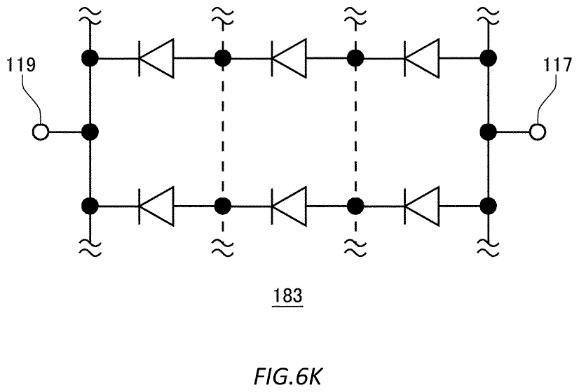

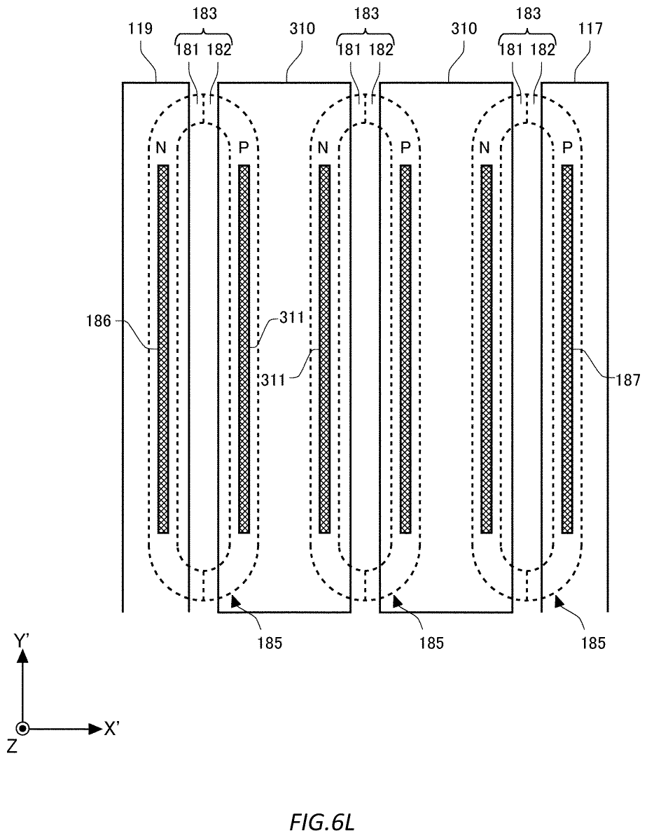

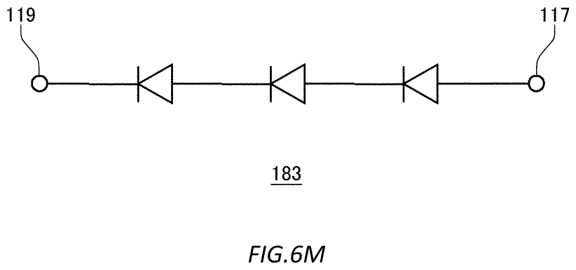

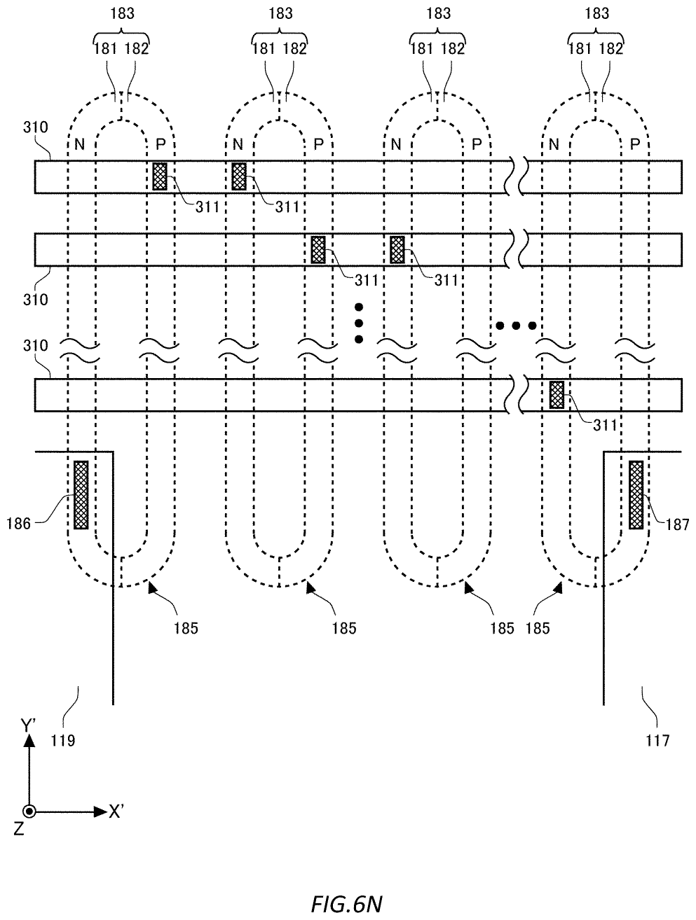

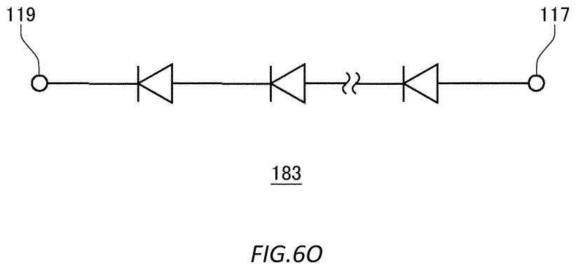

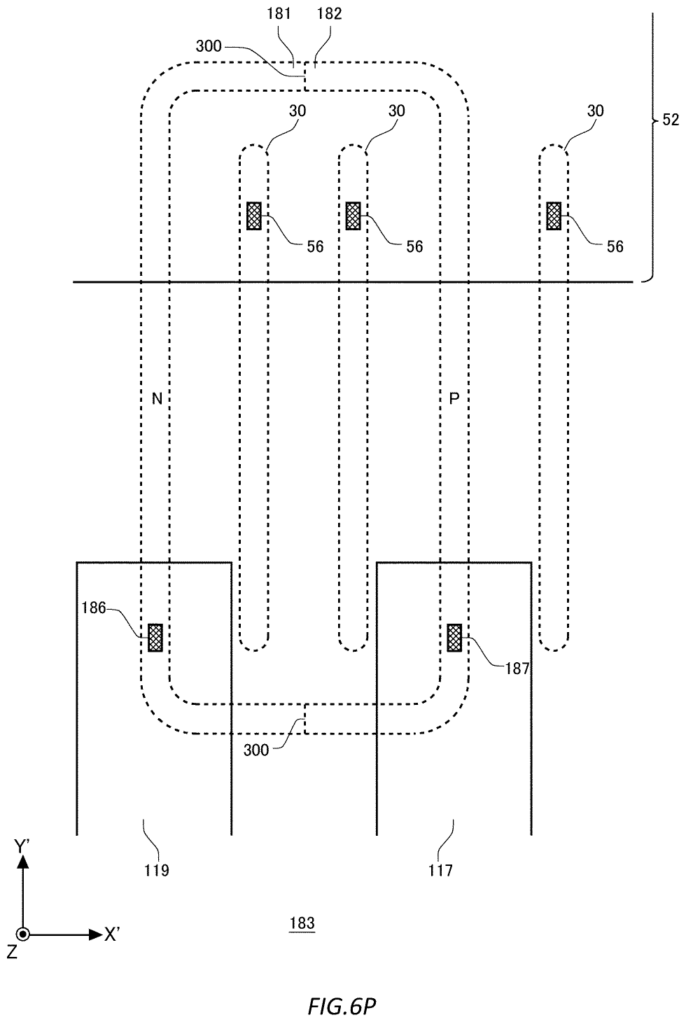

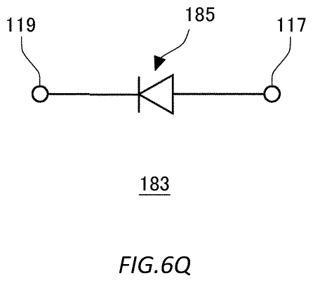

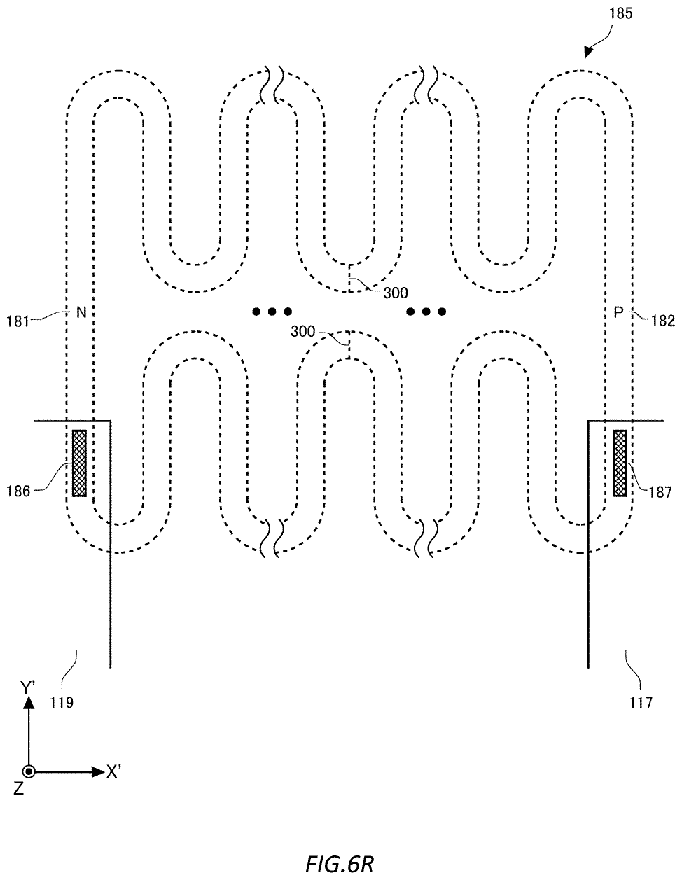

FIG. 6A illustrates an example of an enlarged top view of the temperature sensitive diode portion 183 in the temperature sensitive portion 180 of a region T in FIG. 3. In the present example, only some members of the semiconductor device 100 are illustrated, and illustration of some members is omitted. In the present drawing, the Z axis which is a direction parallel to the depth direction of the semiconductor substrate 10, an X′ axis which is a direction in which the cathode wiring portion 119 and the anode wiring portion 117 are spaced apart, and a Y′ axis which is orthogonal thereto are illustrated.

The temperature sensitive contact portion 188 includes an anode contact portion 187 and a cathode contact portion 186. The anode contact portion 187 may be provided on the interlayer dielectric film 38 to electrically connect the anode wiring portion 117 and the temperature sensitive anode region 182. The cathode contact portion 186 may be provided on the interlayer dielectric film 38 to electrically connect the cathode wiring portion 119 and the temperature sensitive cathode region 181. The interlayer dielectric film 38 is omitted in FIG. 6A.

The temperature sensitive trench portion 185 includes one or a plurality (two or more) of temperature sensitive trench portion(s) 185. The anode contact portion 187 may have a plurality of anode contact portions 187 respectively provided corresponding to the plurality of temperature sensitive trench portions 185. The cathode contact portion 186 may include a plurality of cathode contact portions 186 respectively provided corresponding to the plurality of temperature sensitive trench portions 185. The anode wiring portion 117 may be provided to extend above the plurality of temperature sensitive trench portions 185 and electrically connected to the plurality of anode contact portions 187. The cathode wiring portion 119 may be provided to extend above the plurality of temperature sensitive trench portions 185 and electrically connected to the plurality of cathode contact portions 186. In the present example, the plurality of temperature sensitive trench portions 185 are connected in parallel between the anode wiring portion 117 and the cathode wiring portion 119.

The temperature sensitive trench portion 185 may have a loop structure in which one end of the temperature sensitive trench portion 185 is connected to another end thereof. A cross section, which is parallel to the depth direction of the semiconductor substrate 10, in a direction along the loop structure of the temperature sensitive trench portion 185 in the present example may be the cross section illustrated in FIG. 5A or 5B. That is, the PN junction 300 of the temperature sensitive anode region 182 and the temperature sensitive cathode region 181 in the present example may be formed as illustrated in FIG. 5A, or may be formed as illustrated in FIG. 5B.

In the present example, the anode wiring portion 117 and the cathode wiring portion 119 are provided apart from each other in an X′ axis direction. The X′ axis direction may be parallel to, intersect with, or be perpendicular to a longitudinal direction of the temperature sensitive trench portion 185. The X′ axis direction in the present example is parallel to the longitudinal direction of the temperature sensitive trench portion 185. Since an extending direction of the temperature sensitive wiring portion 189 in the present example is perpendicular to the longitudinal direction of the temperature sensitive trench portion 185, it is easy to separate the anode wiring portion 117 and the cathode wiring portion 119 from each other, and insulation can be easily secured. In addition, the anode wiring portion 117 and the cathode wiring portion 119 can be formed with a sufficient width.

In the present example, the temperature sensitive wiring portion 189 extends in a Y′ axis direction. The Y′ axis direction which is the extending direction of the temperature sensitive wiring portion 189 may or may not coincide with the Y axis direction which is the longitudinal direction of the active trench portion 122. The Y′ axis direction which is the extending direction of the temperature sensitive wiring portion 189 in the present example coincides with the Y axis direction which is an extending direction of the active trench portion 122.

The anode contact portion 187 and the cathode contact portion 186 of the temperature sensitive contact portion 188 may be provided at different positions in the extending direction (Y′ axis direction) of the temperature sensitive wiring portion 189. In the present example, the cathode contact portion 186 is provided above the anode contact portion 187 (a positive direction of the Y′ axis direction). Accordingly, it becomes easy to identify whether the temperature sensitive contact portions 188 is the anode contact portion 187 or the cathode contact portion 186, whereby erroneous wiring can be prevented.

Note that in the present example, the anode wiring portion 117 and the cathode wiring portion 119 extend in parallel with the Y axis direction, but the present invention is not limited thereto. The same also applies to a modification described below. For example, the arrangement is not limited to that of FIG. 3, and the Y′ axis direction in which the anode wiring portion 117 and the cathode wiring portion 119 extend may coincide with the X axis direction. In a case of a relationship in the present example in which longitudinal directions of the temperature sensitive wiring portion 189 and the temperature sensitive trench portion 185 are orthogonal to each other, the longitudinal direction of the temperature sensitive trench portion 185 coincides with the extending direction of the active trench portion 122. At this time, the longitudinal directions of the temperature sensitive trench portion 185 and the active trench portion 122 are aligned, whereby both trench portions can be stably formed. In addition, the anode wiring portion 117 and the cathode wiring portion 119 may extend in opposite directions to each other on a same axis. In addition, the anode pad 116 and the cathode pad 118 may be provided in the temperature sensitive portion 180. That is, the anode pad 116 and the temperature sensitive anode region 182 may be electrically connected via the anode contact portion 187 without involving the anode wiring portion 117, and the cathode pad 118 and the temperature sensitive cathode region 181 may be electrically connected via the cathode contact portion 186 without involving the cathode wiring portion 119. The anode pad 116 and the cathode pad 118 may be arranged side by side together with the temperature sensitive portion 180 on one side of the semiconductor device 100. Alternatively, the anode pad 116 and the cathode pad 118 may be arranged on facing sides of the semiconductor device 100, respectively. Alternatively, the anode pad 116 and the cathode pad 118 may be arranged differently from the above.

The longitudinal direction of the temperature sensitive trench portion 185 may be parallel to, intersect with, or be perpendicular to the extending direction of the active trench portion 122. The longitudinal direction of the temperature sensitive trench portion 185 in the present example is the X axis direction, and is perpendicular to the Y axis direction which is the extending direction of the active trench portion 122.

FIG. 6B is an enlarged top view illustrating another example of the temperature sensitive diode portion 183 in the temperature sensitive portion 180. FIG. 6B is different from FIG. 6A in that a position of the PN junction 300 is different. The PN junctions 300 in the present example are provided between a linear portion 320 and a curved portion 321 of the temperature sensitive trench portion 185. The PN junction 300 in the present example may be formed as illustrated in FIG. 5A or 5B.

FIG. 6C is an enlarged top view illustrating another example of the temperature sensitive diode portion 183 in the temperature sensitive portion 180. FIG. 6C is different from FIG. 6A in that the position of the PN junction 300 is different. The PN junctions 300 in the present example are provided both at a position between the linear portion 320 and the curved portion 321 of the temperature sensitive trench portion 185 and at the linear portion 320 of the temperature sensitive trench portion 185. The PN junction 300 in the present example may be formed as illustrated in FIG. 5A or 5B.

FIG. 6D is an enlarged top view illustrating another example of the temperature sensitive diode portion 183 in the temperature sensitive portion 180. FIG. 6D is different from FIG. 6A in that a shape of the temperature sensitive trench portion 185, the position of the PN junction 300, and positions of the anode contact portion 187 and the cathode contact portion 186 are different. The temperature sensitive trench portion 185 has a linear structure. The cathode contact portion 186 is provided above the temperature sensitive cathode region 181. The cathode wiring portion 119 is electrically connected to the temperature sensitive cathode region 181 via the cathode contact portion 186. The anode contact portion 187 is provided above the temperature sensitive anode region 182. The anode wiring portion 117 is electrically connected to the temperature sensitive anode region 182 via the anode contact portion 187.

One PN junction 300 is formed between the temperature sensitive cathode region 181 and the temperature sensitive anode region 182. The PN junction 300 in the present example may be formed as illustrated in FIG. 5A or 5B.

FIG. 6E is an enlarged top view illustrating another example of the temperature sensitive diode portion 183 in the temperature sensitive portion 180. FIG. 6E is different from FIG. 6D in that a number and the positions of the PN junctions 300 of the temperature sensitive trench conductive portion 201 are different. The PN junctions 300 in the present example are formed at a central portion and an end portion of the temperature sensitive trench portion 185. The central portion of the temperature sensitive trench portion 185 may be a part sandwiched between the cathode wiring portion 119 and the anode wiring portion 117. The end portion of the temperature sensitive trench portion 185 may be, in an extending direction of the the temperature sensitive trench portion 185 (X axis direction), a part in a negative direction of the X axis direction relative to the cathode wiring portion 119 or a part in a positive direction of the X axis direction relative to the anode wiring portion 117. The end portion of the temperature sensitive trench portion 185 where the PN junction 300 in the present example is provided is a part in the positive direction of the X axis direction relative to the anode wiring portion 117. The PN junction 300 in the present example may be formed as illustrated in FIG. 5A or 5B.

FIG. 6F illustrates an equivalent circuit of the temperature sensitive diode portion 183 illustrated in FIGS. 6A, 6B, 6C, 6D, and 6E. In the temperature sensitive diode portion 183 in the present example, one PN diode or a plurality (two or more) of PN diodes are connected in parallel between the cathode wiring portion 119 and the anode wiring portion 117.

FIG. 6G is an enlarged top view illustrating another example of the temperature sensitive diode portion 183 in the temperature sensitive portion 180. The temperature sensitive trench portion 185 in the present example is different from the example of FIG. 6A in that its longitudinal direction is perpendicular to the X′ axis direction which is a direction in which the anode wiring portion 117 and the cathode wiring portion 119 are spaced apart. Other configurations may be the same as those in the example of FIG. 6A.

The longitudinal direction of the temperature sensitive trench portion 185 in the present example is the Y′ axis direction. In the present example, the temperature sensitive wiring portion 189 extends in the Y′ axis direction. The Y′ axis direction which is the extending direction of the temperature sensitive wiring portion 189 may or may not coincide with the Y axis direction which is the longitudinal direction of the active trench portion 122. The Y′ axis direction which is the extending direction of the temperature sensitive wiring portion 189 in the present example coincides with the Y axis direction which is the extending direction of the active trench portion 122. At this time, the longitudinal directions of the temperature sensitive trench portion 185 and the active trench portion 122 are aligned, whereby both trench portions can be stably formed. By aligning the longitudinal direction of the temperature sensitive trench portion 185, the longitudinal direction of the active trench portion 122, and the extending direction of the temperature sensitive wiring portion 189, the temperature sensitive portion 180 can be formed in a small region.

A length of the temperature sensitive contact portion 188 in the extending direction of the temperature sensitive trench portion 185 may be larger than a width thereof in a direction (X′ axis direction) perpendicular to the extending direction of the temperature sensitive trench portion 185. As in the present example, the length of the temperature sensitive contact portion 188 may be provided long over a range in which the temperature sensitive trench portion 185 is a linear part.

The equivalent circuit of the temperature sensitive diode portion 183 illustrated in FIG. 6G is illustrated in FIG. 6F. In the present example, in the temperature sensitive diode portion 183, one PN diode or a plurality (two or more) of PN diodes are connected in parallel between the cathode wiring portion 119 and the anode wiring portion 117. In the present example, a plurality of temperature sensitive trench portions 185 spaced apart in the Y′ axis direction can be connected in parallel.

FIG. 6H is an enlarged top view illustrating another example of the temperature sensitive diode portion 183 in the temperature sensitive portion 180. FIG. 6H is different from FIG. 6A in that a plurality of temperature sensitive trench portions 185 spaced apart in the Y′ axis direction are connected in series by a plurality of short wiring portions 310 and a plurality of short contact portions 311. One cathode contact portion 186 is provided only in the temperature sensitive trench portion 185 at one end (+Y′ axis direction) in the array direction (Y′ axis direction) in which the temperature sensitive trench portions 185 are arrayed. One anode contact portion 187 is provided only in the temperature sensitive trench portion 185 at another end (−Y′ axis direction) in the array direction (Y′ axis direction) in which the temperature sensitive trench portions 185 are arrayed.

The short wiring portion 310 is provided on an upper surface side of the temperature sensitive diode portion 183. The short wiring portion 310 may be formed of a material similar to that of the anode wiring portion 117 or the cathode wiring portion 119. The short wiring portion 310 is provided between the anode wiring portion 117 and the cathode wiring portion 119. The short wiring portion 310 is not in contact with the anode wiring portion 117 and the cathode wiring portion 119.

The short contact portion 311 is provided in the interlayer dielectric film 38 located below the short wiring portion 310. The short contact portion 311 is located on an upper surface of the temperature sensitive trench conductive portion 201. Only one short contact portion 311 is provided only in either one of the temperature sensitive cathode region 181 or the temperature sensitive anode region 182 in one loop-shaped temperature sensitive trench portion 185. In the temperature sensitive trench portions 185 adjacent to each other, polarities of the temperature sensitive trench conductive portions 201 provided with the short contact portions 311 are different. That is, when the short contact portion 311 in one temperature sensitive trench portion 185 is provided on the temperature sensitive cathode region 181, the short contact portion 311 in another temperature sensitive trench portion 185 adjacent to the one temperature sensitive trench portion 185 is provided on the temperature sensitive anode region 182. The short wiring portion 310 is provided so as to straddle two loop-shaped temperature sensitive trench portions 185 adjacent to each other, and short-circuits the temperature sensitive cathode region 181 and the temperature sensitive anode region 182 of the different temperature sensitive trench portions 185 to electrically cause a same potential. Therefore, the temperature sensitive diode portion 183 including N temperature sensitive trench portions 185 is provided with N PN diodes connected in series. A number of the PN diodes connected in series may be 2 or more, 5 or more, or 10 or more. The number of the PN diodes connected in series may be 100 or less, 50 or less, or 20 or less. Connecting a plurality of PN diodes in series can increase a potential difference for sensing a temperature, whereby a sensing accuracy is improved.

A plurality of short wiring portions 310 in the present example are arranged apart from each other in the Y′ axis direction, but one short wiring portion 310 may be arranged, or a plurality of short wiring portions may be arranged apart from each other in the X′ axis direction. In addition, the plurality of PN diodes connected in series may be connected in parallel by repeatedly placing, in the Y′ axis direction, an array from the temperature sensitive trench portion 185 including the cathode contact portion 186 to the temperature sensitive trench portion 185 including the anode contact portion 187. At this time, the short wiring portion 310 may connect one temperature sensitive anode region 182 and one temperature sensitive cathode region 181, or may connect a plurality of temperature sensitive anode regions 182 and a plurality of temperature sensitive cathode regions 181 in parallel.

The plurality of temperature sensitive trench portions 185 may consist only of the temperature sensitive trench portions 185 having a loop structure, may consist only of the temperature sensitive trench portions 185 having a linear structure, or may consist of both the temperature sensitive trench portions 185 having a loop structure and the temperature sensitive trench portions 185 having a linear structure. In addition, the temperature sensitive trench portion 185 may have a structure other than the loop structure and the linear structure.

FIG. 6I is an enlarged top view illustrating another example of the temperature sensitive diode portion 183 in the temperature sensitive portion 180. FIG. 6I is different from FIG. 6H in that the number and positions of the PN junctions 300 of the temperature sensitive trench conductive portion 201 are different, and that the short wiring portion 310 and the short contact portion 311 are included.

In the temperature sensitive diode portion 183 in the present example, two or more temperature sensitive trench portions 185 are provided in which a plurality of PN junctions 300 are formed in one trench as illustrated in FIG. 5C. Three or more temperature sensitive trench portions 185 may be provided, or four or more temperature sensitive trench portions may be provided. In each temperature sensitive trench portion 185, five PN junctions 300 are provided. That is, three temperature sensitive anode regions 182 are provided in the temperature sensitive trench conductive portion 201 of one temperature sensitive trench portion 185, and at least one end or another end of each temperature sensitive anode region 182 is in contact with the temperature sensitive cathode region 181. In addition, three temperature sensitive cathode regions 181 are provided in the temperature sensitive trench conductive portion 201 of one temperature sensitive trench portion 185, and at least one end or another end of each temperature sensitive cathode region 181 is in contact with the temperature sensitive anode region 182. In the present example, three regions of PNPN are formed in the temperature sensitive trench conductive portion 201 of one temperature sensitive trench portion 185.

The anode wiring portion 117 is provided on the upper surface side of the temperature sensitive diode portion 183, and in each temperature sensitive trench portion 185, the anode wiring portion 117 is in contact with the temperature sensitive anode region 182 via the anode contact portion 187. That is, the anode wiring portion 117 is electrically connected to the temperature sensitive anode region 182. The cathode wiring portion 119 is provided on the upper surface side of the temperature sensitive diode portion 183, and in each temperature sensitive trench portion 185, the cathode wiring portion 119 is in contact with the temperature sensitive cathode region 181 via the cathode contact portion 186. That is, the cathode wiring portion 119 is electrically connected to the temperature sensitive cathode region 181.

The short wiring portion 310 is provided on the upper surface side of the temperature sensitive diode portion 183. The short wiring portion 310 may be formed of a material similar to that of the anode wiring portion 117 or the cathode wiring portion 119. The short wiring portion 310 is provided between the anode wiring portion 117 and the cathode wiring portion 119. The short wiring portion 310 is not in contact with the anode wiring portion 117 and the cathode wiring portion 119.

The short contact portion 311 is provided in the interlayer dielectric film 38 located below the short wiring portion 310. The short contact portion 311 is located on the upper surface of the temperature sensitive trench conductive portion 201. The short contact portion 311 overlaps with the temperature sensitive anode region 182 or the temperature sensitive cathode region 181 in each temperature sensitive trench portion 185 in plan view. In one temperature sensitive trench portion 185, the short contact portions 311 are provided on the upper surfaces of both the temperature sensitive anode region 182 and the temperature sensitive cathode region 181 of the part sandwiched between the anode wiring portion 117 and the cathode wiring portion 119.

The short wiring portion 310 is, via the short contact portions 311, in contact with both the temperature sensitive anode region 182 and the temperature sensitive cathode region 181 of the part sandwiched between the anode wiring portion 117 and the cathode wiring portion 119. That is, both the temperature sensitive anode region 182 and the temperature sensitive cathode region 181 of the part sandwiched between the anode wiring portion 117 and the cathode wiring portion 119 are electrically connected to the short wiring portion 310. Accordingly, the temperature sensitive anode region 182 and the temperature sensitive cathode region 181 of the part sandwiched between the anode wiring portion 117 and the cathode wiring portion 119 have a same electrical potential. Therefore, one temperature sensitive trench portion 185 is provided with three PN diodes connected in series. A number of the PN diodes connected in series is not limited to three. Connecting a plurality of PN diodes in series can increase the potential difference for sensing a temperature, whereby the sensing accuracy is improved.

Also in the present example, the plurality of PN diodes connected in series may be connected in parallel by repeatedly placing, in the Y′ axis direction, the array from the temperature sensitive trench portion 185 including the cathode contact portion 186 to the temperature sensitive trench portion 185 including the anode contact portion 187.

FIG. 6J is an enlarged top view illustrating another example of the temperature sensitive diode portion 183 in the temperature sensitive portion 180. The temperature sensitive trench portion 185 in the present example includes a plurality of temperature sensitive trench portions 185 spaced apart in the X′ axis direction, and the temperature sensitive diode portions 183 provided in the respective temperature sensitive trench portions 185 may be connected in series via the anode wiring portion 117, the short wiring portion 310, and the cathode wiring portion 119. The PN junction 300 in the present example may be formed as illustrated in FIG. 5A or 5B.

The longitudinal direction of the temperature sensitive trench portion 185 in the present example is parallel to the X′ axis direction. The short wiring portion 310 connects the plurality of temperature sensitive trench portions 185 spaced apart in the X′ axis direction. Also in the present example, the plurality of PN diodes connected in series may be connected in parallel by repeatedly placing, in the Y′ axis direction, the array from the temperature sensitive trench portion 185 including the cathode contact portion 186 to the temperature sensitive trench portion 185 including the anode contact portion 187.

FIG. 6K is an equivalent circuit diagram of the temperature sensitive diode portion 183 illustrated in FIGS. 6H, 6I, and 6J. In the present example, in the temperature sensitive diode portion 183, the PN diodes formed in the temperature sensitive trench portion 185 are connected in parallel via the cathode wiring portion 119, the anode wiring portion 117, or the short wiring portion 310. The PN diodes connected in parallel are connected in series via the short wiring portion 310. The PN diodes may be connected in parallel by the short wiring portions 310. Note that, in FIGS. 6K, 6H, 6I, and 6J, a number of parallel connections is two, and a number of series connections is three, but the present invention is not limited thereto.

FIG. 6L is an enlarged top view illustrating another example of the temperature sensitive diode portion 183 in the temperature sensitive portion 180. The longitudinal direction of the temperature sensitive trench portion 185 in the present example may be parallel to, intersect with, or be perpendicular to the extending direction of the active trench portion 122. The temperature sensitive trench portion 185 in the present example may include a plurality of temperature sensitive trench portions 185, and the temperature sensitive diode portions 183 provided in the respective temperature sensitive trench portions 185 may be connected in series via the short wiring portion 310. The PN junction 300 in the present example may be formed as illustrated in FIG. 5A or 5B.

The longitudinal direction of the temperature sensitive trench portion 185 in the present example is perpendicular to the X′ axis direction and parallel to the Y′ axis direction. The short wiring portion 310 connects the plurality of temperature sensitive trench portions 185 spaced apart in the X′ axis direction. Also in the present example, the plurality of PN diodes connected in series may be connected in parallel by repeatedly placing, in the Y′ axis direction, the array from the temperature sensitive trench portion 185 including the cathode contact portion 186 to the temperature sensitive trench portion 185 including the anode contact portion 187. At this time, the short wiring portion 310 may connect one temperature sensitive anode region 182 and one temperature sensitive cathode region 181, or may connect a plurality of temperature sensitive anode regions 182 and a plurality of temperature sensitive cathode regions 181 in parallel. The present example will be described as an example having no parallel connection.

The Y′ axis direction may or may not coincide with the Y axis direction which is the longitudinal direction of the active trench portion 122. When the Y′ axis direction coincides with the Y axis direction which is the longitudinal direction of the active trench portion 122, both trench portions are easily formed by aligning the temperature sensitive trench portion 185 and the active trench portion 122.

FIG. 6M is an equivalent circuit diagram of the temperature sensitive diode portion 183 illustrated in FIG. 6L. In the present example, in the temperature sensitive diode portion 183, two PN diodes formed in the temperature sensitive trench portion 185 are connected in series via the short wiring portion 310, and are connected to the cathode wiring portion 119 or the cathode pad 118 and the anode wiring portion 117 or the anode pad 116. Note that, in the present example, the number of series connections is three, but may be two or three or more.

FIG. 6N illustrates another example of the enlarged top view of the temperature sensitive diode portion 183 in the temperature sensitive portion 180 of the region T in FIG. 3. The present example is different from FIG. 6L in including a plurality of short wiring portions 310 spaced apart in the Y′ axis direction. A dimension of the metal wiring may be larger than a dimension of the trench portion. For example, as illustrated in FIG. 6G, when different metal wirings are formed between the trench portions adjacent to each other, it may be difficult to secure an interval between the metal wirings adjacent to each other. As in the present example, by connecting a plurality of temperature sensitive trench portions 185 in series via the plurality of short wiring portions 310 having a sufficient size arranged so as to have a sufficiently large interval, it is possible to easily secure an interval between the cathode wiring portion 119 and each of the anode wiring portion 117 and the short wiring portion 310.

FIG. 6O illustrates an equivalent circuit of the temperature sensitive diode portion 183 illustrated in FIG. 6N. The temperature sensitive diode portion 183 in the present example is obtained by connecting four or more PN diodes in series.

FIG. 6P illustrates another example of the enlarged top view of the temperature sensitive diode portion 183 in the temperature sensitive portion 180 of the region T in FIG. 3. The present example is different from that of FIG. 6G in that a loop-shaped part of the temperature sensitive trench portion 185 is wide and one or more dummy trench portions 30 are provided inside the temperature sensitive trench portion 185. The dimension of the metal wiring may be larger than the dimension of the trench portion. For example, as illustrated in FIG. 6G, when different metal wirings are formed between the trench portions adjacent to each other, it may be difficult to secure the interval between the metal wirings adjacent to each other. As in the present example, by providing one or more dummy trench portions 30 inside the temperature sensitive trench portion 185, the cathode wiring portion 119 and the anode wiring portion 117 can be spaced apart by a distance roughly equivalent to a number of the dummy trench portions 30. Providing the dummy trench portion 30 inside the temperature sensitive trench portion 185 can prevent the electric field from concentrating at the bottom portion of the temperature sensitive trench portion 185. Accordingly, it is possible to easily secure an interval between the cathode wiring portion 119 and the anode wiring portion 117. Note that when the temperature sensitive trench portion 185 is covered with the well region, it is possible to prevent the electric field from concentrating at the bottom portion of the temperature sensitive trench portion 185, and thus the dummy trench portion 30 may not be provided.

FIG. 6Q illustrates an equivalent circuit of the temperature sensitive diode portion 183 illustrated in FIG. 6P. In the present example, the temperature sensitive diode portion 183 is one PN diode.

FIG. 6R illustrates another example of the enlarged top view of the temperature sensitive diode portion 183 in the temperature sensitive portion 180 of the region T in FIG. 3. The present example is different from that of FIG. 6G in that the loop-shaped part of the temperature sensitive trench portion 185 is wide and one or more small loop structures are provided inside the temperature sensitive trench portion 185. The dimension of the metal wiring may be larger than the dimension of the trench portion. For example, as illustrated in FIG. 6G, when different metal wirings are formed between the trench portions adjacent to each other, it may be difficult to secure the interval between the metal wirings adjacent to each other. As in the present example, by providing one or more loop structures inside the temperature sensitive trench portion 185, the cathode wiring portion 119 and the anode wiring portion 117 can be spaced apart by a distance roughly equivalent to a number of at least one fold of the temperature sensitive trench portion 185. Providing the temperature sensitive trench portion 185, which is arranged in a folded manner, between the temperature sensitive trench portions 185 including the cathode contact portion 186 and the anode contact portion 187 can prevent the electric field from concentrating at the bottom portion of the temperature sensitive trench portion 185. Accordingly, it is possible to easily secure the interval between the cathode wiring portion 119 and the anode wiring portion 117.

The equivalent circuit of the temperature sensitive diode portion 183 illustrated in FIG. 6R is illustrated in FIG. 6Q. In the present example, the temperature sensitive diode portion 183 is one PN diode.

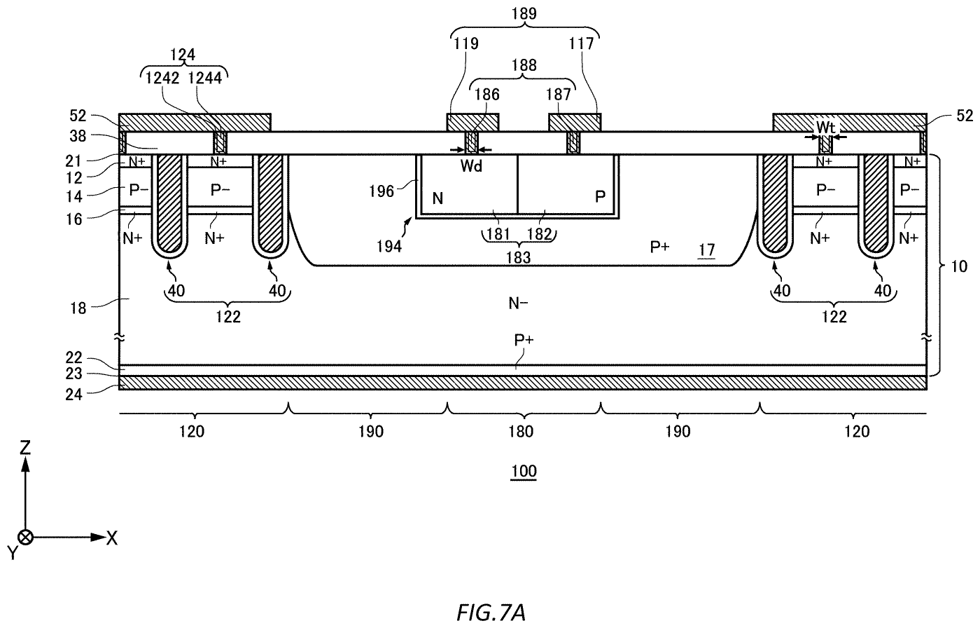

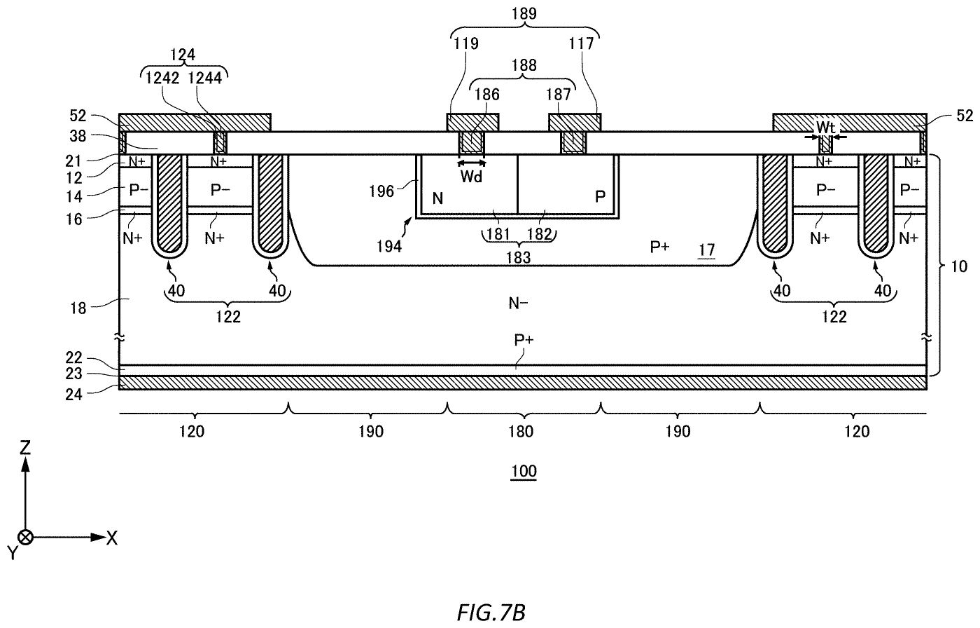

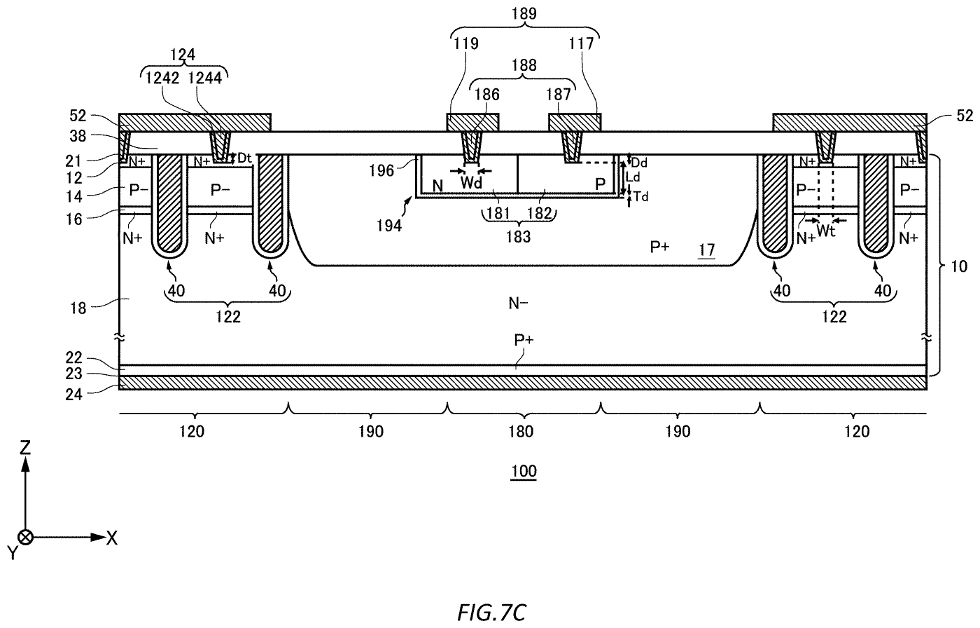

FIG. 7A illustrates a cross section of a modification of the semiconductor device 100 including the temperature sensitive portion 180. The semiconductor device 100 in the present example is different from those in the examples of FIGS. 4A to 4D in that a recess region 194 is provided. In the present example, the difference from the examples of FIGS. 4A to 4D will be particularly described, and other configurations may be the same as those in at least one example of FIGS. 4A to 4D.

The temperature sensitive portion 180 may include the recess region 194 including a recess on the front surface 21 side of the semiconductor substrate 10. The temperature sensitive portion 180 may include, in the recess region 194, the temperature sensitive diode portion 183 provided above the semiconductor substrate 10. The temperature sensitive diode portion 183 may be provided above a dielectric film 196 in the recess region 194. The dielectric film 196 may be a BPSG film, a BSG film, a PSG film, an HTO film, or a stack of these materials.

The temperature sensitive contact portion 188 may be provided on the interlayer dielectric film 38 to electrically connect the temperature sensitive wiring portion 189 and the temperature sensitive diode portion 183. The temperature sensitive wiring portion 189 electrically connected to the temperature sensitive cathode region 181 of the temperature sensitive diode portion 183 may be the cathode wiring portion 119, and the temperature sensitive wiring portion 189 electrically connected to the temperature sensitive anode region 182 of the temperature sensitive diode portion 183 may be the anode wiring portion 117.

The contact width Wd of the temperature sensitive contact portion 188 may be the same as the contact width Wt of the active contact portion 124. When the contact width Wd of the temperature sensitive contact portion 188 and the contact width Wt of the active contact portion 124 are substantially the same, both contact portions can be simultaneously formed by a same etching step. However, the contact width Wd of the temperature sensitive contact portion 188 may be different from the contact width Wt of the active contact portion 124. The contact width Wd of the temperature sensitive contact portion 188 may be larger than the contact width Wt of the active contact portion 124, or may be smaller than the contact width Wt of the active contact portion 124.

In the depth direction of the semiconductor substrate 10, the height position of the upper surface of the interlayer dielectric film 38 in the active portion 120 may be substantially the same as the height position of the upper surface of the interlayer dielectric film 38 in the recess region 194. When the height position of the upper surface of the interlayer dielectric film 38 in the active portion 120 is substantially the same as the height position of the upper surface of the interlayer dielectric film in the recess region 194, the active contact portion 124 and the temperature sensitive contact portion 188 can be simultaneously formed by a same etching step. That is, when the upper surfaces of both the interlayer dielectric film 38 in the active portion 120 and the interlayer dielectric film 38 in the recess region 194 have a same height from the front surface 21 of the semiconductor substrate 10, no misalignment in the focal point of exposure occurs in the photolithography step. Therefore, a dimensional tolerance of the interlayer dielectric film, the emitter electrode, or the like can be reduced. Furthermore, the active contact portion 124 and the temperature sensitive contact portion 188 can be formed with a same dimensional tolerance. Accordingly, it is possible to easily manufacture the contact portions with fewer steps than in a case where the contact portions are formed in separate steps.

By forming the temperature sensitive contact portion 188 and the active contact portion 124 in the same step, it is possible to suppress the spread of the active contact portion 124, and it is possible to suppress the short circuit failure or the like between the gate and the emitter. In addition, the temperature sensitive contact portion 188 and the active contact portion 124 are formed in the same step, and a same contact portion is formed, so that embedding of the plug metal in the contact portion is improved. Accordingly, it is possible to prevent the plug metal from remaining during etch-back, and it is possible to improve the yield in manufacturing the semiconductor device 100. Note that the active contact portion 124 and the temperature sensitive contact portion 188 may be formed by different steps.

FIG. 7B illustrates a cross section of a modification of the semiconductor device 100 including the temperature sensitive portion 180. The present example is different from the example of FIG. 7A in that the contact width Wd of the temperature sensitive contact portion 188 is different from the contact width Wt of the active contact portion 124. In the present example, the difference from the example of FIG. 7A will be particularly described, and other configurations may be the same as those in the example of FIG. 7A.

The contact width Wd of the temperature sensitive contact portion 188 may be larger than the contact width Wt of the active contact portion 124. By making the contact width Wd of the temperature sensitive contact portion 188 larger than the contact width Wt of the active contact portion 124, even when the semiconductor device 100 is miniaturized, the semiconductor device can be stably manufactured, and stable characteristics can be obtained. In this case, the active contact portion 124 and the temperature sensitive contact portion 188 may be formed by different steps.

FIG. 7C illustrates a cross section of a modification of the semiconductor device 100 including the temperature sensitive portion 180. The present example is different from the example of FIG. 7A in that the temperature sensitive contact portion 188 and the active contact portion 124 in the present example have a trench contact shape. In the present example, the difference from the example of FIG. 7A will be particularly described, and other configurations may be the same as those in the example of FIG. 7A.

A distance Ld from a lower end of the temperature sensitive contact portion 188 to an upper surface of the dielectric film 196 of the temperature sensitive portion 180 in the depth direction of the semiconductor substrate 10 may be larger than, smaller than, or equal to a thickness Td of the dielectric film 196. In the depth direction of the semiconductor substrate 10, a distance Dd from the front surface 21 of the semiconductor substrate 10 to the lower end of the temperature sensitive contact portion 188 may be smaller than the distance Ld from the lower end of the temperature sensitive contact portion 188 to the upper surface of the dielectric film 196. In the present example, Dd is smaller than Ld. However, in the depth direction of the semiconductor substrate 10, the distance Dd from the front surface 21 of the semiconductor substrate 10 to the lower end of the temperature sensitive contact portion 188 may be larger than the distance Ld from the lower end of the temperature sensitive contact portion 188 to the upper surface of the dielectric film 196.

The temperature sensitive contact portion 188 may not penetrate the temperature sensitive diode portion 183. The temperature sensitive contact portion 188 in the present example does not penetrate the temperature sensitive diode portion 183. That is, Ld>0 may be satisfied. In another example, the temperature sensitive contact portion 188 may penetrate the temperature sensitive diode portion 183, and Ld=0 may be satisfied. However, it should be noted that when the temperature sensitive contact portion 188 extends from the upper surface of the dielectric film 196 in the depth direction of the semiconductor substrate 10 and the thickness Td of the dielectric film 196 below the temperature sensitive contact portion 188 decreases, insulation between the temperature sensitive diode portion 183 and the semiconductor substrate 10 may not be maintained.

A depth Dd at which the temperature sensitive contact portion 188 in the present example extends from the upper surface of the temperature sensitive diode portion 183 in the Z axis direction is smaller than a thickness of the temperature sensitive diode portion 183. The depth Dd may be equal to a depth Dt at which the active contact portion 124 extends from the front surface 21 in the Z axis direction. When the upper surfaces of both the interlayer dielectric film 38 in the active portion 120 and the interlayer dielectric film 38 in the recess region 194 have a same height from the front surface 21 of the semiconductor substrate 10, no misalignment in the focal point of exposure occurs in the photolithography step. Therefore, the dimensional tolerance of the interlayer dielectric film 38, the emitter electrode 52, or the like can be reduced, and the depths can be made substantially the same even in a case of the trench contact shape. Even when the semiconductor device 100 is miniaturized, the semiconductor device can be stably manufactured, and stable characteristics can be obtained. In another example, the depth Dd may be shallower than the depth Dt. In the temperature sensitive portion 180, the temperature sensitive contact portion 188 may not penetrate the temperature sensitive diode portion 183, and in the active portion 120, the active contact portion 124 may reach a deep portion of the contact region 15. Accordingly, latch-up is suppressed. In this case, the active contact portion 124 and the temperature sensitive contact portion 188 may be formed by different steps.

A combination of whether the active contact portion 124 has the planar contact shape in FIG. 7A or the trench contact shape in FIG. 7C and whether the temperature sensitive contact portion 188 has the planar contact shape in FIG. 7A or the trench contact shape in FIG. 7C is arbitrary. That is, both the active contact portion 124 and the temperature sensitive contact portion 188 may have the planar contact shape, one of the active contact portion 124 or the temperature sensitive contact portion 188 may have the planar contact shape and another may have the trench contact shape, or both the active contact portion 124 and the temperature sensitive contact portion 188 may have the trench contact shape.

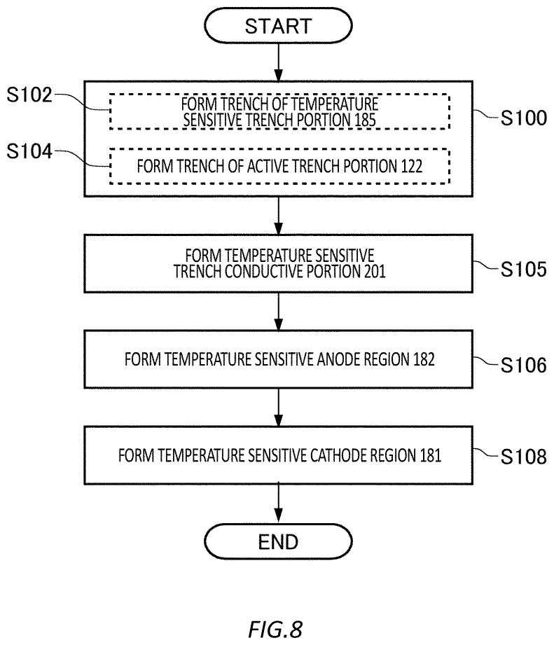

FIG. 8 is a flowchart illustrating an example of a manufacturing step of the semiconductor device 100. In step S100, a trench of the temperature sensitive trench portion 185 and a trench of the active trench portion 122 are formed on the front surface 21 side of the semiconductor substrate 10. Step S100 may include step S102 of forming the trench of the temperature sensitive trench portion 185 on the front surface 21 side of the semiconductor substrate 10 and step S104 of forming the trench of the active trench portion 122 on the front surface 21 side of the semiconductor substrate 10.

The trench of the temperature sensitive trench portion 185 and the trench of the active trench portion 122 may be simultaneously formed by a same etching step. That is, step S102 and step S104 may be a same step. Since the trench of the temperature sensitive trench portion 185 and the trench of the active trench portion 122 are formed by the same step, the semiconductor device 100 including the temperature sensitive portion 180 can be easily manufactured.

However, after the trench of the temperature sensitive trench portion 185 is formed in step S102, the trench of the active trench portion 122 may be formed in step S104, or after the trench of the active trench portion 122 is formed in step S104, the trench of the temperature sensitive trench portion 185 may be formed in step S102.

Step S100 may include a step of forming the trench insulating portion 184 to be a dielectric film by covering an inner wall of the trench after forming the trench. The dielectric film on a trench side wall may be a thermal oxide film. In the step of forming the trench insulating portion 184, a sacrificial oxide film may be formed by thermal oxidation, the sacrificial oxide film may be removed, and then a thermal oxide film may be formed again as the dielectric film.

In step S105, the temperature sensitive trench conductive portion 201 is formed inside the trench of the temperature sensitive trench portion 185. The temperature sensitive trench conductive portion 201 may be polysilicon. The polysilicon may be non-doped or may be doped with a dopant of the N type such as phosphorous or a dopant of the P type such as boron. The temperature sensitive trench conductive portion 201 may fill the temperature sensitive trench portion 185 to be embedded thereinto.

In step S106, the temperature sensitive anode region 182 is formed in the temperature sensitive trench conductive portion 201. The temperature sensitive anode region 182 can be formed in a method that is conventional to persons skilled in the art. As an example, when the temperature sensitive trench conductive portion 201 is non-doped polysilicon or doped polysilicon of the N type, the temperature sensitive anode region 182 may be formed by implanting impurity ions of the P type into the temperature sensitive trench conductive portion 201 and performing annealing processing. When the temperature sensitive trench conductive portion 201 is the N type, the dose amount is adjusted such that a concentration of the dopant of the P type is higher than that of the dopant of the N type. When the temperature sensitive anode region 182 is formed by ion implantation, a region where diffusion of ions does not reach may remain non-doped or the N type. Even when the region where diffusion of ions does not reach remains non-doped or the N type, the electric field distribution can be made uniform by making trench depths of the temperature sensitive anode region 182 and the temperature sensitive cathode region 181 the same, and favorable characteristics can be obtained. As another example, the temperature sensitive anode region 182 may be doped polysilicon with the dopant of the P type.

In step S108, the temperature sensitive cathode region 181 in contact with the temperature sensitive anode region 182 is formed inside the trench of the temperature sensitive trench portion 185. The temperature sensitive cathode region 181 can be formed in a method that is conventional to persons skilled in the art. As an example, when the temperature sensitive trench conductive portion 201 is non-doped polysilicon or doped polysilicon of the P type, the temperature sensitive cathode region 181 may be formed by implanting impurity ions of the N type into the temperature sensitive trench conductive portion 201 and performing annealing processing. When the temperature sensitive trench conductive portion 201 is the P type, the dose amount is adjusted such that a concentration of the dopant of the N type is higher than that of the dopant of the P type. When the temperature sensitive cathode region 181 is formed by ion implantation, a region where diffusion of ions does not reach may remain non-doped or the P type. Even when the region where diffusion of ions does not reach remains non-doped or the P type, the electric field distribution can be made uniform by making the trench depths of the temperature sensitive anode region 182 and the temperature sensitive cathode region 181 the same, and favorable characteristics can be obtained.

A manufacturing order of the temperature sensitive anode region 182 and the temperature sensitive cathode region 181 is not limited thereto. The temperature sensitive anode region 182 may be formed after formation of the temperature sensitive cathode region 181, and the temperature sensitive anode region 182 and the temperature sensitive cathode region 181 may be formed by a same step.

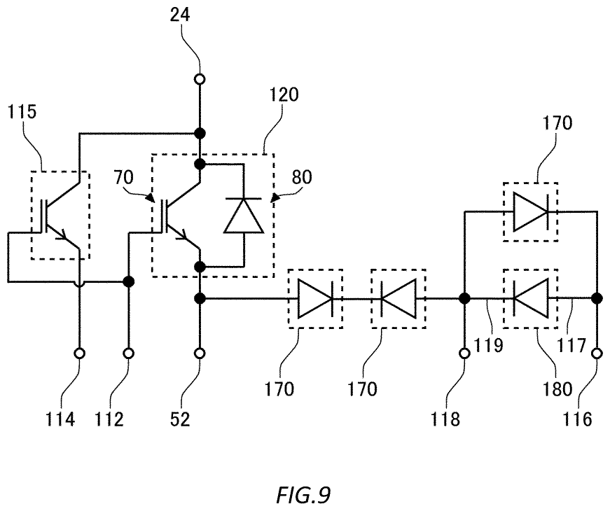

FIG. 9 is an example of electrical connection of each portion of the semiconductor device 100. In the present example, a Zener diode 170 is provided in anti-parallel to protect a withstand voltage between the cathode pad 118 and the anode pad 116. The Zener diode 170 may have a similar configuration by a manufacturing method similar to that of the temperature sensitive diode portion 183. A forward voltage of the Zener diode 170 in this case may be different from a forward voltage of the temperature sensitive diode portion 183. When the temperature sensitive diode portion 183 consists of a plurality of temperature sensitive cathode regions 181 and a plurality of temperature sensitive anode regions 182 connected in series, the Zener diode 170 may be provided between each temperature sensitive cathode region 181 and each temperature sensitive anode region 182. In addition, the Zener diode 170 may be provided between the temperature sensitive portion 180 and the active portion 120 for electric field protection. The Zener diode 170 may have a configuration similar to that of the temperature sensitive diode portion 183. A breakdown voltage of the Zener diode 170 in this case may be different from a breakdown voltage of the temperature sensitive diode portion 183. A plurality of Zener diodes 170 may be connected in series. In another example, the Zener diodes 170 may be connected to a different position and the Zener diode 170 may not be provided.

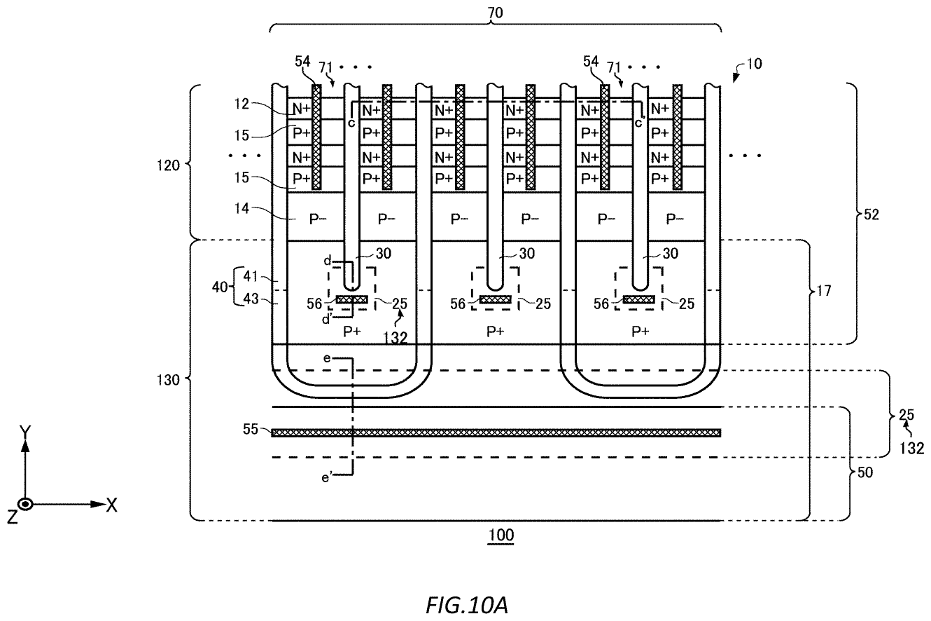

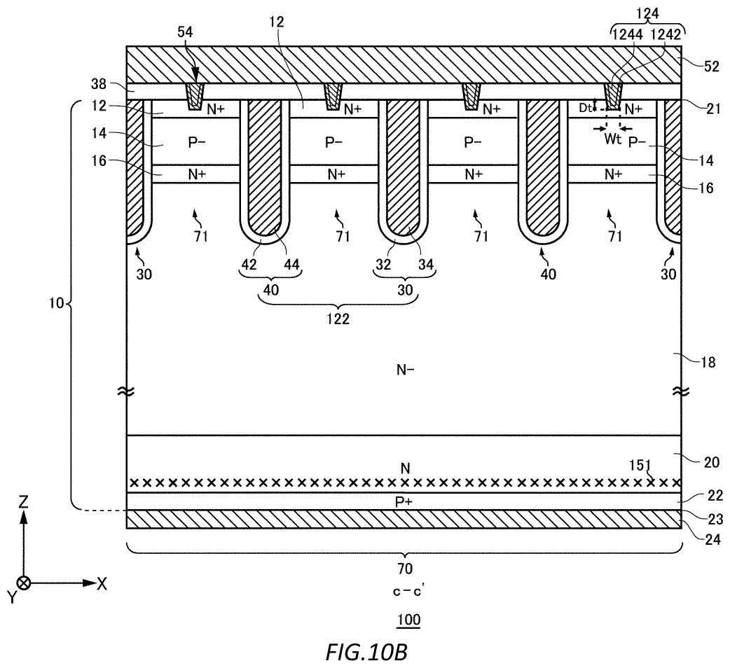

FIG. 10A illustrates an example of an enlarged top view of the semiconductor device 100. The semiconductor device 100 in the present example is different from that in the example of FIG. 1A in that the connection portion 25 is provided between the emitter electrode 52 and the dummy conductive portion 34. In the present example, the difference from the example of FIG. 1A will be particularly described, and other configurations may be the same as those in the example of FIG. 1A.

The semiconductor device 100 includes the active portion 120 which is a part through which a main current flows between the front surface 21 and the back surface 23 of the semiconductor substrate 10, and an inactive portion 130 which is a remaining part. For example, a boundary between the active portion 120 and the inactive portion 130 is a boundary between the base region 14 and the well region 17.

The interlayer dielectric film 38 is provided above the active portion 120 and the inactive portion 130, but the interlayer dielectric film 38 is omitted in FIG. 9. The contact hole 54, the contact hole 55, and the contact hole 56 are provided to penetrate the interlayer dielectric film 38.

The contact hole 55 electrically connects the gate metal layer 50 and the gate conductive portion 44 in the transistor portion 70 via the connection portion 25. The contact hole 56 electrically connects the emitter electrode 52 and the dummy conductive portion 34 in the dummy trench portion 30 via the connection portion 25. The connection portion 25 is a conductive material such as polysilicon doped with impurities. The connection portion 25 in the present example is polysilicon (N+) doped with impurities of the N type. The polysilicon is an example of a polycrystalline semiconductor. The connection portion 25 is an example of a polycrystalline portion 132 provided above the semiconductor substrate 10. The connection portion 25 is an example of the polycrystalline portion 132 included in the inactive portion 130.

FIG. 10B illustrates an example of a cross section c-c′ in FIG. 10A. The semiconductor device 100 in the present example is different from that in the example of FIG. 1B in that the active contact portion 124 has a trench shape. Other configurations may be the same as those in the example of FIG. 1B.

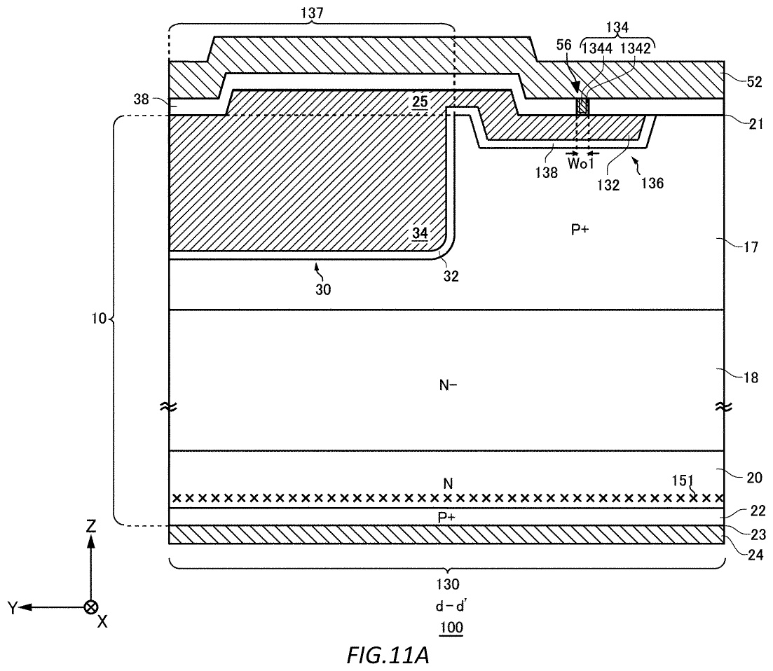

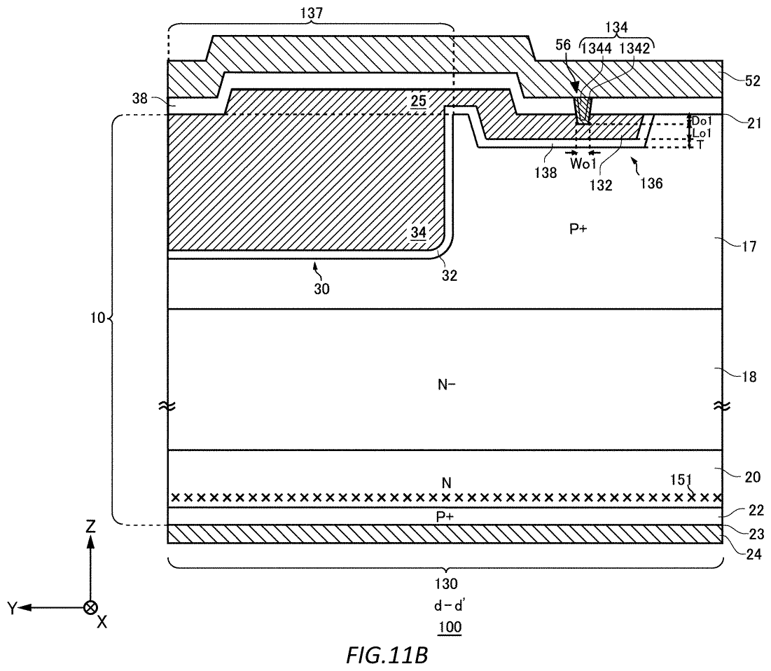

FIG. 11A illustrates an example of a cross section d-d′ in FIG. 9. The cross section d-d′ is a YZ plane passing through the contact hole 56 in the inactive portion 130. The semiconductor device 100 in the present example includes, in the cross section d-d′, the semiconductor substrate 10, the interlayer dielectric film 38, the emitter electrode 52, the collector electrode 24, and a first inactive contact portion 134. Note that, in the present example, the contact hole 56 which is elongated in the X axis direction is described as an example, but a longitudinal direction of the contact hole 56 may be along the Y axis direction or may be along another direction.

The inactive portion 130 include a recess region 136 including a recess on the front surface 21 side of the semiconductor substrate 10. The inactive portion 130 includes, in the recess region 136, the polycrystalline portion 132 provided above the semiconductor substrate 10.

The polycrystalline portion 132 in the present example is the connection portion 25.

The inactive portion 130 may include the dielectric film 138 on the upper surface of the semiconductor substrate 10 in the recess region 136. The dielectric film 138 may be, for example, a same material as that of the dummy dielectric film 32. The dielectric film 138 may be, for example, a thermal oxide film. The polycrystalline portion 132 may be provided above the dielectric film 138 in the recess region 136. The connection portion 25 in the present example is provided above the dielectric film 138.

In the depth direction of the semiconductor substrate 10, the height position of the upper surface of the interlayer dielectric film 38 in the active portion 120 is the same as the height position of the upper surface of the interlayer dielectric film 38 in the recess region 136. That is, since the height position of the upper surface of the connection portion 25 provided in the recess region 136 is the same as the height position of the front surface 21 of the semiconductor substrate 10, the height position of the upper surface of the interlayer dielectric film 38 in the active portion 120 may be the same as the height position of the upper surface of the interlayer dielectric film 38 in the recess region 136.

The first inactive contact portion 134 electrically connects the emitter electrode 52 and the polycrystalline portion 132 in contact with each other. The first inactive contact portion 134 may electrically connect a film mainly including metal like the emitter electrode 52 and a film mainly including a polycrystalline substance (polysilicon in the present example) like the polycrystalline portion 132. A contact width Wo1 of the first inactive contact portion 134 may be the same as the contact width Wt of the active contact portion 124. When the contact width Wo1 of the first inactive contact portion 134 and the contact width Wt of the active contact portion 124 are substantially the same, both contact portions can be simultaneously formed by a same etching step. However, the contact width Wo1 of the first inactive contact portion 134 may be different from the contact width Wt of the active contact portion 124. The contact width Wo1 of the first inactive contact portion 134 may be larger than the contact width Wt of the active contact portion 124, or may be smaller than the contact width Wt of the active contact portion 124. When the height position of the upper surface of the interlayer dielectric film 38 in the active portion 120 is the same as the height position of the upper surface of the interlayer dielectric film 38 in the recess region 136, the active contact portion 124 and the first inactive contact portion 134 can be simultaneously formed by a same etching step. That is, when the upper surfaces of both the interlayer dielectric film 38 in the active portion 120 and the interlayer dielectric film 38 in the recess region 136 have a same height from the front surface 21 of the semiconductor substrate 10, no misalignment in the focal point of exposure occurs in the photolithography step. Therefore, the dimensional tolerance of the interlayer dielectric film, the emitter electrode, or the like can be reduced. Furthermore, the active contact portion 124 and the first inactive contact portion 134 can be formed with a same dimensional tolerance. Accordingly, it is possible to easily manufacture the contact portions with fewer steps than in a case where the contact portions are formed in separate steps.

By forming the first inactive contact portion 134 and the active contact portion 124 in the same step, it is possible to suppress the spread of the active contact portion 124, and it is possible to suppress the short circuit failure or the like between the gate and the emitter. In addition, the first inactive contact portion 134 and the active contact portion 124 are formed in the same step, and a same contact portion is formed, so that embedding of the plug metal in the contact portion is improved. Accordingly, it is possible to prevent the plug metal from remaining during etch-back, and it is possible to improve the yield in manufacturing the semiconductor device 100. Note that the active contact portion 124 and the first inactive contact portion 134 may be formed by different steps.

The first inactive contact portion 134 is electrically connected to the polycrystalline portion 132. The first inactive contact portion 134 in the present example is electrically connected to the connection portion 25. The first inactive contact portion 134 may electrically connect the emitter electrode 52 and the connection portion 25.

The first inactive contact portion 134 may include a barrier metal film 1342 provided in the contact hole 55 and a plug portion 1344. The barrier metal film 1342 of the first inactive contact portion 134 may contain titanium, a titanium compound, or the like. The plug portion 1344 of the first inactive contact portion 134 may contain a plug metal such as tungsten.

The polycrystalline portion 132 may be connected to the emitter electrode 52 through the contact hole 56 provided in the interlayer dielectric film 38 above the recess region 136. The connection portion 25 in the present example is connected to the emitter electrode 52 through the contact hole 56 provided in the interlayer dielectric film 38. The polycrystalline portion 132 may be connected to the dummy conductive portion 34 above a non-recess region 137. The non-recess region 137 may be a region where no recess is formed on the front surface 21 side of the semiconductor substrate 10. The connection portion 25 in the present example is connected to the dummy conductive portion 34 above the non-recess region 137. By providing the dummy trench portion 30 in the non-recess region 137, a trench shape is formed more stably than a case where the dummy trench portion 30 is provided in the recess region 136. In another example, the dummy trench portion 30 may be formed in the recess region 136, and the connection portion 25 may be connected to the dummy conductive portion 34 above the recess region 136.

FIG. 11B illustrates an example of the cross section d-d′ in FIG. 10A. The semiconductor device 100 in the present example is different from that in the example of FIG. 11A in that the first inactive contact portion 134 has a trench shape. In the present example, the difference from the example of FIG. 11A will be particularly described, and other configurations may be the same as those in the example of FIG. 11A.

A distance Lo1 from a lower end of the first inactive contact portion 134 to the upper surface of the dielectric film 138 in the depth direction of the semiconductor substrate 10 may be larger than, smaller than, or equal to a thickness T of the dielectric film 138. In the depth direction of the semiconductor substrate 10, a distance Do1 from the front surface 21 of the semiconductor substrate 10 to the lower end of the first inactive contact portion 134 may be smaller than the distance L1 from the lower end of the first inactive contact portion 134 to the upper surface of the dielectric film 138. In the present example, Do1 is smaller than Lo1. However, in the depth direction of the semiconductor substrate 10, the distance L2 from the front surface 21 of the semiconductor substrate 10 to the lower end of the first inactive contact portion 134 may be larger than the distance Lo1 from the lower end of the first inactive contact portion 134 to the upper surface of the dielectric film 138.

The first inactive contact portion 134 may not penetrate the polycrystalline portion 132. The first inactive contact portion 134 in the present example does not penetrate the connection portion 25. That is, Lo1>0 may be satisfied. In another example, the first inactive contact portion 134 may penetrate the connection portion 25, and Lo1=0 may be satisfied. In the present example, the first inactive contact portion 134 may extend from the upper surface of the dielectric film 138 in the depth direction of the semiconductor substrate 10, and the thickness T of the dielectric film 138 below the first inactive contact portion 134 may be reduced, or the first inactive contact portion 134 may penetrate the dielectric film 138 to reach the semiconductor substrate 10. However, it should be noted that there may be a problem in the first inactive contact portion 134 of another region formed simultaneously.

The depth Do1 from the front surface 21 of the semiconductor substrate 10 to the lower end of the first inactive contact portion 134 may be the same as the depth Dt from the front surface 21 of the semiconductor substrate 10 to the lower end of the active contact portion 124. When Do1 and Dt are substantially the same, both contact portions can be simultaneously formed by a same etching step. When the upper surfaces of both the interlayer dielectric film 38 in the active portion 120 and the interlayer dielectric film 38 in the recess region 136 have a same height from the front surface 21 of the semiconductor substrate 10, no misalignment in the focal point of exposure occurs in the photolithography step. Therefore, the dimensional tolerance of the interlayer dielectric film 38, the emitter electrode 52, or the like can be reduced, and the depths can be made substantially the same even in the case of the trench contact shape. In another example, the depth Do1 may be shallower than the depth Dt. In the inactive portion 130, the first inactive contact portion 134 may not penetrate the connection portion 25, and in the active portion 120, the active contact portion 124 may reach the deep portion of the contact region 15. Accordingly, the latch-up is suppressed. In this case, the active contact portion 124 and the first inactive contact portion 134 may be formed by different steps.

A combination of whether the active contact portion 124 has the planar contact shape in FIG. 1B or the trench contact shape in FIG. 10B and whether the first inactive contact portion 134 has the planar contact shape in FIG. 11A or the trench contact shape in FIG. 11B is arbitrary. That is, both the active contact portion 124 and the first inactive contact portion 134 may have the planar contact shape, one of the active contact portion 124 or the first inactive contact portion 134 may have the planar contact shape and another may have the trench contact shape, or both the active contact portion 124 and the first inactive contact portion 134 may have the trench contact shape.

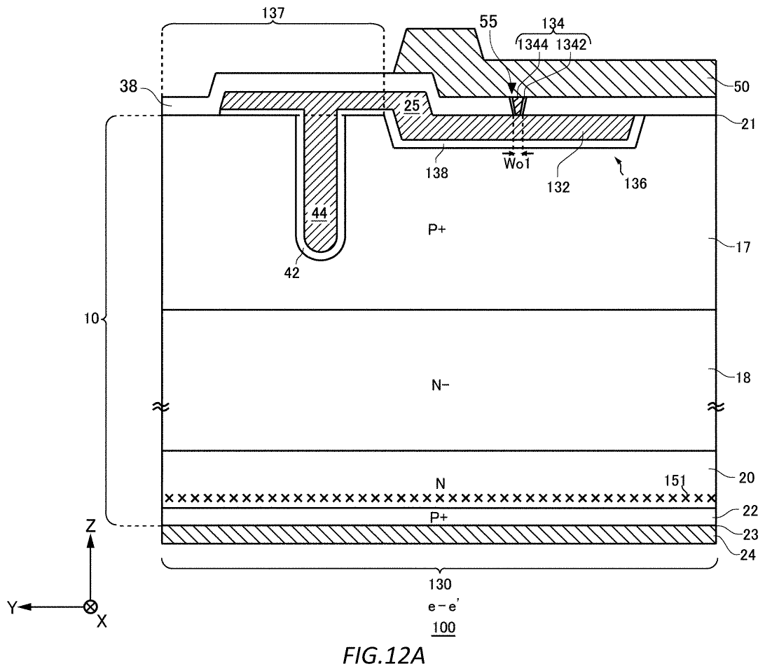

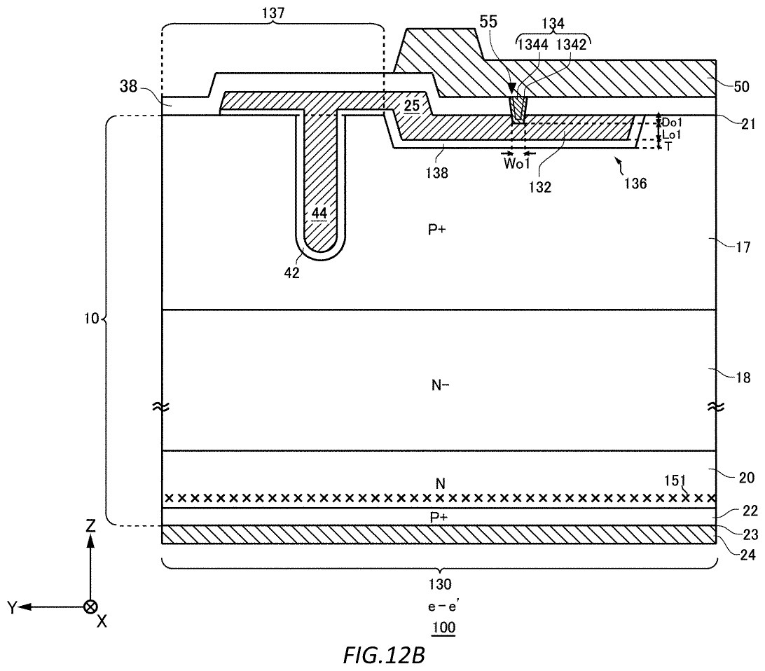

FIG. 12A illustrates an example of a cross section e-e′ in FIG. 10A. The cross section e-e′ is a YZ plane passing through the contact hole 55 in the inactive portion 130. The semiconductor device 100 in the present example includes, in the cross section e-e′, the semiconductor substrate 10, the interlayer dielectric film 38, the gate metal layer 50, the collector electrode 24, and the first inactive contact portion 134. Note that, in the present example, the contact hole 55 which is elongated in the X axis direction is described as an example, but the longitudinal direction of the contact hole 55 may be along the Y axis direction or may be along another direction.

The inactive portion 130 includes the recess region 136 including a recess on the front surface 21 side of the semiconductor substrate 10. The inactive portion 130 includes, in the recess region 136, the polycrystalline portion 132 provided above the semiconductor substrate 10. The polycrystalline portion 132 in the present example is the connection portion 25.

The inactive portion 130 may include the dielectric film 138 on the upper surface of the semiconductor substrate 10 in the recess region 136. The dielectric film 138 may be, for example, a same material as that of the gate dielectric film 42. The dielectric film 138 may be, for example, a thermal oxide film. The polycrystalline portion 132 may be provided above the dielectric film 138 in the recess region 136. The connection portion 25 in the present example is provided above the dielectric film 138.

In the depth direction of the semiconductor substrate 10, the height position of the upper surface of the interlayer dielectric film 38 in the active portion 120 is the same as the height position of the upper surface of the interlayer dielectric film 38 in the recess region 136. That is, since the height position of the upper surface of the connection portion 25 provided in the recess region 136 is the same as the height position of the front surface 21 of the semiconductor substrate 10, the height position of the upper surface of the interlayer dielectric film 38 in the active portion 120 may be the same as the height position of the upper surface of the interlayer dielectric film 38 in the recess region 136.

The contact width Wo1 of the first inactive contact portion 134 may be the same as the contact width Wt of the active contact portion 124. When the contact width Wo1 of the first inactive contact portion 134 and the contact width Wt of the active contact portion 124 are substantially the same, both contact portions can be simultaneously formed by a same etching step. However, the contact width Wo1 of the first inactive contact portion 134 may be different from the contact width Wt of the active contact portion 124. The contact width Wo1 of the first inactive contact portion 134 may be larger than the contact width Wt of the active contact portion 124, or may be smaller than the contact width Wt of the active contact portion 124.

When the height position of the upper surface of the interlayer dielectric film 38 in the active portion 120 is the same as the height position of the upper surface of the interlayer dielectric film 38 in the recess region 136, the active contact portion 124 and the first inactive contact portion 134 can be simultaneously formed by a same etching step. That is, when the upper surfaces of both the interlayer dielectric film 38 in the active portion 120 and the interlayer dielectric film 38 in the recess region 136 have a same height from the front surface 21 of the semiconductor substrate 10, no misalignment in the focal point of exposure occurs in the photolithography step. Therefore, the dimensional tolerance of the interlayer dielectric film, the emitter electrode, or the like can be reduced. Furthermore, the active contact portion 124 and the first inactive contact portion 134 can be formed with a same dimensional tolerance. Accordingly, it is possible to easily manufacture the contact portions with fewer steps than in a case where the contact portions are formed in separate steps.

By forming the first inactive contact portion 134 and the active contact portion 124 in the same step, it is possible to suppress the spread of the active contact portion 124, and it is possible to suppress the short circuit failure or the like between the gate and the emitter. In addition, the first inactive contact portion 134 and the active contact portion 124 are formed in the same step, and a same contact portion is formed, so that embedding of the plug metal in the contact portion is improved. Accordingly, it is possible to prevent the plug metal from remaining during etch-back, and it is possible to improve the yield in manufacturing the semiconductor device 100. Note that the active contact portion 124 and the first inactive contact portion 134 may be formed by different steps.

The first inactive contact portion 134 is electrically connected to the polycrystalline portion 132. The first inactive contact portion 134 in the present example is electrically connected to the connection portion 25. The first inactive contact portion 134 may electrically connect the gate metal layer 50 and the connection portion 25.

The polycrystalline portion 132 may be connected to the gate metal layer 50 through the contact hole 55 provided in the interlayer dielectric film 38 above the recess region 136. The connection portion 25 in the present example is connected to the gate metal layer 50 through the contact hole 55 provided in the interlayer dielectric film 38. The polycrystalline portion 132 may be connected to the gate conductive portion 44 above the non-recess region 137. The connection portion 25 in the present example is connected to the gate conductive portion 44 above the non-recess region 137. By providing the gate trench portion 40 in the non-recess region 137, a trench shape is formed more stably than a case where the gate trench portion 40 is provided in the recess region 136. In another example, the gate trench portion 40 may be formed in the recess region 136, and the connection portion 25 may be connected to the gate conductive portion 44 above the recess region 136.

FIG. 12B illustrates an example of the cross section e-e′ in FIG. 10A. The semiconductor device 100 in the present example is different from that in the example of FIG. 12A in that the first inactive contact portion 134 has a trench shape. In the present example, the difference from the example of FIG. 12A will be particularly described, and other configurations may be the same as those in the example of FIG. 12A.

The distance Lo1 from the lower end of the first inactive contact portion 134 to the upper surface of the dielectric film 138 in the depth direction of the semiconductor substrate 10 may be larger than, smaller than, or equal to the thickness T of the dielectric film 138. In the depth direction of the semiconductor substrate 10, the distance Do1 from the front surface 21 of the semiconductor substrate 10 to the lower end of the first inactive contact portion 134 may be smaller than the distance Lo1 from the lower end of the first inactive contact portion 134 to the upper surface of the dielectric film 138. In the present example, Do1 is smaller than Lo1. However, in the depth direction of the semiconductor substrate 10, the distance Do1 from the front surface 21 of the semiconductor substrate 10 to the lower end of the first inactive contact portion 134 may be larger than the distance Lo1 from the lower end of the first inactive contact portion 134 to the upper surface of the dielectric film 138.

The first inactive contact portion 134 may not penetrate the polycrystalline portion 132. The first inactive contact portion 134 in the present example does not penetrate the connection portion 25. That is, Lo1>0 may be satisfied. In another example, the first inactive contact portion 134 may penetrate the connection portion 25, and Lo1=0 may be satisfied. However, it should be noted that when the first inactive contact portion 134 extends from the upper surface of the dielectric film 138 in the depth direction of the semiconductor substrate 10 and the thickness T of the dielectric film 138 below the first inactive contact portion 134 decreases, insulation between the connection portion 25 and the semiconductor substrate 10 may not be maintained.

The depth Do1 from the front surface 21 of the semiconductor substrate 10 to the lower end of the first inactive contact portion 134 may be the same as the depth Dt from the front surface 21 of the semiconductor substrate 10 to the lower end of the active contact portion 124. When Do1 and Dt are substantially the same, both contact portions can be simultaneously formed by a same etching step. When the upper surfaces of both the interlayer dielectric film 38 in the active portion 120 and the interlayer dielectric film 38 in the recess region 136 have a same height from the front surface 21 of the semiconductor substrate 10, no misalignment in the focal point of exposure occurs in the photolithography step. Therefore, the dimensional tolerance of the interlayer dielectric film 38, the emitter electrode 52, or the like can be reduced, and the depths can be made substantially the same even in the case of the trench contact shape. In another example, the depth Do1 may be shallower than the depth Dt. In the inactive portion 130, the first inactive contact portion 134 may not penetrate the connection portion 25, and in the active portion 120, the active contact portion 124 may reach the deep portion of the contact region 15. Accordingly, the latch-up is suppressed. In this case, the active contact portion 124 and the first inactive contact portion 134 may be formed by different steps.

A combination of whether the active contact portion 124 has the planar contact shape in FIG. 1B or the trench contact shape in FIG. 10B and whether the first inactive contact portion 134 has the planar contact shape in FIG. 12A or the trench contact shape in FIG. 12B is arbitrary. That is, both the active contact portion 124 and the first inactive contact portion 134 may have the planar contact shape, one of the active contact portion 124 or the first inactive contact portion 134 may have the planar contact shape and another may have the trench contact shape, or both the active contact portion 124 and the first inactive contact portion 134 may have the trench contact shape.

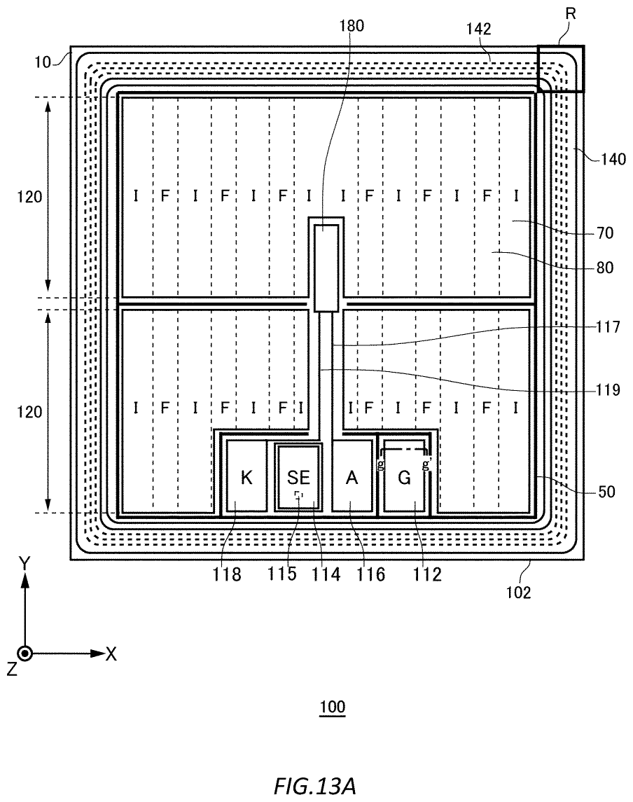

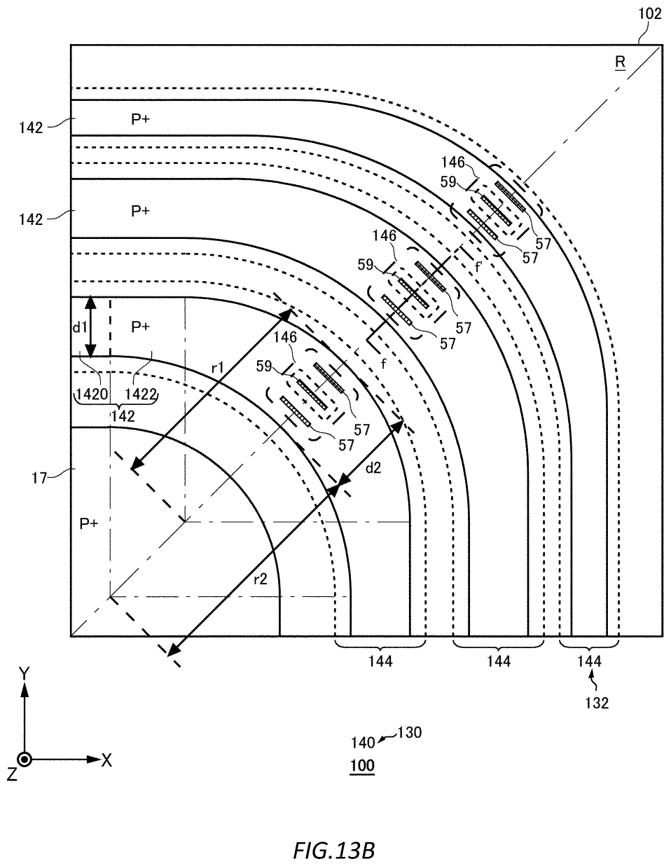

FIG. 13A illustrates an example of a top view of the semiconductor device 100. The semiconductor device 100 in the present example includes a guard ring 142 in the edge termination structure portion 140. The semiconductor device 100 may include a plurality of guard rings 142.

The guard ring 142 is a region of the second conductivity type which is provided between the active portion 120 and the end side 102 of the semiconductor substrate 10 at the front surface 21 of the semiconductor substrate 10. The guard ring 142 is of the P+ type as an example. The guard ring 142 may enclose the active portion 120 in top view. In the present example, the well region 17 adjacent to the active portion 120 may also be included in the guard ring 142. In addition, a plurality of guard rings 142 may be provided. The guard ring 142 arranged on an outside may enclose the guard ring 142 arranged on an inside. The outside refers to a side close to the end side 102, and the inside refers to a side close to a center of the semiconductor substrate 10 in top view. By providing the guard ring 142, the depletion layer on the front surface 21 side of the active portion 120 can be extended to the end side 102 side, and a withstand voltage of the semiconductor device 100 can be improved. The guard ring 142, which is spaced apart from the well region 17 adjacent to the active portion 120, may also be formed in a same diffusion process as that of the well region 17, and its inner and outer diffusion shapes may be substantially the same. In another example, the guard ring 142 may be a VLD in which a depth becomes shallower toward the outside. In still another example, the guard ring 142 may be formed in a same diffusion process as that of the base region 14. The semiconductor device 100 may further include at least one of a field plate or a RESURF provided to enclose the active portion 120 in the edge termination structure portion 140.

FIG. 13B illustrates an example of the region R in FIG. 13A. The semiconductor device 100 in the present example includes the guard ring 142 and a field plate 144 in the edge termination structure portion 140. The edge termination structure portion 140 is an example of the inactive portion 130. The semiconductor device 100 may include the interlayer dielectric film 38, an edge metal layer 146, and a field dielectric film 148 in the edge termination structure portion 140. The interlayer dielectric film 38 and the field dielectric film 148 are omitted in FIG. 13B. A contact hole 57 and a contact hole 59 are provided to penetrate the interlayer dielectric film 38.

The field plate 144 is a conductive member provided above the semiconductor substrate 10. The field plate 144 in the present example is formed of polysilicon doped with impurities. The field plate 144 is an example of the polycrystalline portion 132. The field plate 144 is provided above the guard ring 142. The field plate 144 may be electrically connected to the guard ring 142 corresponding thereto.

The guard ring 142 has a non-corner region 1420 and a corner region 1422. The non-corner region 1420 is, for example, a region of the guard ring 142 extending along the end side 102 of the semiconductor substrate 10, and the corner region 1422 is, for example, a part connecting the regions of the guard ring 142 extending along the end side 102 of the semiconductor substrate 10.

The contact hole 57 connects the edge metal layer 146 and the field plate 144. A barrier metal film formed of titanium, a titanium compound, or the like and/or a plug portion formed of tungsten or the like may be formed inside the contact hole 57.

The contact hole 59 connects the edge metal layer 146 and the guard ring 142. A barrier metal film formed of titanium, a titanium compound, or the like and/or a plug portion formed of tungsten or the like may be formed inside the contact hole 59. The field plate 144 may not be provided around the contact hole 59.

The contact hole 57 and the contact hole 59 may be provided above the corner region 1422 of the guard ring 142. However, at least one of the contact hole 57 or the contact hole 59 may be provided above the non-corner region 1420 of the guard ring 142, or both the contact hole 57 and the contact hole 59 may be provided above the non-corner region 1420 of the guard ring 142. The contact hole 57 and the contact hole 59 in the present example are elongated in a direction in which the guard ring 142 and the field plate 144 extend, and are provided side by side from a center side to the end side 102 side. In another example, the contact hole 57 and the contact hole 59 may be arrayed in the direction in which the guard ring 142 and the field plate 144 extend, the longitudinal direction of each contact hole may be a direction from the center side to the end side 102 side, and each contact hole may include a plurality of contact holes.

A width d2 of the corner region 1422 may be wider than a width d1 of the non-corner region 1420. That is, a curvature radius r1 on the end side 102 side (outside) may be smaller than a sum of a curvature radius r2 on the center side (inside) and d1. In the present example, r1 is smaller than r2. The edge metal layer 146 may be provided at a widest portion of the corner region 1422 or in a vicinity thereof. In another example, the width d2 of the corner region 1422 may be equal to the width d1 of the non-corner region 1420. In addition, in still another example, the edge metal layer 146 may be provided in the non-corner region 1420, or may be provided across the non-corner region 1420 and the corner region 1422.

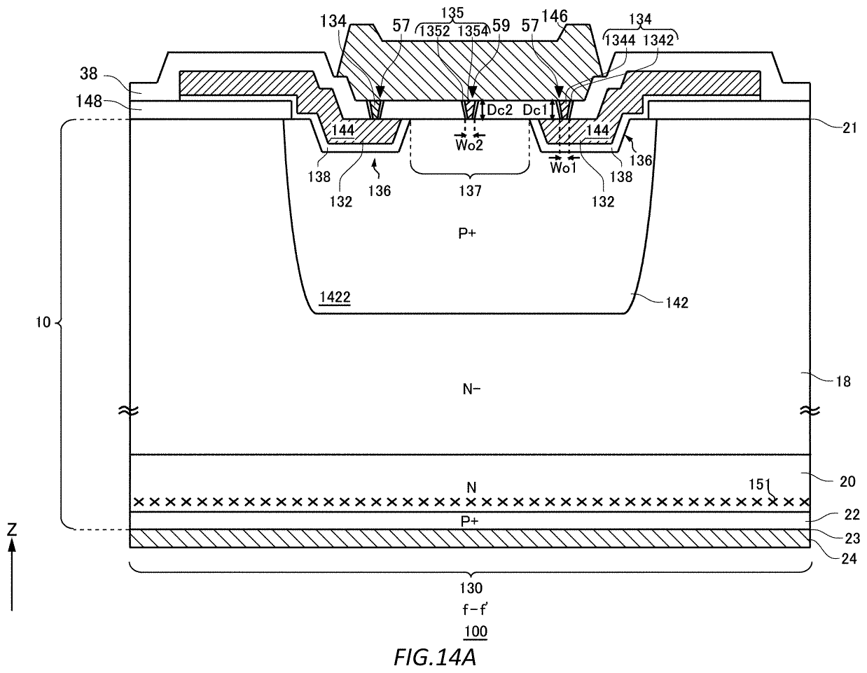

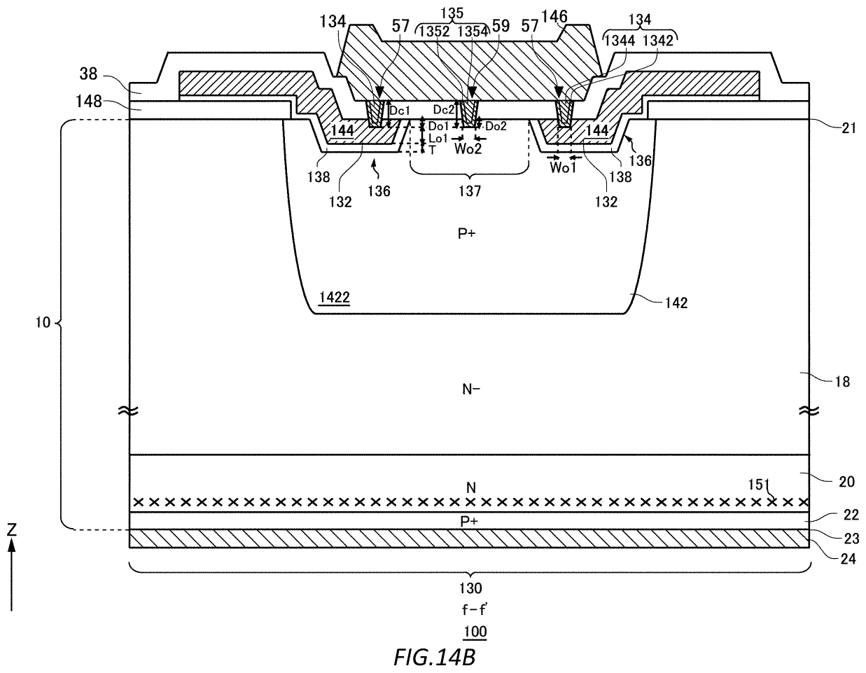

FIG. 14A illustrates an example of a cross section f-f′ in FIG. 13B. The cross section f-f′ is a plane, in the inactive portion 130, passing through the contact hole 57 and the contact hole 59 and parallel to the Z axis direction. The semiconductor device 100 in the present example includes, in the cross section f-f′, the semiconductor substrate 10, the interlayer dielectric film 38, the field dielectric film 148, the edge metal layer 146, the collector electrode 24, the first inactive contact portion 134, and a second inactive contact portion 135.

The field dielectric film 148 is provided above the semiconductor substrate 10. The field dielectric film 148 may be provided so as to cover the drift region 18 exposed on the front surface 21 of the semiconductor substrate 10 between the well region 17 adjacent to the active portion 120 and the guard ring 142 and between the guard rings 142. The field dielectric film 148 may be provided so as to enclose the active portion 120 along the guard ring 142.

The field dielectric film 148 may include a dielectric film obtained by oxidizing or nitriding the semiconductor substrate 10, may include a dielectric film deposited by CVD or the like, or may include another dielectric film. The field dielectric film 148 may be a dielectric film with a single layer, or may be a dielectric film in which a plurality of films formed by different methods are stacked.

The edge metal layer 146 is provided above the semiconductor substrate 10 and is electrically connected to the guard ring 142. The edge metal layer 146 is provided above the semiconductor substrate 10 with the interlayer dielectric film 38 interposed therebetween. The edge metal layer 146 may be electrically connected to the field plate 144. The edge metal layer 146 may be electrically floating. For example, when a voltage V is applied to the collector electrode 24 in a state where the gate of the semiconductor device 100 is off, the edge metal layer 146 is at a predetermined voltage lower than the voltage V. When the guard ring 142 is the well region 17 adjacent to the active portion 120, the edge metal layer 146 may be at a same potential as that of the emitter electrode 52.

The edge metal layer 146 is formed of a material containing metal. At least a partial region of the edge metal layer 146 may be formed of metal such as aluminum (Al) or of a metal alloy such as an aluminum-silicon alloy (AlSi) or an aluminum-silicon-copper alloy (AlSiCu). The edge metal layer 146 may include a barrier metal film formed of titanium, a titanium compound, or the like under a region formed of aluminum or the like.

The inactive portion 130 includes the recess region 136 including a recess on the front surface 21 side of the semiconductor substrate 10. The inactive portion 130 includes, in the recess region 136, the polycrystalline portion 132 provided above the semiconductor substrate 10. The polycrystalline portion 132 in the present example is the field plate 144.

The inactive portion 130 may include the dielectric film 138 on the upper surface of the semiconductor substrate 10 in the recess region 136. The dielectric film 138 may be, for example, a same material as that of the gate dielectric film 42 and/or the dummy dielectric film 32. The dielectric film 138 may be, for example, a thermal oxide film. The polycrystalline portion 132 may be provided above the dielectric film 138 in the recess region 136. The field plate 144 in the present example is provided above the dielectric film 138.

In the depth direction of the semiconductor substrate 10, the height position of the upper surface of the interlayer dielectric film 38 in the active portion 120 is the same as the height position of the upper surface of the interlayer dielectric film 38 in the recess region 136. That is, since the height position of the upper surface of the field plate 144 provided in the recess region 136 is the same as the height position of the front surface 21 of the semiconductor substrate 10, the height position of the upper surface of the interlayer dielectric film 38 in the active portion 120 may be the same as the height position of the upper surface of the interlayer dielectric film 38 in the recess region 136. In addition, the height position of the upper surface of the interlayer dielectric film 38 in the recess region 136 may be the same as the height position of the upper surface of the interlayer dielectric film 38 in the non-recess region 137 in the inactive portion 130.

The second inactive contact portion 135 electrically connects the edge metal layer 146 and the guard ring 142 in contact with each other. The second inactive contact portion 135 may electrically connect a film mainly including metal like the edge metal layer 146 and a film including a monocrystalline substance (a silicon substrate in the present example) like the guard ring 142. A contact width Wo1 of the first inactive contact portion 134 in the recess region 136 and a contact width Wo2 of the second inactive contact portion 135 in the non-recess region 137 may be the same as the contact width Wt of the active contact portion 124. When the contact width Wo1 of the first inactive contact portion 134, the contact width Wo2 of the second inactive contact portion 135, and the contact width Wt of the active contact portion 124 are substantially the same, all the contact portions can be simultaneously formed by a same etching step. However, the contact width Wo1 of the first inactive contact portion 134, the contact width Wo2 of the second inactive contact portion 135, and the contact width Wt of the active contact portion 124 may be different from each other.

When the height position of the upper surface of the interlayer dielectric film 38 in the active portion 120, the height position of the upper surface of the interlayer dielectric film 38 in the recess region 136, and the height position of the upper surface of the interlayer dielectric film 38 in the non-recess region 137 are the same, the active contact portion 124, the first inactive contact portion 134, and the second inactive contact portion 135 can be simultaneously formed by a same etching step. That is, when the upper surfaces of all of the interlayer dielectric film 38 in the active portion 120, the interlayer dielectric film 38 in the recess region 136, and the interlayer dielectric film 38 in the non-recess region 137 have a same height from the front surface 21 of the semiconductor substrate 10, no misalignment in the focal point of exposure occurs in the photolithography step. Therefore, the dimensional tolerance of the interlayer dielectric film 38, the emitter electrode 52, or the like can be reduced. Furthermore, the active contact portion 124, the first inactive contact portion 134, and the second inactive contact portion 135 can be formed with a same dimensional tolerance. Accordingly, it is possible to easily manufacture the contact portions with fewer steps than in a case where the contact portions are formed in separate steps.

By forming the first inactive contact portion 134, the second inactive contact portion 135, and the active contact portion 124 in the same step, it is possible to suppress the spread of the active contact portion 124, and it is possible to suppress the short circuit failure or the like between the gate and the emitter. In addition, the first inactive contact portion 134, the second inactive contact portion 135, and the active contact portion 124 are formed in the same step, and a same contact portion is formed, so that embedding of the plug metal in the contact portion is improved. Accordingly, it is possible to prevent the plug metal from remaining during etch-back, and it is possible to improve the yield in manufacturing the semiconductor device 100. Note that the active contact portion 124, the first inactive contact portion 134, and the second inactive contact portion 135 may be formed by different steps.

The first inactive contact portion 134 is electrically connected to the polycrystalline portion 132. The first inactive contact portion 134 in the present example is electrically connected to the field plate 144. The first inactive contact portion 134 may electrically connect the edge metal layer 146 and the field plate 144. The first inactive contact portion 134 may be provided above the corner region 1422 of the guard ring 142.

The first inactive contact portion 134 may include the barrier metal film 1342 provided in the contact hole 57 and the plug portion 1344. The barrier metal film 1342 of the first inactive contact portion 134 may contain titanium, a titanium compound, or the like. The plug portion 1344 of the first inactive contact portion 134 may contain a plug metal such as tungsten. The second inactive contact portion 135 may include a barrier metal film 1352 provided in the contact hole 59 and a plug portion 1354. The barrier metal film 1352 of the second inactive contact portion 135 may contain titanium, a titanium compound, or the like. The plug portion 1354 of the first inactive contact portion 134 may contain a plug metal such as tungsten.

The polycrystalline portion 132 may be connected to the edge metal layer 146 through the contact hole 57 provided in the interlayer dielectric film 38 above the recess region 136. The field plate 144 in the present example is connected to the edge metal layer 146 through the contact hole 57 provided in the interlayer dielectric film 38. The edge metal layer 146 may be connected to the guard ring 142 through the contact hole 59 provided in the interlayer dielectric film 38 above the non-recess region 137 of the inactive portion 130.

A distance Dc1 from a position where the first inactive contact portion 134 and the edge metal layer 146 are in contact with each other to a lower end of the first inactive contact portion 134 may be equal to a distance Dc2 from a position where the second inactive contact portion 135 and the edge metal layer 146 are in contact with each other to a lower end of the second inactive contact portion 135. Here, a state where two distances such as the distance Dc1 and the distance Dc2 being equal may mean that one distance is 90% or more and 110% or less of another distance. Alternatively, the distance Dc1 may be larger or smaller than the distance Dc2.

FIG. 14B illustrates an example of the cross section f-f′ in FIG. 13B. The semiconductor device 100 in the present example is different from that in the example of FIG. 14A in that the first inactive contact portion 134 has a trench shape. In the present example, the difference from the example of FIG. 14A will be particularly described, and other configurations may be the same as those in the example of FIG. 14A.

The distance Lo1 from the lower end of the first inactive contact portion 134 to the upper surface of the dielectric film 138 in the depth direction of the semiconductor substrate 10 may be larger than, smaller than, or equal to the thickness T of the dielectric film 138. In the depth direction of the semiconductor substrate 10, the distance Do1 from the front surface 21 of the semiconductor substrate 10 to the lower end of the first inactive contact portion 134 may be smaller than the distance Lo1 from the lower end of the first inactive contact portion 134 to the upper surface of the dielectric film 138. In the present example, Do1 is smaller than Lo1. However, in the depth direction of the semiconductor substrate 10, the distance Do1 from the front surface 21 of the semiconductor substrate 10 to the lower end of the first inactive contact portion 134 may be larger than the distance Lo1 from the lower end of the first inactive contact portion 134 to the upper surface of the dielectric film 138.

The first inactive contact portion 134 may not penetrate the polycrystalline portion 132. The first inactive contact portion 134 in the present example does not penetrate the field plate 144. That is, Lo1>0 may be satisfied. In another example, the first inactive contact portion 134 may penetrate the field plate 144, and Lo1=0 may be satisfied. In the present example, the first inactive contact portion 134 may extend from the upper surface of the dielectric film 138 in the depth direction of the semiconductor substrate 10, and the thickness T of the dielectric film 138 below the first inactive contact portion 134 may be reduced, or the first inactive contact portion 134 may penetrate the dielectric film 138 to reach the guard ring 142. However, it should be noted that there may be a problem in the first inactive contact portion 134 in another region formed simultaneously.

The depth Do1 from the front surface 21 of the semiconductor substrate 10 to the lower end of first inactive contact portion 134 in the recess region 136 and a depth Do2 from the front surface 21 of the semiconductor substrate 10 to the lower end of the second inactive contact portion 135 in non-recess region 137 may be the same as the depth Dt from the front surface 21 of the semiconductor substrate 10 to the lower end of the active contact portion 124. When Do1, Do2, and Dt are substantially the same, all the contact portions can be simultaneously formed by a same etching step. When the upper surfaces of all of the interlayer dielectric film 38 in the active portion 120, the interlayer dielectric film 38 in the recess region 136, and the interlayer dielectric film 38 in the non-recess region 137 have a same height from the front surface 21 of the semiconductor substrate 10, no misalignment in the focal point of exposure occurs in the photolithography step. Therefore, the dimensional tolerance of the interlayer dielectric film 38, the emitter electrode 52, or the like can be reduced, and the depths can be made substantially the same even in the case of the trench contact shape. However, Do1, Do2, and Dt may be different from each other. For example, the depth Do1 may be shallower than the depth Dt. The first inactive contact portion 134 may not penetrate the field plate 144, and in the active portion 120, the active contact portion 124 may reach the deep portion of the contact region 15. Accordingly, the latch-up is suppressed. In this case, the active contact portion 124 and the first inactive contact portion 134 may be formed by different steps. In another example, the depth Do1 may be shallower than the depth Do2.

A combination of whether the active contact portion 124 has the planar contact shape in FIG. 1B or the trench contact shape in FIG. 10B and whether the first inactive contact portion 134 has the planar contact shape in FIG. 14A or the trench contact shape in FIG. 14B is arbitrary. That is, both the active contact portion 124 and the first inactive contact portion 134 may have the planar contact shape, one of the active contact portion 124 or the first inactive contact portion 134 may have the planar contact shape and another may have the trench contact shape, or both the active contact portion 124 and the first inactive contact portion 134 may have the trench contact shape. Whether the second inactive contact portion 135 has the planar contact shape in FIG. 14A or the trench contact shape in FIG. 14B may also be arbitrarily selected. The second inactive contact portion 135 may have a same shape as that of the first inactive contact portion 134, may have a same shape as that of the active contact portion 124, or may have a shape different from any shape.

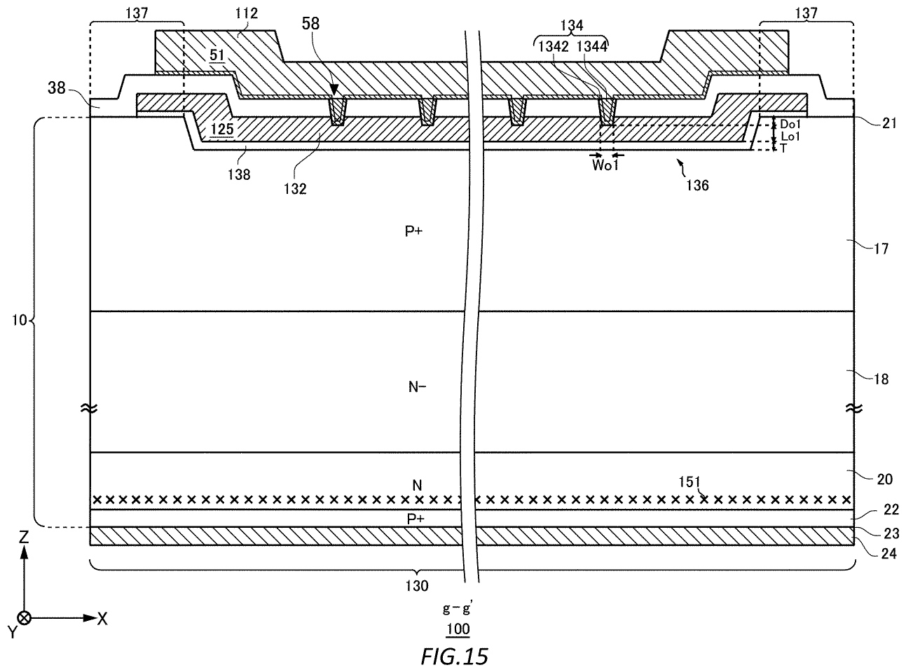

FIG. 15 illustrates an example of a cross section g-g′ in FIG. 13A. The cross section g-g′ is an XZ plane passing through the gate pad 112 in the inactive portion 130. The semiconductor device 100 in the present example includes, in the cross section g-g′, the semiconductor substrate 10, the interlayer dielectric film 38, a pad electrode 51, the collector electrode 24, and the first inactive contact portion 134. The gate pad 112 is an example of the pad electrode 51.

The pad electrode 51 is provided above the semiconductor substrate 10. The pad electrode 51 may be provided above the interlayer dielectric film 38. The gate pad 112 in the present example is provided above the interlayer dielectric film 38.

The inactive portion 130 includes the recess region 136 including a recess on the front surface 21 side of the semiconductor substrate 10. The inactive portion 130 includes, in the recess region 136, the polycrystalline portion 132 provided above the semiconductor substrate 10. The polycrystalline portion 132 in the present example is a pad connection portion 125.

The inactive portion 130 may include the dielectric film 138 on the upper surface of the semiconductor substrate 10 in the recess region 136. The dielectric film 138 may be, for example, a same material as that of the dummy dielectric film 32 and/or the gate dielectric film 42. The dielectric film 138 may be, for example, a thermal oxide film. The polycrystalline portion 132 may be provided above the dielectric film 138 in the recess region 136. The pad connection portion 125 in the present example is provided above the dielectric film 138.

In the depth direction of the semiconductor substrate 10, the height position of the upper surface of the interlayer dielectric film 38 in the active portion 120 is the same as the height position of the upper surface of the interlayer dielectric film 38 in the recess region 136. That is, since the height position of the upper surface of the pad connection portion 125 provided in the recess region 136 is the same as the height position of the front surface 21 of the semiconductor substrate 10, the height position of the upper surface of the interlayer dielectric film 38 in the active portion 120 may be the same as the height position of the upper surface of the interlayer dielectric film 38 in the recess region 136.

When the height position of the upper surface of the interlayer dielectric film 38 in the active portion 120 is the same as the height position of the upper surface of the interlayer dielectric film 38 in the recess region 136, the active contact portion 124 and the first inactive contact portion 134 can be simultaneously formed by a same etching step. That is, when the upper surfaces of both the interlayer dielectric film 38 in the active portion 120 and the interlayer dielectric film 38 in the recess region 136 have a same height from the front surface 21 of the semiconductor substrate 10, no misalignment in the focal point of exposure occurs in the photolithography step. Therefore, a dimensional tolerance of the interlayer dielectric film 38, the emitter electrode 52, the pad electrode 51, or the like can be reduced. Furthermore, the active contact portion 124 and the first inactive contact portion 134 can be formed with a same dimensional tolerance. Accordingly, it is possible to easily manufacture the contact portions with fewer steps than in a case where the contact portions are formed in separate steps.

By forming the first inactive contact portion 134 and the active contact portion 124 in the same step, it is possible to suppress the spread of the active contact portion 124, and it is possible to suppress the short circuit failure or the like between the gate and the emitter. In addition, the first inactive contact portion 134 and the active contact portion 124 are formed in the same step, and a same contact portion is formed, so that embedding of the plug metal in the contact portion is improved. Accordingly, it is possible to prevent the plug metal from remaining during etch-back, and it is possible to improve the yield in manufacturing the semiconductor device 100. Note that the active contact portion 124 and the first inactive contact portion 134 may be formed by different steps.

The first inactive contact portion 134 is electrically connected to the polycrystalline portion 132. The first inactive contact portion 134 in the present example is electrically connected to the pad connection portion 125. The first inactive contact portion 134 may electrically connect the pad electrode 51 and the pad connection portion 125.

The first inactive contact portion 134 may include the barrier metal film 1342 provided in a contact hole 58 and the plug portion 1344. The barrier metal film 1342 of the first inactive contact portion 134 may contain titanium, a titanium compound, or the like. The plug portion 1344 of the first inactive contact portion 134 may contain a plug metal such as tungsten. The barrier metal film 1342 in the present example is provided above the interlayer dielectric film 38 and is in contact with the pad electrode 51. Also in the active portion 120 or other inactive portions 130 such as the edge termination structure portion 140 or the temperature sensitive portion 180, the barrier metal film 1242, the barrier metal film 1342, and/or the barrier metal film 1882 may be provided above the interlayer dielectric film 38. The plug portion 1344 in the present example is provided inside the contact hole 58. In another example, the plug portion 1344 may be provided outside the contact hole 58 and above the barrier metal film 1342 and be in contact with the pad electrode 51, and also in the active portion 120 or other inactive portions 130, the plug portion 1244, the plug portion 1344, the plug portion 1354, and/or the plug portion 1884 may be provided outside the contact hole and above the barrier metal film 1242, the barrier metal film 1342, the barrier metal film 1352, and/or the barrier metal film 1882. In still another example, the barrier metal film 1342 may not be provided above the interlayer dielectric film 38 but may be provided only inside the contact hole 58.

The polycrystalline portion 132 may be connected to the pad electrode 51 through the contact hole 58 provided in the interlayer dielectric film 38 above the recess region 136. The pad connection portion 125 in the present example is connected to the pad electrode 51 through the contact hole 58 provided in the interlayer dielectric film 38.

Below the gate pad 112, the entire polycrystalline portion 132 may be formed in the recess region 136. The polycrystalline portion 132 of the non-recess region 137 may be provided extending outside the gate pad 112 in top view. In another example, the polycrystalline portion 132 may not be provided in the non-recess region 137.

The pad connection portion 125 may be formed of a same polycrystalline as that of the gate conductive portion 44 and the dummy conductive portion 34. In another example, the pad connection portion 125 may be a polycrystalline film obtained by performing ion implantation or the like as necessary to impart conductivity to a polycrystalline film formed simultaneously with a polycrystalline material constituting the temperature sensitive diode portion 183, and the dielectric film 138 below the polycrystalline portion 132 may have a same configuration as that of the dielectric film 196 of the temperature sensitive portion 180. The pad connection portion 125 may not be electrically connected to a portion other than the pad electrode 51. In this case, the pad electrode 51 may be directly connected to the gate metal layer 50. In addition, the pad connection portion 125 may not have conductivity. In another example, the pad connection portion 125 may be electrically connected to the portion other than the pad electrode 51. For example, the pad connection portion 125 may be connected to the connection portion 25. In addition, the pad electrode 51 may not be directly connected to the gate metal layer 50 but may be connected via the pad connection portion 125. In this case, the pad connection portion 125 has conductivity, and may be connected to the gate metal layer 50 outside the gate pad 112 in top view and may be connected to the gate metal layer 50 by a method similar to that of the connection with the pad electrode 51.

The barrier metal film 1342 may be provided up to an end portion of the pad electrode 51. The pad electrode 51 may be provided extending above the non-recess region 137. In another example, the pad electrode 51 may not be provided above the non-recess region 137.

The contact width Wo1 of the first inactive contact portion 134 may be the same as the contact width Wt of the active contact portion 124. When the contact width Wo1 of the first inactive contact portion 134 and the contact width Wt of the active contact portion 124 are substantially the same, both contact portions can be simultaneously formed by a same etching step. However, the contact width Wo1 of the first inactive contact portion 134 may be different from the contact width Wt of the active contact portion 124. The contact width Wo1 of the first inactive contact portion 134 may be larger than the contact width Wt of the active contact portion 124, or may be smaller than the contact width Wt of the active contact portion 124.

In the semiconductor device 100 in the present example, the first inactive contact portion 134 has a trench shape.

The distance Lo1 from the lower end of the first inactive contact portion 134 to the upper surface of the dielectric film 138 in the depth direction of the semiconductor substrate 10 may be larger than, smaller than, or equal to the thickness T of the dielectric film 138. In the depth direction of the semiconductor substrate 10, the distance L2 from the front surface 21 of the semiconductor substrate 10 to the lower end of the first inactive contact portion 134 may be smaller than the distance L1 from the lower end of the first inactive contact portion 134 to the upper surface of the 138 dielectric film 138. In the present example, Do1 is smaller than Lo1. However, in the depth direction of the semiconductor substrate 10, the distance Do1 from the front surface 21 of the semiconductor substrate 10 to the lower end of the first inactive contact portion 134 may be larger than the distance Lo1 from the lower end of the first inactive contact portion 134 to the upper surface of the dielectric film 138.

The first inactive contact portion 134 may not penetrate the polycrystalline portion 132. The first inactive contact portion 134 in the present example does not penetrate the pad connection portion 125. That is, Lo1>0 may be satisfied. In another example, the first inactive contact portion 134 may penetrate the pad connection portion 125, and Lo1=0 may be satisfied. However, it should be noted that when the first inactive contact portion 134 extends from the upper surface of the dielectric film 138 in the depth direction of the semiconductor substrate 10 and the thickness T of the dielectric film 138 below the first inactive contact portion 134 decreases, insulation between the pad connection portion 125 and the semiconductor substrate 10 may not be maintained.

The depth Do1 from the front surface 21 of the semiconductor substrate 10 to the lower end of the first inactive contact portion 134 may be the same as the depth Dt from the front surface 21 of the semiconductor substrate 10 to the lower end of the active contact portion 124. When Do1 and Dt are substantially the same, both contact portions can be simultaneously formed by a same etching step. When the upper surfaces of both the interlayer dielectric film 38 in the active portion 120 and the interlayer dielectric film 38 in the recess region 136 have a same height from the front surface 21 of the semiconductor substrate 10, no misalignment in the focal point of exposure occurs in the photolithography step. Therefore, the dimensional tolerance of the interlayer dielectric film 38, the emitter electrode 52, or the like can be reduced, and the depths can be made substantially the same even in the case of a trench contact shape. In another example, the depth Do1 may be shallower than the depth Dt. In the inactive portion 130, the first inactive contact portion 134 may not penetrate the pad connection portion 125, and in the active portion 120, the active contact portion 124 may reach the deep portion of the contact region 15. Accordingly, the latch-up is suppressed. In this case, the active contact portion 124 and the first inactive contact portion 134 may be formed by different steps.

The first inactive contact portion 134 may have a planar contact shape. That is, Do1=0 may be satisfied. A combination of whether the active contact portion 124 has the planar contact shape in FIG. 1B or the trench contact shape in FIG. 10B and whether the first inactive contact portion 134 has the planar contact shape or the trench contact shape is arbitrary. That is, both the active contact portion 124 and the first inactive contact portion 134 may have the planar contact shape, one of the active contact portion 124 or the first inactive contact portion 134 may have the planar contact shape and another may have the trench contact shape, or both the active contact portion 124 and the first inactive contact portion 134 may have the trench contact shape.

Although description has been given using the gate pad 112 in FIG. 15, the configuration described with respect to the gate pad 112 may also be applied to another pad. For example, the configuration may be used for the anode pad 116, the cathode pad 118, and/or the sensing electrode 114 illustrated in FIG. 13A, and/or any pad (not shown). The pad electrode 51 may be in direct contact with the anode wiring portion 117, the cathode wiring portion 119, or the like, or may be indirectly connected via the polycrystalline portion 132. In addition, when the pad is a Kelvin emitter pad (not shown) having a same potential as that of the emitter electrode 52, the first inactive contact portion 134 may extend from the upper surface of the dielectric film 138 in the depth direction of the semiconductor substrate 10, and the thickness T of the dielectric film 138 below the first inactive contact portion 134 may be reduced, or the first inactive contact portion 134 may penetrate the dielectric film 138 to reach the semiconductor substrate 10. Note that although the example of the XZ cross section has been described with reference to FIG. 15, a longitudinal direction of the contact hole 58 may not be the Y axis direction. For example, the longitudinal direction of the contact hole 58 may be the X axis direction or any direction, and the contact holes 58 having different directions may be used in combination.

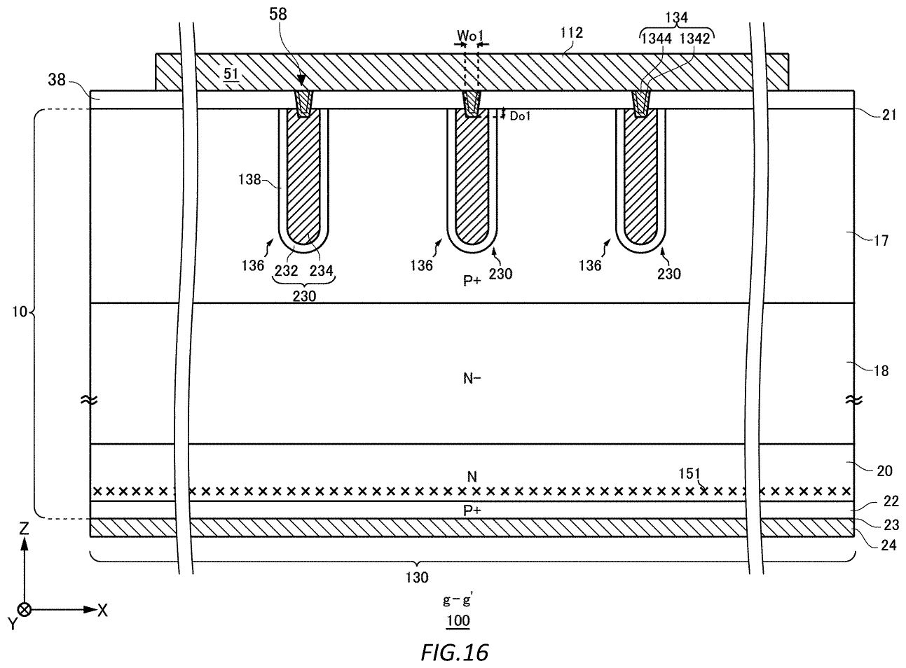

FIG. 16 illustrates another example of the cross section g-g′ in FIG. 13A. The semiconductor device 100 in the present example includes, in the cross section g-g′, the semiconductor substrate 10, the interlayer dielectric film 38, the pad electrode 51, the collector electrode 24, and the first inactive contact portion 134.

The semiconductor device 100 in the present example includes a pad trench portion 230 provided in the semiconductor substrate 10. The pad trench portion 230 includes, therein, a pad trench dielectric film 232 and a pad trench conductive portion 234 insulated from the semiconductor substrate 10 by the pad trench dielectric film 232. The pad trench portion 230 is an example of the recess region 136. The pad trench conductive portion 234 is an example of the polycrystalline portion 132. The pad trench dielectric film 232 is an example of the dielectric film 138. The interlayer dielectric film 38 may be provided above the pad trench portion 230 and the front surface 21 of the semiconductor substrate 10. The contact hole 58 may be provided in the interlayer dielectric film 38. The first inactive contact portion 134 may include the barrier metal film 1342 provided in the contact hole 58 and the plug portion 1344. The first inactive contact portion 134 may connect the pad electrode 51 provided above the interlayer dielectric film 38 and the pad trench conductive portion 234.

The pad electrode 51 may be directly connected to the gate metal layer 50. In another example, the pad electrode 51 may not be directly connected to the gate metal layer 50, but may be connected via the pad trench conductive portion 234. In this case, the pad trench conductive portion 234 may be connected to the gate metal layer 50 outside the gate pad 112 in top view, and may be connected to the gate metal layer 50 by a method similar to the connection with the pad electrode 51.

The pad trench conductive portion 234 may be formed similarly to the gate conductive portion 44 and/or the dummy conductive portion 34. In addition, the pad trench conductive portion 234 may be a polycrystalline film which is formed simultaneously with a polycrystalline material constituting the temperature sensitive diode portion 183 and, if necessary, imparted with conductivity through ion implantation or the like. The pad trench dielectric film 232 may be formed similarly to the gate dielectric film 42 and/or the dummy dielectric film 32. In addition, when the temperature sensitive portion 180 includes the temperature sensitive trench portion 185, the pad trench dielectric film 232 may be formed similarly to the trench insulating portion 184. At least a part of the pad trench portion 230 may extend to the active portion 120 and function as the gate trench portion 40.

In the depth direction of the semiconductor substrate 10, the height position of the upper surface of the interlayer dielectric film 38 in the active portion 120 is the same as the height position of the upper surface of the interlayer dielectric film 38 in the recess region 136. That is, since the height position of the upper surface of the pad trench conductive portion 234 provided in the recess region 136 is the same as the height position of the front surface 21 of the semiconductor substrate 10, the height position of the upper surface of the interlayer dielectric film 38 in the active portion 120 may be the same as the height position of the upper surface of the interlayer dielectric film 38 in the recess region 136.

When the height position of the upper surface of the interlayer dielectric film 38 in the active portion 120 is the same as the height position of the upper surface of the interlayer dielectric film 38 in the recess region 136, the active contact portion 124 and the first inactive contact portion 134 can be simultaneously formed by a same etching step. That is, when the upper surfaces of both the interlayer dielectric film 38 in the active portion 120 and the interlayer dielectric film 38 in the recess region 136 have a same height from the front surface 21 of the semiconductor substrate 10, no misalignment in the focal point of exposure occurs in the photolithography step. Therefore, the dimensional tolerance of the interlayer dielectric film 38, the emitter electrode 52, the pad electrode 51, or the like can be reduced. Furthermore, the active contact portion 124 and the first inactive contact portion 134 can be formed with a same dimensional tolerance. Accordingly, it is possible to easily manufacture the contact portions with fewer steps than in a case where the contact portions are formed in separate steps.

By forming the first inactive contact portion 134 and the active contact portion 124 in the same step, it is possible to suppress the spread of the first inactive contact portion 134, and it is possible to suppress the short circuit failure or the like between the gate and the emitter. In addition, the first inactive contact portion 134 and the active contact portion 124 are formed in the same step, and a same contact portion is formed, so that embedding of the plug metal in the contact portion is improved. Accordingly, it is possible to prevent the plug metal from remaining during etch-back, and it is possible to improve the yield in manufacturing the semiconductor device 100. Note that the active contact portion 124 and the first inactive contact portion 134 may be formed by different steps.

In the semiconductor device 100 in the present example, the first inactive contact portion 134 has a trench shape. In another example, the first inactive contact portion 134 may have a planar contact shape. That is, Do1=0 may be satisfied. The first inactive contact portion 134 may include the barrier metal film 1342 provided in the contact hole 58 and the plug portion 1344. The barrier metal film 1342 of the first inactive contact portion 134 may contain titanium, a titanium compound, or the like. The plug portion 1344 of the first inactive contact portion 134 may contain a plug metal such as tungsten.

Although description has been given using the gate pad 112 in FIG. 16, the configuration described with respect to the gate pad 112 may also be applied to another pad. For example, the configuration may be used for the anode pad 116, the cathode pad 118, and/or the sensing electrode 114 illustrated in FIG. 13A, and/or any pad (not shown). The pad electrode 51 may be in direct contact with the anode wiring portion 117, the cathode wiring portion 119, or the like, or may be indirectly connected via the pad trench conductive portion 234. When the pad electrode 51 is the anode pad 116 or the cathode pad 118, the pad trench portion 230 may be the temperature sensitive trench portion 185. Note that although the example of the XZ cross section has been described with reference to FIG. 16, the longitudinal direction of the contact hole 58 and the pad trench portion 230 may not be the Y axis direction. For example, the longitudinal direction of the contact hole 58 and/or the pad trench portion 230 may be the X axis direction or any direction, and the contact hole 58 and/or the pad trench portion 230 having different directions may be used in combination.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

For example, the temperature sensitive contact portion 188 connecting the temperature sensitive trench conductive portion 201 of the temperature sensitive trench portion 185 has been described using an example having a planar contact shape, but may have a trench contact shape. The temperature sensitive contact portion 188 and the first inactive contact portion 134 may have a planar contact shape, and the active contact portion 124 may have a trench contact shape. The first inactive contact portion 134 may have different shapes, and for example, may differ in shape between the edge termination structure portion 140 and the pad.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### (Item 1)

A semiconductor device including: an active portion; and a temperature sensitive portion, wherein
the temperature sensitive portion includes a temperature sensitive diode portion, and the temperature sensitive diode portion includes
a temperature sensitive trench portion which is provided on a front surface side of a semiconductor substrate,
a temperature sensitive trench conductive portion which is provided inside the temperature sensitive trench portion,
a temperature sensitive anode region of a first conductivity type which is provided in the temperature sensitive trench conductive portion, and
a temperature sensitive cathode region of a second conductivity type which is provided in the temperature sensitive trench conductive portion and is in contact with the temperature sensitive anode region to form a PN junction.

### (Item 2)

The semiconductor device according to item 1, wherein
an inside of the temperature sensitive trench portion is filled with the temperature sensitive trench conductive portion.

### (Item 3)

The semiconductor device according to item 1, wherein
a side wall of the temperature sensitive anode region is in contact with a side wall of the temperature sensitive cathode region.

### (Item 4)

The semiconductor device according to item 1, wherein
a lower surface of one of the temperature sensitive anode region or the temperature sensitive cathode region is in contact with an upper surface of another of the temperature sensitive anode region or the temperature sensitive cathode region.

### (Item 5)

The semiconductor device according to item 1, wherein
the temperature sensitive anode region includes a plurality of temperature sensitive anode regions which are provided inside a trench of the temperature sensitive trench portion,
the temperature sensitive cathode region includes a plurality of temperature sensitive cathode regions which are provided inside the trench of the temperature sensitive trench portion, and
the plurality of temperature sensitive anode regions and the plurality of temperature sensitive cathode regions are alternately arrayed inside the trench of the temperature sensitive trench portion in a direction parallel to a front surface of the semiconductor substrate.

### (Item 6)

The semiconductor device according to item 1, wherein
the temperature sensitive trench portion includes a trench insulating portion which is provided on an inner wall of the temperature sensitive trench conductive portion inside a trench of the temperature sensitive trench portion.

### (Item 7)

The semiconductor device according to any one of items 1 to 6, including:
an interlayer dielectric film which is provided above the active portion and the temperature sensitive diode portion;
a temperature sensitive wiring portion which is electrically connected to the temperature sensitive trench portion; and
a temperature sensitive contact portion which is provided in the interlayer dielectric film and electrically connects the temperature sensitive wiring portion and the temperature sensitive trench portion, wherein
the temperature sensitive wiring portion includes
an anode wiring portion which is electrically connected to the temperature sensitive anode region, and
a cathode wiring portion which is electrically connected to the temperature sensitive cathode region, and
the temperature sensitive contact portion includes
an anode contact portion which is provided in the interlayer dielectric film and electrically connects the anode wiring portion and the temperature sensitive anode region, and
a cathode contact portion which is provided in the interlayer dielectric film and electrically connects the cathode wiring portion and the temperature sensitive cathode region.

### (Item 8)

The semiconductor device according to item 7, wherein
the temperature sensitive trench portion includes a plurality of temperature sensitive trench portions,
the anode contact portion includes a plurality of anode contact portions respectively provided corresponding to the plurality of temperature sensitive trench portions,
the cathode contact portion includes a plurality of cathode contact portions respectively provided corresponding to the plurality of temperature sensitive trench portions,
the anode wiring portion is provided to extend above the plurality of temperature sensitive trench portions, and is electrically connected to the plurality of anode contact portions, and
the cathode wiring portion is provided to extend above the plurality of temperature sensitive trench portions, and is electrically connected to the plurality of cathode contact portions.

### (Item 9)

The semiconductor device according to item 7, wherein
the temperature sensitive trench portion has a linear structure connected to the anode contact portion and the cathode contact portion.

### (Item 10)

The semiconductor device according to any one of items 1 to 6, wherein
the temperature sensitive trench portion has a loop structure in which one end of the temperature sensitive trench portion is connected to another end thereof.

### (Item 11)

The semiconductor device according to any one of items 1 to 6, including
a well region of the second conductivity type which is provided in the semiconductor substrate, wherein
the temperature sensitive trench portion is provided inside the well region in top view, and at least one of a side wall or a bottom portion of the temperature sensitive trench portion is in contact with the well region.

### (Item 12)

The semiconductor device according to any one of items 1 to 6, including
a transition portion which is provided between the temperature sensitive trench portion and the active portion.

### (Item 13)

The semiconductor device according to item 12, wherein
the transition portion includes a dummy trench portion which is provided on the front surface side of the semiconductor substrate.

### (Item 14)

The semiconductor device according to item 12, wherein
the transition portion includes a well region of the second conductivity type which is provided in the semiconductor substrate.

### (Item 15)

The semiconductor device according to any one of items 1 to 6, wherein
the active portion includes an active trench portion which is provided at a front surface of the semiconductor substrate, and
a trench depth of the temperature sensitive trench portion is the same as a trench depth of the active trench portion.

### (Item 16)

A semiconductor device including:
an active portion which is provided in a semiconductor substrate;
a temperature sensitive portion which is provided above the semiconductor substrate; and
an interlayer dielectric film which is provided above the active portion and the temperature sensitive portion, wherein
the temperature sensitive portion includes
a recess region which includes a recess on a front surface side of the semiconductor substrate, and
a temperature sensitive diode portion, which is provided above the semiconductor substrate, in the recess region, and
in a depth direction of the semiconductor substrate, a height position of an upper surface of the interlayer dielectric film in the active portion is the same as a height position of an upper surface of the interlayer dielectric film in the recess region.

### (Item 17)

The semiconductor device according to item 16, including:
a temperature sensitive wiring portion which is electrically connected to the temperature sensitive diode portion; and
a temperature sensitive contact portion which is provided in the interlayer dielectric film and electrically connects the temperature sensitive wiring portion and the temperature sensitive diode portion.

### (Item 18)

The semiconductor device according to item 17, wherein
the active portion includes
an active trench portion which is provided at a front surface of the semiconductor substrate, and
an active contact portion which is provided above the semiconductor substrate, and
a contact width of the temperature sensitive contact portion is larger than a contact width of the active contact portion.

### (Item 19)

The semiconductor device according to item 16, wherein
the temperature sensitive portion includes a dielectric film on an upper surface of the semiconductor substrate in the recess region.

### (Item 20)

The semiconductor device according to item 19, wherein
the temperature sensitive portion includes a temperature sensitive contact portion which is electrically connected to temperature sensitive diode portion, and
a distance from a lower end of the temperature sensitive contact portion to an upper surface of the dielectric film in the depth direction of the semiconductor substrate is larger than a thickness of the dielectric film.

### (Item 21)

The semiconductor device according to item 19, wherein
the temperature sensitive portion includes a temperature sensitive contact portion which is electrically connected to temperature sensitive diode portion, and
in the depth direction of the semiconductor substrate, a distance from a front surface of the semiconductor substrate to a lower end of the temperature sensitive contact portion is larger than a distance from the lower end of the temperature sensitive contact portion to an upper surface of the dielectric film.

### (Item 22)

The semiconductor device according to item 19, wherein
the temperature sensitive portion includes a temperature sensitive contact portion which is electrically connected to temperature sensitive diode portion, and
in the depth direction of the semiconductor substrate, a distance from a front surface of the semiconductor substrate to a lower end of the temperature sensitive contact portion is smaller than the distance from a lower end of the temperature sensitive contact portion to an upper surface of the dielectric film.

### (Item 23)

A method for manufacturing a semiconductor device including: forming an active portion; and forming a temperature sensitive portion, wherein
the forming the temperature sensitive portion includes
forming a temperature sensitive trench portion on a front surface side of a semiconductor substrate,
forming a temperature sensitive trench conductive portion inside the temperature sensitive trench portion,
forming a temperature sensitive anode region in the temperature sensitive trench conductive portion, and
forming, in the temperature sensitive trench conductive portion, a temperature sensitive cathode region in contact with the temperature sensitive anode region.

### (Item 24)

The method for manufacturing the semiconductor device according to item 23, wherein
the forming the active portion includes forming a trench of an active trench portion on the front surface side of the semiconductor substrate, and
a trench of the temperature sensitive trench portion and the trench of the active trench portion are simultaneously formed by a same etching step.

### (Item 25)

A semiconductor device including an active portion and an inactive portion, including
an interlayer dielectric film which is provided above the active portion and the inactive portion, wherein
the inactive portion includes
a recess region which includes a recess on a front surface side of a semiconductor substrate, and
a polycrystalline portion, which is provided above the semiconductor substrate, in the recess region, and
in a depth direction of the semiconductor substrate, a height position of an upper surface of the interlayer dielectric film in the active portion is the same as a height position of an upper surface of the interlayer dielectric film in the recess region.

### (Item 26)

The semiconductor device according to item 25, wherein
the inactive portion includes a first inactive contact portion which is provided in the interlayer dielectric film above the recess region and is electrically connected to the polycrystalline portion.

### (Item 27)

The semiconductor device according to item 26, wherein
the inactive portion includes a dielectric film on an upper surface of the semiconductor substrate in the recess region, and
a distance from a lower end of the first inactive contact portion to an upper surface of the dielectric film in the depth direction of the semiconductor substrate is larger than a thickness of the dielectric film.

### (Item 28)

The semiconductor device according to item 26, wherein
the inactive portion includes a dielectric film on an upper surface of the semiconductor substrate in the recess region, and
in the depth direction of the semiconductor substrate, a distance from a front surface of the semiconductor substrate to a lower end of the first inactive contact portion is larger than a distance from the lower end of the first inactive contact portion to an upper surface of the dielectric film.

### (Item 29)

The semiconductor device according to item 26, wherein
the inactive portion includes a dielectric film on an upper surface of the semiconductor substrate in the recess region, and
in the depth direction of the semiconductor substrate, a distance from a front surface of the semiconductor substrate to a lower end of the first inactive contact portion is smaller than a distance from the lower end of the first inactive contact portion to an upper surface of the dielectric film.

### (Item 30)

The semiconductor device according to any one of items 26 to 29, including:
a gate trench portion which is provided at a front surface of the semiconductor substrate and includes a gate conductive portion; and
a gate metal layer which is provided above the semiconductor substrate, wherein
the first inactive contact portion is electrically connected to the gate metal layer and the polycrystalline portion, wherein
the polycrystalline portion is connected to the gate conductive portion.

### (Item 31)

The semiconductor device according to item 30, wherein
the polycrystalline portion is provided extending outside the recess region, and
The gate trench portion is provided outside the recess region.

### (Item 32)

The semiconductor device according to any one of items 26 to 29, including:
a dummy trench portion which is provided at a front surface of the semiconductor substrate and includes a dummy conductive portion; and
an emitter electrode which is provided above the semiconductor substrate, wherein
the first inactive contact portion is electrically connected to the emitter electrode and the polycrystalline portion, wherein
the polycrystalline portion is connected to the dummy conductive portion.

### (Item 33)

The semiconductor device according to item 32, wherein
the polycrystalline portion provided extending outside the recess region, and
the dummy trench portion is provided outside the recess region.

### (Item 34)

The semiconductor device according to any one of items 26 to 29, including:
a guard ring of the second conductivity type which is provided between the active portion and an end side of the semiconductor substrate at a front surface of the semiconductor substrate; and
an edge metal layer which is provided above the semiconductor substrate, wherein
the inactive portion includes a second inactive contact portion which is provided in the interlayer dielectric film outside the recess region and electrically connects the edge metal layer and guard ring, wherein
the first inactive contact portion electrically connects the edge metal layer and the polycrystalline portion.

### (Item 35)

The semiconductor device according to item 34, wherein
in the depth direction of the semiconductor substrate, a distance from a position where the first inactive contact portion and the edge metal layer are in contact with each other to a lower end of the first inactive contact portion is equal to a distance from a position where the second inactive contact portion and the edge metal layer are in contact with each other to a lower end of the second inactive contact portion.

### (Item 36)

The semiconductor device according to item 34, wherein
the first inactive contact portion is provided above a corner region of the guard ring.

### (Item 37)

The semiconductor device according to any one of items 26 to 29, including
a pad electrode which is provided above the semiconductor substrate, wherein
the first inactive contact portion electrically connects the pad electrode and the polycrystalline portion.

### EXPLANATION OF REFERENCES

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 31: extending part; 32: dummy dielectric film; 33: connecting part; 34: dummy conductive portion; 38: interlayer dielectric film; 40: gate trench portion; 41: extending part; 42: gate dielectric film; 43: connecting part; 44: gate conductive portion; 50: gate metal layer; 51: pad electrode; 52: emitter electrode; 54: contact hole; 55: contact hole; 56: contact hole; 57: contact hole; 58: contact hole; 59: contact hole; 70: transistor portion; 71: mesa portion; 80: diode portion; 81: mesa portion; 82: cathode region; 90: boundary portion; 91: mesa portion; 100: semiconductor device; 102: end side; 112: gate pad; 114: sensing electrode; 115: current sensing portion; 116: anode pad; 117: anode wiring portion; 118: cathode pad; 119: cathode wiring portion; 120: active portion; 122: active trench portion; 124: active contact portion; 125: pad connection portion; 130: inactive portion; 132: polycrystalline portion; 134: first inactive contact portion; 135: second inactive contact portion; 136: recess region; 137: non-recess region; 138: dielectric film; 140: edge termination structure portion; 142: guard ring; 144: field plate; 146: edge metal layer; 148: field dielectric film; 151: back surface side lifetime control region; 152: front surface side lifetime control region; 170: Zener diode; 180: temperature sensitive portion; 181: temperature sensitive cathode region; 182: temperature sensitive anode region; 183: temperature sensitive diode portion; 184: trench insulating portion; 185: temperature sensitive trench portion; 186: cathode contact portion; 187: anode contact portion; 188: temperature sensitive contact portion; 189: temperature sensitive wiring portion; 190: transition portion; 191: mesa portion; 194: recess region; 196: dielectric film; 201: temperature sensitive trench conductive portion; 230: pad trench portion; 232: pad trench dielectric film; 234: pad trench conductive portion; 300: PN junction; 310: short wiring portion; 311: short contact portion; 320: linear portion; 321: curved portion; 1242: barrier metal film; 1244: plug portion; 1342: barrier metal film; 1344: plug portion; 1352: barrier metal film; 1354: plug portion; 1420: non-corner region; 1422: corner region; 1882: barrier metal film; and 1884: plug portion.

What is claimed is:

1. A semiconductor device comprising an active portion and a temperature sensitive portion, wherein
the temperature sensitive portion includes a temperature sensitive diode portion, and
the temperature sensitive diode portion includes
a temperature sensitive trench portion which is provided on a front surface side of a semiconductor substrate,
a temperature sensitive trench conductive portion which is provided inside the temperature sensitive trench portion,
a temperature sensitive anode region of a first conductivity type which is provided in the temperature sensitive trench conductive portion, and
a temperature sensitive cathode region of a second conductivity type which is provided in the temperature sensitive trench conductive portion and is in contact with the temperature sensitive anode region to form a PN junction.

2. The semiconductor device according to claim 1, wherein
an inside of the temperature sensitive trench portion is filled with the temperature sensitive trench conductive portion.

3. The semiconductor device according to claim 1, wherein
a side wall of the temperature sensitive anode region is in contact with a side wall of the temperature sensitive cathode region.

4. The semiconductor device according to claim 1, wherein
a lower surface of one of the temperature sensitive anode region or the temperature sensitive cathode region is in contact with an upper surface of another of the temperature sensitive anode region or the temperature sensitive cathode region.

5. The semiconductor device according to claim 1, wherein
the temperature sensitive anode region includes a plurality of temperature sensitive anode regions which are provided inside a trench of the temperature sensitive trench portion,
the temperature sensitive cathode region includes a plurality of temperature sensitive cathode regions which are provided inside the trench of the temperature sensitive trench portion, and
the plurality of temperature sensitive anode regions and the plurality of temperature sensitive cathode regions are alternately arrayed inside the trench of the temperature sensitive trench portion in a direction parallel to a front surface of the semiconductor substrate.

6. The semiconductor device according to claim 1, wherein
the temperature sensitive trench portion includes a trench insulating portion which is provided on an inner wall of the temperature sensitive trench conductive portion inside a trench of the temperature sensitive trench portion.

7. The semiconductor device according to claim 1, comprising:
an interlayer dielectric film which is provided above the active portion and the temperature sensitive diode portion;
a temperature sensitive wiring portion which is electrically connected to the temperature sensitive trench portion; and
a temperature sensitive contact portion which is provided in the interlayer dielectric film and electrically connects the temperature sensitive wiring portion and the temperature sensitive trench portion, wherein
the temperature sensitive wiring portion includes
an anode wiring portion which is electrically connected to the temperature sensitive anode region, and
a cathode wiring portion which is electrically connected to the temperature sensitive cathode region, and
the temperature sensitive contact portion includes
an anode contact portion which is provided in the interlayer dielectric film and electrically connects the anode wiring portion and the temperature sensitive anode region, and
a cathode contact portion which is provided in the interlayer dielectric film and electrically connects the cathode wiring portion and the temperature sensitive cathode region.

8. The semiconductor device according to claim 7, wherein
the temperature sensitive trench portion includes a plurality of temperature sensitive trench portions,
the anode contact portion includes a plurality of anode contact portions respectively provided corresponding to the plurality of temperature sensitive trench portions,
the cathode contact portion includes a plurality of cathode contact portions respectively provided corresponding to the plurality of temperature sensitive trench portions,
the anode wiring portion is provided to extend above the plurality of temperature sensitive trench portions, and is electrically connected to the plurality of anode contact portions, and
the cathode wiring portion is provided to extend above the plurality of temperature sensitive trench portions, and is electrically connected to the plurality of cathode contact portions.

9. The semiconductor device according to claim 7, wherein
the temperature sensitive trench portion has a linear structure connected to the anode contact portion and the cathode contact portion.

10. The semiconductor device according to claim 2, comprising:
an interlayer dielectric film which is provided above the active portion and the temperature sensitive diode portion;
a temperature sensitive wiring portion which is electrically connected to the temperature sensitive trench portion; and
a temperature sensitive contact portion which is provided in the interlayer dielectric film and electrically connects the temperature sensitive wiring portion and the temperature sensitive trench portion, wherein
the temperature sensitive wiring portion includes
an anode wiring portion which is electrically connected to the temperature sensitive anode region, and
a cathode wiring portion which is electrically connected to the temperature sensitive cathode region, and
the temperature sensitive contact portion includes
an anode contact portion which is provided in the interlayer dielectric film and electrically connects the anode wiring portion and the temperature sensitive anode region, and
a cathode contact portion which is provided in the interlayer dielectric film and electrically connects the cathode wiring portion and the temperature sensitive cathode region.

11. The semiconductor device according to claim 10, wherein
the temperature sensitive trench portion includes a plurality of temperature sensitive trench portions,
the anode contact portion includes a plurality of anode contact portions respectively provided corresponding to the plurality of temperature sensitive trench portions,
the cathode contact portion includes a plurality of cathode contact portions respectively provided corresponding to the plurality of temperature sensitive trench portions,
the anode wiring portion is provided to extend above the plurality of temperature sensitive trench portions, and is electrically connected to the plurality of anode contact portions, and
the cathode wiring portion is provided to extend above the plurality of temperature sensitive trench portions, and is electrically connected to the plurality of cathode contact portions.

12. The semiconductor device according to claim 10, wherein
the temperature sensitive trench portion has a linear structure connected to the anode contact portion and the cathode contact portion.

13. The semiconductor device according to claim 1, wherein
the temperature sensitive trench portion has a loop structure in which one end of the temperature sensitive trench portion is connected to another end thereof.

14. The semiconductor device according to claim 1, comprising
a well region of the second conductivity type which is provided in the semiconductor substrate, wherein
the temperature sensitive trench portion is provided inside the well region in top view, and at least one of a side wall or a bottom portion of the temperature sensitive trench portion is in contact with the well region.

15. The semiconductor device according to claim 1, comprising
a transition portion which is provided between the temperature sensitive trench portion and the active portion.

16. The semiconductor device according to claim 15, wherein
the transition portion includes a dummy trench portion which is provided on the front surface side of the semiconductor substrate.

17. The semiconductor device according to claim 15, wherein
the transition portion includes a well region of the second conductivity type which is provided in the semiconductor substrate.

18. The semiconductor device according to claim 1, wherein
the active portion includes an active trench portion which is provided at a front surface of the semiconductor substrate, and
a trench depth of the temperature sensitive trench portion is the same as a trench depth of the active trench portion.

19. A method for manufacturing a semiconductor device comprising: forming an active portion; and forming a temperature sensitive portion, wherein
the forming the temperature sensitive portion includes
forming a temperature sensitive trench portion on a front surface side of a semiconductor substrate,
forming a temperature sensitive trench conductive portion inside the temperature sensitive trench portion,
forming a temperature sensitive anode region in the temperature sensitive trench conductive portion, and
forming, in the temperature sensitive trench conductive portion, a temperature sensitive cathode region in contact with the temperature sensitive anode region.

20. The method for manufacturing the semiconductor device according to claim 19, wherein
the forming the active portion includes forming a trench of an active trench portion on the front surface side of the semiconductor substrate, and
a trench of the temperature sensitive trench portion and the trench of the active trench portion are simultaneously formed by a same etching step.
